(19) United States
(12) Patent Application Publication
(10) Pub. No.: US 2026/0333942 A1
(43) Pub. Date: Oct. 22, 2026

(54) ARTICLE, SOLAR PANEL, AND INSULATED GLASS UNIT EACH INCLUDING AN ULTRAVIOLET BLOCKING AND VISIBLE ANTI-REFLECTIVE COATING

(71) Applicant: CORNING INCORPORATED, CORNING, NY (US)

(72) Inventors: Jaymin Amin, Corning, NY (US); Robert Alan Bellman, Ithaca, NY (US); Philip Simon Brown, Big Flats, NY (US); Matthew John Dejneka, Corning, NY (US); Shandon Dee Hart, Elmira, NY (US); Carlo Anthony Kosik Williams, Painted Post, NY (US); Peter Joseph Lezzi, Corning, NY (US); Lin Lin, Painted Post, NY (US); Fred Douglas Woodall, II, Elmira, NY (US); Steven Akira Yamada, Painted Post, NY (US)

(21) Appl. No.: 19/702,332

(22) Filed: Jun. 9, 2026

Related U.S. Application Data
(63) Continuation-in-part of application No. PCT/US2025/058740, filed on Dec. 9, 2025.
(60) Provisional application No. 63/730,553, filed on Dec. 11, 2024.
(60) Provisional application No. 63/759,589, filed on Feb. 18, 2025.
(60) Provisional application No. 63/761,293, filed on Feb. 21, 2025.

(51) Int. Cl. H10F 77/30; H10F 19/80; H10F 77/42

(52) U.S. Cl. CPC H10F 77/315; H10F 19/804; H10F 77/334; H10F 77/42

(57) ABSTRACT

An article is described herein including a substrate with a multilayer coating disposed on a first major surface of the substrate. The article exhibits, due at least in part to the multilayer coating, relatively low transmittance of ultraviolet wavelengths, relatively high reflectance of ultraviolet wavelengths, relatively high transmittance of visible wavelengths, and relatively low transmittance of infrared wavelengths. The multilayer coating exhibits a relatively high hardness. The multilayer coating an include a plurality of multilayer sections, each of the multilayer sections disposed successively with respect to one another on the first major surface and comprising at least two layers exhibiting unique indices of refraction. Also disclosed are a solar panel and an insulated glass unit including the article.

### CROSS-REFERENCE TO RELATED APPLICATIONS

This application in a continuation-in-part of International Patent Application No. PCT/US2025/058740 filed Dec. 9, 2025, which claims priority to and the benefit of U.S. Provisional Application No. 63/761,293 filed Feb. 21, 2025, U.S. Provisional Application No. 63/759,589 filed Feb. 18, 2025, and U.S. Provisional Application No. 63/730,553 filed Dec. 11, 2024, all of which are incorporated herein by reference in their entireties.

### BACKGROUND

Electricity demand tends to increase as the human population of the Earth increases. Traditionally, carbon-based fuels have been utilized to generate electricity. However, the Earth's reserves of carbon-based fuels are finite. Alternative ways to generate electricity have been developed and are in development, such as generating electricity from the Sun, from wind, from waves, from tidal changes, and so on.

As a particular example, solar panels generate electricity from the Sun. Nuclear fusion and other processes at the Sun generate photons, which are packets of energy, spanning a broad range of wavelengths. These photons travel toward the Earth. Photons of certain wavelength ranges manage to penetrate the Earth's atmosphere and reach the Earth's surface. Table 1 below, as well as FIG. 1 of the Drawings, show the relative abundance of photons as a function of wavelength, both within space unfiltered by the Earth's atmosphere (AMOG) and within Earth's environment after being filtered by the atmosphere (AM1.5G). The photons from the Sun correspond to the ultraviolet, visible, near-infrared (NIR), and radio wave spectrums, with the atmosphere filtering much of the smaller wavelengths of the ultraviolet spectrum. Photons corresponding to the radio wave spectrum have much less energy per photon than photons corresponding to the ultraviolet, visible, and near-infrared spectrums (because energy per photon is inversely proportional to wavelength).

TABLE 1

| | Average AMOG | Normalized | Average AM1.5G | Normalized |
|---|---|---|---|---|
| Wavelength | Photon Flux | Average AMOG | Photon Flux | Average AM1.5G |
| Range (nm): | (s⁻¹ m⁻² nm⁻¹) | Photon Flux | (s⁻¹ m⁻² nm⁻¹) | Photon Flux |
| 200-250 | 4.66E+25 | 0.01 | 0 | 0 |
| 250-300 | 3.66E+26 | 0.07 | 0 | 0 |
| 300-350 | 1.30E+27 | 0.25 | 4.63E+26 | 0.10 |
| 350-400 | 2.02E+27 | 0.38 | 1.23E+27 | 0.27 |
| 400-450 | 3.74E+27 | 0.71 | 2.65E+27 | 0.58 |
| 450-500 | 4.75E+27 | 0.90 | 3.72E+27 | 0.82 |
| 500-550 | 4.95E+27 | 0.94 | 4.04E+27 | 0.88 |
| 550-600 | 5.28E+27 | 0.99 | 4.32E+27 | 0.95 |
| 600-650 | 5.29E+27 | 1.00 | 4.53E+27 | 0.99 |
| 650-700 | 5.09E+27 | 0.96 | 4.56E+27 | 1.00 |
| 700-750 | 4.87E+27 | 0.92 | 4.39E+27 | 0.96 |
| 750-800 | 4.67E+27 | 0.88 | 4.16E+27 | 0.91 |
| 800-850 | 4.45E+27 | 0.84 | 4.05E+27 | 0.89 |
| 850-900 | 4.21E+27 | 0.80 | 4.02E+27 | 0.88 |
| 900-950 | 4.07E+27 | 0.77 | 2.46E+27 | 0.54 |
| 950-1000 | 3.85E+27 | 0.73 | 2.91E+27 | 0.64 |
| 1000-1050 | 3.61E+27 | 0.68 | 3.58E+27 | 0.78 |
| 1050-1100 | 3.40E+27 | 0.64 | 3.23E+27 | 0.71 |
| 1100-1200 | 3.17E+27 | 0.60 | 1.83E+27 | 0.40 |
| 1200-1300 | 2.89E+27 | 0.55 | 2.71E+27 | 0.59 |
| 1300-1400 | 2.56E+27 | 0.48 | 7.90E+26 | 0.17 |
| 1400-1500 | 2.33E+27 | 0.44 | 5.12E+26 | 0.11 |
| 1500-1600 | 2.12E+27 | 0.40 | 1.99E+27 | 0.44 |
| 1600-1700 | 1.89E+27 | 0.36 | 1.84E+27 | 0.40 |
| 1700-1800 | 1.64E+27 | 0.31 | 1.27E+27 | 0.28 |

In turn, solar panels include a semiconductor material that provides a photovoltaic effect that transforms photons into electricity. The semiconductor material absorbs the photons from the Sun. If the photon that the semiconductor material absorbs has sufficient energy, then the photon excites an electron to move from a relatively lower energy valence band to a relatively higher energy conduction band. The electron that moved to the conduction band leaves a “hole” in the valence band and thus a charge separation. When the semiconductor material is connected to an electrical circuit, with appropriate doping and structure of the semiconductor material, such as in various combinations of n-doped and p-doped silicon regions arranged into junction structures known in the field of photovoltaics, the charge separation leads to electrical current. Such solar panels have been utilized both for terrestrial and space-based applications.

Whether the photon that the semiconductor material absorbs has sufficient energy to excite an electron to move from the valence band to the conduction band depends on the bandgap of the semiconductor material. Silicon, for example, has a bandgap energy of about 1.1 electronvolts (eV), which corresponds to a photon having a wavelength of about 1100 nm, which is in the near-infrared spectrum. Photons having wavelengths of about 1100 nm and shorter (thus having higher energy per photon), when absorbed by the silicon semiconductor, excite the electron to move from the valence band to the conduction band. Practical silicon-based PV cells can generate at least some energy using wavelengths as long as about 1200 nm, and shorter wavelengths, but not using wavelengths longer than 1200 nm. Other semiconductor materials have different bandgap energies.

In addition to a semiconductor material that converts photons into electricity, solar panels typically include both (i) a cover article over the semiconductor material and (ii) an encapsulant that encapsulates the semiconductor material. The cover article separates the semiconductor material from the external environment, such as rain, hail, debris, and other things that could damage the semiconductor material or wiring and electrical connections needed to efficiently harvest electricity from photovoltaic cells within the solar panel. The encapsulant further helps prevent moisture from reaching and then degrading the semiconductor material.

The cover article sometimes includes a substrate having a glass composition. However, a typical glass-to-air interface reflects about 4% of incident electromagnetic radiation in the visible spectrum. The reflected photons cannot be used to generate electricity. To counter the natural reflectance of the glass-to-air interface, the cover article sometimes includes an anti-reflection (AR) coating coated onto the surface of the substrate of glass. The AR coating is typically a porous layer of SiO₂. The layer of porous SiO₂ reduces reflectance, increasing the number of photons transmitted therethrough to the photovoltaic cells.

However, there are various problems with the typical solar panel described above. First, the typical porous SiO₂ AR coating lacks durability. The typical porous SiO₂ AR coating is readily removed via weather events, abrasion from dirt or sand, and cleaning. It is estimated that the typical porous SiO₂ AR coating is completely removed from the substrate after only five years of use and, in some cases, after only six months of use. The lack of durability is a problem because removal of the AR coating causes the substrate of glass to revert to its natural reflectance, and photons that otherwise could have been converted into electricity are reflected into the external environment. Further, SiO₂ AR coatings are susceptible to scratches, chips, and partial delamination, which cause light scattering or multi-bounce reflection events resulting in an even higher reflectance (or lower transmittance) than if the substrate did not include the SiO₂ coating at all. These degradation mechanisms result in reduced electrical energy generation from the solar panel over time, which also leads to higher effective costs for electricity, which can be quantified as a higher levelized cost of energy over the life of the solar panel.

Second, electromagnetic radiation within the ultraviolet spectrum degrades the encapsulant and other components of the solar panel (e.g., regions near silicon-metal contacts). As the encapsulant degrades (sometimes called “yellowing” of the encapsulant), the encapsulant absorbs photons before the photons reach the semiconductor material to generate the electric current. The problem is exacerbated in space-based applications because the Earth's atmosphere is not available to filter the shorter wavelength and higher energy portions of the ultraviolet spectrum.

Third, heat generation is an issue. In general, photons associated with wavelengths of 1200 nm or greater do not excite electrons to move from the valence band to the conductive band. Photons that the semiconductor material absorb but do not excite electrons to the conductive band can generate heat. More particularly, although these infrared photons with wavelengths longer than 1200 nm would typically have low absorption within an undoped (intrinsic) silicon material, they are in fact absorbed at appreciable levels in doped silicon (e.g. p-doped or n-doped) of the type used in solar cells. This sub-bandgap absorption in silicon at wavelengths in the range of 1200 nm to 2500 nm varies with doping levels and cell architecture, but may be as high as 30% or even higher, leading to appreciable heat generation in the solar cell or solar panel. The heat generated can result in suboptimal solar panel electricity generation. Further, these sub-bandgap infrared photons may also be absorbed by other elements within the solar cell and panel, such as the cover glass, polymer encapsulant, metal contacts, semiconductor junctions, and interfaces between these elements and/or the semiconductor materials. Such absorbance further generates heat. Still further, encapsulants may contain ultraviolet (UV) absorbing materials in order to slow down degradation, but this UV absorption can generate heat as well. Thus, those photons may be absorbed by elements within the solar panel, or by elements surrounding the solar panel, and generate heat. The increased heat and increased operating temperature of the solar cells decreases electrical conversion efficiency.

### SUMMARY

The present disclosure addresses those problems, among others, with a multilayer coating for a cover glass that includes at least one high hardness material layer, that is engineered via principles of interference to reduce reflectance within the visible spectrum, that is engineered via principles of interference to simultaneously increase reflectance within the ultraviolet range, and optionally to increase simultaneously reflectance within the infrared range.

According to an Aspect 1 of the present disclosure, an article comprises: a substrate comprising a first major surface and a second major surface, the first major surface and the second major surface facing in generally opposite directions; and a multilayer coating disposed on the first major surface of the substrate, the multilayer coating comprising a total coating thickness, wherein (a) the multilayer coating of the article exhibits a maximum hardness that is greater than or equal to 5 GPa measured at any depth within an indentation depth range of (i) from 0 to 500 nm into the total coating thickness or (ii) from 0 to the total coating thickness, whichever of (i) and (ii) is smaller, according to a Berkovich Indenter Hardness Test, (b) the article exhibits an average first-surface reflectance, at an angle of incidence of 5 degrees from orthogonal to the first major surface, that is less than or equal to 1.10% across one or more of the following wavelength ranges: from 700 nm to 750 nm, from 750 nm to 800 nm, from 800 nm to 850 nm, and from 850 nm to 900 nm, and (c) the article exhibits an average transmittance through the article, at an angle of incidence of 0 degrees from orthogonal to the first major surface, that is (i) less than or equal to 12.0% across the wavelength range of from 250 nm to 300 nm, and (ii) less than or equal to 50% across the wavelength range of from 300 nm to 350 nm.

According to an Aspect 2 of the present disclosure, the article of Aspect 1 is presented, wherein (A) the substrate comprises a glass composition or a glass-ceramic composition, and (B) the multilayer coating further comprises (1) a plurality of multilayer sections, each of the multilayer sections disposed successively with respect to one another on the first major surface, each multilayer section comprising at least two layers, wherein (a) both of the at least two layers exhibit unique indices of refraction, (b) the layer of the at least two layers disposed closer to the first major surface of the substrate is one of (i) an LRI layer exhibiting a low index of refraction within a range of from 1.35 to 1.60, (ii) an MLRI layer exhibiting a medium-low index of refraction that is within a range of from 1.61 to 1.84, and (iii) an MHRI layer exhibiting a medium-high index of refraction that is within a range of from 1.85 to 2.10, and (c) the layer of the at least two layers disposed farther from the first major surface of the substrate exhibits a greater index of refraction than the closer layer and is one of (i) an MLRI layer, (ii) an MHRI layer, and (iii) an HRI layer exhibiting a high index of refraction that is within a range of from 2.11 to 2.70, and (2) a capping LRI layer disposed over the plurality of multilayer sections, the capping LRI layer exhibiting the low index of refraction and comprising a capping layer thickness.

According to an Aspect 3 of the present disclosure, the article of any one of Aspects 1-2 is presented, wherein the average first-reflectance, at an angle of incidence of 5 degrees from orthogonal to the first major surface, that the article exhibits is less than or equal to 0.9% across all of the following wavelength ranges: from 500 nm to 550 nm, from 550 nm to 600 nm, from 600 nm to 650 nm, from 650 nm to 700 nm, from 700 nm to 750 nm, from 750 nm to 800 nm, and from 800 nm to 850 nm.

According to an Aspect 4 of the present disclosure, the article of any one of Aspects 1-3 is presented, wherein (i) the article exhibits an average first-surface reflectance, at an angle of incidence of 5 degrees from orthogonal to the first major surface, that is less than or equal to 1.50% across the wavelength range of from 450 nm to 900 nm, and (ii) the article exhibits an average transmittance, at an angle of incidence of 0 degrees from orthogonal to the first major surface, that is greater than or equal to 30% across the wavelength range of from 300 nm to 350 nm.

According to an Aspect 5 of the present disclosure, the article of any one of Aspects 1-4 is presented, wherein (a) the article exhibits an average transmittance through the article, at an angle of incidence of 0 degrees from orthogonal to the first major surface, that is less than or equal to 10.0% across the wavelength range of from 300 nm to 350 nm, and (b) the article exhibits an average first-surface reflectance, at an angle of incidence of 5 degrees from orthogonal to the first major surface, that is (i) less than or equal to 0.50% across one or more of the following wavelength ranges: from 550 nm to 600 nm, from 600 nm to 650 nm, from 650 nm to 700 nm, and from 750 nm to 800 nm, and (ii) less than or equal to 2.0% across one or more of the following wavelength ranges: from 800 nm to 850 nm, from 850 nm to 900 nm, from 900 nm to 950 nm, from 950 nm to 1000 nm, and from 1000 nm to 1050 nm.

According to an Aspect 6 of the present disclosure, the article of any one of Aspects 1-5 is presented, wherein the article exhibits an average transmittance through the article, at an angle of incidence of 0 degrees from orthogonal to the first major surface, that is (i) less than or equal to 10% across the wavelength range of from 250 nm to 300 nm, (i) less than or equal to 50% across the wavelength range of from 300 nm to 350 nm, and (iii) greater than or equal to 93.0% across the wavelength range of from 400 nm to 1100 nm.

According to an Aspect 7 of the present disclosure, the article of any one of Aspects 1-6 is presented, wherein the article exhibits an average transmittance through the article, at an angle of incidence of 0 degrees from orthogonal to the first major surface, that is less than or equal to 80% across one or more of the following wavelength ranges: from 1200 nm to 1300 nm, from 1300 nm to 1400 nm, from 1400 nm to 1500 nm, from 1500 nm to 1600 nm, from 1600 nm to 1700 nm, from 1700 nm to 1800 nm.

According to an Aspect 8 of the present disclosure, the article of any one of Aspects 1-7 is presented, wherein the article exhibits an average transmittance through the article, at an angle of incidence of 0 degrees from orthogonal to the first major surface, that is less than or equal to 83% across all of the following wavelength ranges: from 1200 nm to 1300 nm, from 1300 nm to 1400 nm, from 1400 nm to 1500 nm, from 1500 nm to 1600 nm, from 1600 nm to 1700 nm, from 1700 nm to 1800 nm.

According to an Aspect 9 of the present disclosure, the article of any one of Aspects 1-8 is presented, wherein (i) the article exhibits an average first-surface reflectance, at an angle of incidence of 5 degrees from orthogonal to the first major surface, that is less than or equal to 1.0% across the wavelength range of from 450 nm to 900 nm, (ii) the article exhibits an average transmittance through the article, at an angle of incidence of 0 degrees from orthogonal to the first major surface, that is greater than or equal to 94.0% across the wavelength range of from 450 nm to 900 nm, and (iii) the article exhibits an average transmittance through the article, at an angle of incidence of 0 degrees from orthogonal to the first major surface, that is less than or equal to 25% across the wavelength range of from 250 nm to 350 nm.

According to an Aspect 10 of the present disclosure, the article of any one of Aspects 1-9 is presented, wherein the article exhibits an average first-surface reflectance, at an angle of incidence of 5 degrees from orthogonal to the first major surface, that is less than or equal to 1.15% across all of the following wavelength ranges: from 700 nm to 750 nm, from 750 nm to 800 nm, from 800 nm to 850 nm, and from 850 nm to 900 nm.

According to an Aspect 11 of the present disclosure, the article of any one of Aspects 1-10 is presented, wherein (i) the article exhibits an average first-surface reflectance, at an angle of incidence of 5 degrees from orthogonal to the first major surface, that is less than or equal to 0.50% across all of the following wavelength ranges: from 550 nm to 600 nm, from 600 nm to 650 nm, from 650 nm to 700 nm, and from 750 nm to 800 nm, and (ii) the article exhibits an average first-surface reflectance, at an angle of incidence of 5 degrees from orthogonal to the first major surface, that is less than or equal to 2.00% across all of the following wavelength ranges: from 800 nm to 850 nm, from 850 nm to 900 nm, from 900 nm to 950 nm, and from 950 nm to 1000 nm.

According to an Aspect 12 of the present disclosure, the article of any one of Aspects 1-11 further comprises a surface modifying layer upon the multilayer coating.

According to an Aspect 13 of the present disclosure, the article of Aspect 12 is presented, wherein the surface modifying layer comprises an anti-soiling coating which includes a single layer of a silane disposed on a silicon containing inorganic matrix layer.

According to an Aspect 14 of the present disclosure, an article comprises (A) a substrate comprising a glass composition or a glass-ceramic composition, a first major surface, and a second major surface, the first major surface and the second major surface facing in generally opposite directions; and (B) a multilayer coating disposed on the first major surface of the substrate, the multilayer coating comprising (1) a plurality of multilayer sections, each of the multilayer sections disposed successively with respect to one another on the first major surface, each multilayer section comprising at least two layers, wherein (a) both of the at least two layers exhibit unique indices of refraction, (b) the layer of the at least two layers disposed closer to the first major surface of the substrate is one of (i) an LRI layer exhibiting a low index of refraction within a range of from 1.35 to 1.60, (ii) an MLRI layer exhibiting a medium-low index of refraction that is within a range of from 1.61 to 1.84, and (iii) an MHRI layer exhibiting a medium-high index of refraction that is within a range of from 1.85 to 2.10, and (c) the layer of the at least two layers disposed farther from the first major surface of the substrate exhibits a greater index of refraction than the closer layer and is one of (i) an MLRI layer, (ii) an MHRI layer, and (iii) an HRI layer exhibiting a high index of refraction that is within a range of from 2.11 to 2.70, (2) a total coating thickness that is within a range of from 100 nm to 10000 nm, and (3) a capping LRI layer disposed over the plurality of multilayer sections, the capping LRI layer exhibiting the low index of refraction and comprising a capping layer thickness, wherein (i) a sum of the layer thicknesses of the LRI layers and the capping LRI layer is within a range of from 50% to 90% of the total coating thickness, and (ii) at least 10% of a 300 nm thick topmost portion of the total coating thickness is made of material forming one or more of the HRI layers, MHRI layers, or both.

According to an Aspect 15 of the present disclosure, the article of the Aspect 14 is presented, wherein the plurality of multilayer sections numbers within a range of from 3 to 15.

According to an Aspect 16 of the present disclosure, the article of any one of the Aspects 14-15 is presented, wherein the total coating thickness of the multilayer coating further is within a range of from 250 nm to 1500 nm.

According to an Aspect 17 of the present disclosure, the article of any one of the Aspects 14-16 is presented, wherein the multilayer coating comprises at least three layers, each of the at least three exhibiting unique indices of refraction.

According to an Aspect 18 of the present disclosure, the article of any one of the Aspects 14-17 is presented, wherein (i) each of the LRI layers and the capping LRI layer comprise one or more of SiO₂, doped SiO₂, Al₂O₃, GeO₂, SiO, AlOₓN_{y}, SiOₓN_{y}, SiᵤAl_{y}OₓN_{y}, MgO, MgF₂, BaF₂, CaF₂, DyF₃, YbF₃, YF₃, and CeF₃, (ii) each of the MLRI layers comprises one or more of AlSixOyNz, AlOₓN_{y}, and SiOₓN_{y}, (iii) each of the MHRI layers comprises one or more of AlSiₓO_{y}N_{z}, SiNₓ, AlOₓN_{y}, and SiOₓN_{y}, and (iv) each of the HRI layers comprises one or more of Nb₂O₅, AlN, SiNₓ, AlOₓN_{y}, SiOₓN_{y}, TiO₂, and CeO₂.

According to an Aspect 19 of the present disclosure, the article of the Aspects 18 is presented, wherein the HRI layer of at least one of the plurality of multilayer sections comprises CeO₂.

According to an Aspect 20 of the present disclosure, the article of any one of the Aspects 14-19 is presented, wherein the layer thickness of each layer of the plurality of multilayer sections is within a range from 8 nm to 220 nm.

According to an Aspect 21 of the present disclosure, the article of any one of the Aspects 14-20 is presented, wherein (i) each of the plurality of multilayer sections of the multilayer coating further comprises a section thickness, and (ii) each of the section thicknesses are within a range of from 20 nm to 260 nm.

According to an Aspect 22 of the present disclosure, the article of any one of the Aspects 14-21 is presented, wherein the glass composition or the glass-ceramic composition of the substrate comprises one or more of elemental titanium, ionic titanium, and a titanium oxide.

According to an Aspect 23 of the present disclosure, the article of any one of the Aspects 14-22 is presented, wherein the glass composition or the glass-ceramic composition, either as analyzed after formation or as batched before formation, comprises (in mol %, on an oxide basis): from 69.0 to 79.0 SiO₂; from 6.40 to 7.40 Al₂O₃; from 0.50 to 4.50 CaO; from 5.0 to 10 Na₂O; from 1.0 to 5.0 K₂O; and from 1.0 to 4.0 TiO₂.

According to an Aspect 24 of the present disclosure, the article of the Aspect 23 is presented, wherein the glass composition or the glass-ceramic composition, either as analyzed after formation or as batched before formation, further comprises (in mol %) from 0.10 to 1.0 CeO₂.

According to an Aspect 25 of the present disclosure, the article of any one of Aspects 14-24 is presented, wherein the glass composition or the glass-ceramic composition of the substrate comprises one or more of elemental cerium, ionic cerium, and a cerium oxide.

According to an Aspect 26 of the present disclosure, the article of any one of Aspects 14-25 is presented, wherein the substrate further comprises (i) one or more regions of compressive stress and (ii) a thickness between the first major surface and the second major surface, the substrate thickness within a range of from 0.050 mm and 5 mm.

According to an Aspect 27 of the present disclosure, the article of any one of Aspects 14-26 is presented, wherein (a) the multilayer coating of the article exhibits a maximum hardness that is greater than or equal to 5 GPa measured at any depth within an indentation depth range of (i) from 0 to 500 nm into the total coating thickness or (ii) from 0 to the total coating thickness, whichever of (i) and (ii) is smaller, according to a Berkovich Indenter Hardness Test, (b) the article exhibits an average first-surface reflectance, at an angle of incidence of 5 degrees from orthogonal to the first major surface, that is less than or equal to 1.10% across one or more of the following wavelength ranges: from 700 nm to 750 nm, from 750 nm to 800 nm, from 800 nm to 850 nm, and from 850 nm to 900 nm, and (c) the article exhibits an average transmittance through the article, at an angle of incidence of 0 degrees from orthogonal to the first major surface, (i) that is less than or equal to 12.0% across the wavelength range of from 250 nm to 300 nm, and (ii) that is less than or equal to 50% across the wavelength range of from 300 nm to 350 nm.

According to an Aspect 28 of the present disclosure, a solar panel comprises: (1) a solar panel comprises: (1) an article comprising: (a) a substrate comprising a first major surface and a second major surface, the first major surface and the second major surface facing in generally opposite directions; and (b) a multilayer coating disposed on the first major surface of the substrate, the multilayer coating comprising a total coating thickness; and (2) one or more photovoltaic (PV) cells disposed beneath the second major surface of the substrate, wherein the multilayer coating of the article exhibits a maximum hardness that is greater than or equal to 5 GPa measured at any depth within an indentation depth range of (i) from 0 to 500 nm into the total coating thickness or (ii) from 0 to the total coating thickness, whichever of (i) and (ii) is smaller, according to a Berkovich Indenter Hardness Test, wherein the article exhibits an average first-surface reflectance, at an angle of incidence of 5 degrees from orthogonal to the first major surface, that is less than or equal to 1.10% across one or more of the following wavelength ranges: from 700 nm to 750 nm, from 750 nm to 800 nm, from 800 nm to 850 nm, and from 850 nm to 900 nm, and wherein the article exhibits an average transmittance through the article, at an angle of incidence of 0 degrees from orthogonal to the first major surface, that is (i) less than or equal to 12.0% across the wavelength range of from 250 nm to 300 nm and (ii) less than or equal to 50% across the wavelength range of from 300 nm to 350 nm.

According to an Aspect 29 of the present disclosure, the solar panel of the Aspect 28 further comprises: a backsheet, wherein, the one or more PV cells is disposed between the backsheet and the article.

According to an Aspect 30 of the present disclosure, an insulated glass unit comprises: (1) a first outer pane comprising an article comprising: (a) a substrate comprising a first major surface and a second major surface, the first major surface and the second major surface facing in generally opposite directions; and (b) a multilayer coating disposed on the first major surface of the substrate, the multilayer coating comprising a total coating thickness; and (2) a second outer pane separated from the first outer pane by a space; wherein (a) the multilayer coating of the article exhibits a maximum hardness that is greater than or equal to 5 GPa measured at any depth within an indentation depth range of (i) from 0 to 500 nm into the total coating thickness or (ii) from 0 to the total coating thickness, whichever of (i) and (ii) is smaller, according to a Berkovich Indenter Hardness Test, (b) the article exhibits an average first-surface reflectance, at an angle of incidence of 5 degrees from orthogonal to the first major surface, that is less than or equal to 1.10% across one or more of the following wavelength ranges: from 700 nm to 750 nm, from 750 nm to 800 nm, from 800 nm to 850 nm, and from 850 nm to 900 nm, and (c) the article exhibits an average transmittance through the article, at an angle of incidence of 0 degrees from orthogonal to the first major surface, that is (i) less than or equal to 12.0% across the wavelength range of from 250 nm to 300 nm and (ii) is less than or equal to 50% across the wavelength range of from 300 nm to 350 nm.

According to an Aspect 31 of the present disclosure, an article comprises: (1) a substrate comprising a first major surface, a second major surface, the first major surface and the second major surface facing in generally opposite directions, and a substrate thickness between the first major surface and the second major surface; and (2) a multilayer coating disposed on the first major surface of the substrate, the multilayer coating comprising a total coating thickness, each of the layers comprising a layer thickness, wherein (a) the article exhibits an average transmittance through the article, at an angle of incidence of 0 degrees from orthogonal to the first major surface, that is less than or equal 20.0% across the wavelength range of from 300 nm to 350 nm, (b) the article exhibits an average transmittance through the article, at an angle of incidence of 0 degrees from orthogonal to the first major surface, that is greater than or equal to 94.8% across the wavelength range of from 450 nm to 900 nm, (c) the article exhibits an average transmittance through the article, at an angle of incidence of 0 degrees from orthogonal to the first major surface, that is less than or equal to 80% across any one or more of the following wavelength ranges: from 1300 nm to 1400 nm, from 1400 nm to 1500 nm, from 1500 nm to 1600 nm, from 1600 nm to 1700 nm, and from 1700 nm to 1800 nm, (d) the article exhibits an average first-surface reflectance, at an angle of incidence of 5 degrees from orthogonal to the first major surface, that is greater than or equal to 40.0% across the wavelength range of from 300 nm to 350 nm, and (e) the multilayer coating of the article exhibits a maximum hardness that is greater than or equal to 5 GPa measured at any depth within an indentation depth range of (i) from 0 to 500 nm into the total coating thickness or (ii) from 0 to the total coating thickness, whichever of (i) and (ii) is smaller, according to a Berkovich Indenter Hardness Test.

According to an Aspect 32 of the present disclosure, the article of Aspect 31 is presented, wherein the article exhibits an ultraviolet cutoff wavelength within a range of from 320 nm to 390 nm.

According to an Aspect 33 of the present disclosure, the article of Aspect 32 is presented, wherein the ultraviolet cutoff wavelength that the article exhibits is within a range of from 340 nm to 380 nm.

According to an Aspect 34 of the present disclosure, the article of any one of Aspects 31-33 is presented, wherein (a) the average transmittance through the article that the article exhibits, at an angle of incidence of 0 degrees from orthogonal to the first major surface, is less than or equal to 10% across the wavelength range of from 300 nm to 350 nm and (b) the average transmittance through the article that the article exhibits, at an angle of incidence of 0 degrees from orthogonal to the first major surface, is greater than or equal to 95.0% across the wavelength range of from 450 nm to 900 nm.

According to an Aspect 35 of the present disclosure, the article of any one of Aspects 31-34 is presented, wherein the article exhibits an average transmittance through the article, at an angle of incidence of 0 degrees from orthogonal to the first major surface, that is less than or equal to 5.0% across the wavelength range of from 300 nm to 350 nm.

According to an Aspect 36 of the present disclosure, the article of any one of Aspects 31-35 is presented, wherein (i) the article exhibits an average first-surface reflectance, at an angle of incidence of 5 degrees from orthogonal to the first major surface, that is less than or equal to 0.9% across the wavelength range of from 450 nm to 900 nm and (ii) the article exhibits an average first-surface reflectance, at an angle of incidence of 5 degrees from orthogonal to the first major surface, that is greater than or equal to 45% across the wavelength range of from 300 nm to 350 nm.

According to an Aspect 37 of the present disclosure, the article of any one of Aspects 31-36 is presented, wherein the article exhibits a UV cut sharpness (85-5) that is less than or equal to 75 nm.

According to an Aspect 38 of the present disclosure, the article of any one of Aspects 31-37 is presented, wherein the total coating thickness of the multilayer coating is less than 450 nm.

According to an Aspect 39 of the present disclosure, the article of any one of Aspects 31-38 is presented, wherein the total coating thickness of the multilayer coating is within a range of from 250 nm to 1000 nm.

According to an Aspect 40 of the present disclosure, the article of any one of Aspects 31-39 is presented, wherein the substrate thickness is within a range of from 20 μm to 200 μm.

According to an Aspect 41 of the present disclosure, the article of any one of Aspects 31-40 is presented, wherein the multilayer coating further comprises (1) a plurality of multilayer sections, each of the multilayer sections disposed successively with respect to one another on the first major surface, each multilayer section comprising at least two layers, wherein (a) both of the at least two layers exhibit unique indices of refraction, (b) the layer of the at least two layers disposed closer to the first major surface of the substrate is one of (i) an LRI layer exhibiting a low index of refraction within a range of from 1.35 to 1.60, (ii) an MLRI layer exhibiting a medium-low index of refraction that is within a range of from 1.61 to 1.84, and (iii) an MHRI layer exhibiting a medium-high index of refraction that is within a range of from 1.85 to 2.10, and (c) the layer of the at least two layers disposed farther from the first major surface of the substrate exhibits a greater index of refraction than the closer layer and is one of (i) an MLRI layer, (ii) an MHRI layer, and (iii) an HRI layer exhibiting a high index of refraction that is within a range of from 2.11 to 2.70, and (2) a capping LRI layer disposed over the plurality of multilayer sections, the capping LRI layer exhibiting the low index of refraction and comprising a capping layer thickness.

According to an Aspect 42 of the present disclosure, the article of Aspect 41 is presented, wherein for the multilayer section disposed furthest from the first major surface of the substrate, the layer thickness of the layer of the at least two layers that exhibits the greater index of refraction than the other of the at least two layers is greater than or equal to 80 nm.

According to an Aspect 43 of the present disclosure, the article of any one of Aspects 41-42 is presented, wherein (i) at least one of the plurality of multilayer sections comprise a layer of SiO₂ and a layer of SiNₓ, (ii) at least one of the plurality of multilayer sections comprise a layer of SiO₂ and a layer of TiO₂, and (iii) all of the multilayer sections that comprise a layer of SiO₂ and a layer of TiO₂ are disposed closer to the first major surface of the substrate than the at least one of the plurality of multilayer sections that comprise a layer of SiO₂ and a layer of SiNₓ.

According to an Aspect 44 of the present disclosure, the article of Aspect 43 is presented, wherein the multilayer coating is free of a layer of TiO₂ layered in direct contact with a layer of SiNₓ.

According to an Aspect 45 of the present disclosure, the article of any one of Aspects 43-44 is presented, wherein a layer of SiO₂ having a layer thickness of less than 2.0 nm is disposed between, and in direct contact with, a layer of SiNₓ and a layer of TiO₂.

According to an Aspect 46 of the present disclosure, the article of any one of Aspects 41-45 is presented, wherein at least 30% of a 300 nm thick topmost portion of the total coating thickness is made of material forming one or more of the HRI layers, MHRI layers, or both.

According to an Aspect 47 of the present disclosure, the article of any one of Aspects 41-46 is presented, wherein at least 50% of a 300 nm thick topmost portion of the total coating thickness is made of SiNₓ.

According to an Aspect 48 of the present disclosure, the article of any one of Aspects 41-47 is presented, wherein (i) each of the LRI layers and the capping LRI layer comprise one or more of SiO₂, doped SiO₂, Al₂O₃, GeO₂, SiO, AlOₓN_{y}, SiOₓN_{y}, SiᵤAl_{y}OₓN_{y}, MgO, MgF₂, BaF₂, CaF₂, DyF₃, YbF₃, YF₃, and CeF₃, (ii) each of the MLRI layers comprises one or more of Al₂O₃, AlSiₓO_{y}N_{z}, AlOₓN_{y}, and SiOₓN_{y}, (iii) each of the MHRI layers comprises one or more of AlSiₓO_{y}N_{z}, SiNₓ, AlOₓN_{y}, and SiOₓN_{y}, and (iv) each of the HRI layers comprises one or more of Nb₂O₅, AlN, SiNₓ, AlOₓN_{y}, SiOₓN_{y}, ZrO₂, TiO₂, and CeO₂.

According to an Aspect 49 of the present disclosure, the article of any one of Aspects 41-48 is presented, wherein the plurality of multilayer sections numbers within a range of from 3 to 15.

According to an Aspect 50 of the present disclosure, the article of any one of the Aspects 41-49 is presented, wherein the total coating thickness of the multilayer coating further is within a range of from 250 nm to 1500 nm.

According to an Aspect 51 of the present disclosure, the article of any one of the Aspects 41-50 is presented, wherein the multilayer coating comprises at least three layers, each of the at least three layers exhibits unique indices of refraction.

According to an Aspect 52 of the present disclosure, the article of any one of the Aspects 41-51 is presented, wherein the HRI layer of at least one of the plurality of multilayer sections comprises CeO₂.

According to an Aspect 53 of the present disclosure, the article of any one of the Aspects 41-52 is presented, wherein the layer thickness of each layer of the plurality of multilayer sections is within a range from 8 nm to 220 nm.

According to an Aspect 54 of the present disclosure, the article of any one of the Aspects 41-53 is presented, wherein (i) each of the plurality of multilayer sections of the multilayer coating further comprises a section thickness, and (ii) each of the section thicknesses are within a range of from 20 nm to 260 nm.

According to an Aspect 55 of the present disclosure, the article of any one of Aspects 31-54 is presented, wherein the substrate comprises a glass composition or a glass-ceramic composition.

According to an Aspect 56 of the present disclosure, the article of Aspect 55 is presented, wherein the glass composition or the glass-ceramic composition of the substrate comprises one or more of elemental titanium, ionic titanium, and a titanium oxide.

According to an Aspect 57 of the present disclosure, the article of any one of the Aspects 55-56 is presented, wherein the glass composition or the glass-ceramic composition, either as analyzed after formation or as batched before formation, comprises (in mol %, on an oxide basis): from 69.0 to 79.0 SiO₂; from 6.40 to 7.40 Al₂O₃; from 0.50 to 4.50 CaO; from 5.0 to 10 Na₂O; from 1.0 to 5.0 K₂O; and from 1.0 to 4.0 TiO₂.

According to an Aspect 58 of the present disclosure, the article of any one of Aspects 55-57 is presented, wherein the glass composition or the glass-ceramic composition, either as analyzed after formation or as batched before formation, further comprises (in mol %) from 0.10 to 1.0 CeO₂.

According to an Aspect 59 of the present disclosure, the article of any one of Aspects 55-58 is presented, wherein the glass composition or the glass-ceramic composition of the substrate comprises one or more of elemental cerium, ionic cerium, and a cerium oxide.

According to an Aspect 60 of the present disclosure, the article of any one of Aspects 55-59 is presented, wherein the substrate further comprises (i) one or more regions of compressive stress and (ii) a thickness between the first major surface and the second major surface, the thickness within a range of from 0.050 mm and 5 mm.

According to an Aspect 61 of the present disclosure, the article of any one of Aspects 31-60 further comprises a surface modifying layer upon the multilayer coating.

According to an Aspect 62 of the present disclosure, the article of Aspect 61 is presented, wherein the surface modifying layer comprises an anti-soiling coating which includes a single layer of a silane disposed on a silicon containing inorganic matrix layer.

According to an Aspect 63 of the present disclosure, the article of any one of Aspects 31-62 is presented, wherein the article exhibits an average first-surface reflectance, at an angle of incidence of 5 degrees from orthogonal to the first major surface, that is less than or equal to 1.10% across one or more of the following wavelength ranges: from 700 nm to 750 nm, from 750 nm to 800 nm, from 800 nm to 850 nm, and from 850 nm to 900 nm.

According to an Aspect 64 of the present disclosure, the article of any one of Aspects 31-63 is presented, wherein the average first-surface reflectance, at an angle of incidence of 5 degrees from orthogonal to the first major surface, that the article exhibits is less than or equal to 0.9% across all of the following wavelength ranges: from 500 nm to 550 nm, from 550 nm to 600 nm, from 600 nm to 650 nm, from 650 nm to 700 nm, from 700 nm to 750 nm, from 750 nm to 800 nm, and from 800 nm to 850 nm.

According to an Aspect 65 of the present disclosure, the article of any one of Aspects 31-64 is presented, wherein the article exhibits an average first-surface reflectance, at an angle of incidence of 5 degrees from orthogonal to the first major surface, that is less than or equal to 0.8% across the wavelength range of from 450 nm to 900 nm.

According to an Aspect 66 of the present disclosure, the article of any one of Aspects 31-65 is presented, wherein the article exhibits an average first-surface reflectance, at an angle of incidence of 5 degrees from orthogonal to the first major surface, that is (i) less than or equal to 0.50% across one or more of the following wavelength ranges: from 550 nm to 600 nm, from 600 nm to 650 nm, from 650 nm to 700 nm, and from 750 nm to 800 nm, and (ii) less than or equal to 2.0% across one or more of the following wavelength ranges: from 800 nm to 850 nm, from 850 nm to 900 nm, from 900 nm to 950 nm, from 950 nm to 1000 nm, and from 1000 nm to 1050 nm.

According to an Aspect 67 of the present disclosure, the article of any one of Aspects 31-66 is presented, wherein the article exhibits an average transmittance through the article, at an angle of incidence of 0 degrees from orthogonal to the first major surface, that is (i) less than or equal to 10% across the wavelength range of from 250 nm to 300 nm, and (ii) greater than or equal to 93.0% across the wavelength range of from 400 nm to 1100 nm.

According to an Aspect 68 of the present disclosure, the article of any one of Aspects 31-67 is presented, wherein the article exhibits an average transmittance through the article, at an angle of incidence of 0 degrees from orthogonal to the first major surface, that is less than or equal to 75% across one or more of the following wavelength ranges: from 1200 nm to 1300 nm, from 1300 nm to 1400 nm, from 1400 nm to 1500 nm, from 1500 nm to 1600 nm, from 1600 nm to 1700 nm, from 1700 nm to 1800 nm.

According to an Aspect 69 of the present disclosure, the article of any one of Aspects 31-68 is presented, wherein the article exhibits an average transmittance through the article, at an angle of incidence of 0 degrees from orthogonal to the first major surface, that is less than or equal to 83% across all of the following wavelength ranges: from 1200 nm to 1300 nm, from 1300 nm to 1400 nm, from 1400 nm to 1500 nm, from 1500 nm to 1600 nm, from 1600 nm to 1700 nm, from 1700 nm to 1800 nm.

According to an Aspect 70 of the present disclosure, the article of any one of Aspects 31-69 is presented, wherein (i) the article exhibits an average first-surface reflectance, at an angle of incidence of 5 degrees from orthogonal to the first major surface, that is less than or equal to 0.7% across the wavelength range of from 450 nm to 900 nm and (ii) the article exhibits an average transmittance through the article, at an angle of incidence of 0 degrees from orthogonal to the first major surface, that is less than or equal to 25% across the wavelength range of from 250 nm to 350 nm.

According to an Aspect 71 of the present disclosure, the article of any one of Aspects 31-70 is presented, wherein the article exhibits an average first-surface reflectance, at an angle of incidence of 5 degrees from orthogonal to the first major surface, that is less than or equal to 1.15% across all of the following wavelength ranges: from 700 nm to 750 nm, from 750 nm to 800 nm, from 800 nm to 850 nm, and from 850 nm to 900 nm.

According to an Aspect 72 of the present disclosure, the article of any one of Aspects 31-71 is presented, wherein (i) the article exhibits an average first-surface reflectance, at an angle of incidence of 5 degrees from orthogonal to the first major surface, that is less than or equal to 0.60% across all of the following wavelength ranges: from 550 nm to 600 nm, from 600 nm to 650 nm, from 650 nm to 700 nm, and from 750 nm to 800 nm, and (ii) the article exhibits an average first-surface reflectance, at an angle of incidence of 5 degrees from orthogonal to the first major surface, that is less than or equal to 2.00% across all of the following wavelength ranges: from 800 nm to 850 nm, from 850 nm to 900 nm, from 900 nm to 950 nm, and from 950 nm to 1000 nm.

According to an Aspect 73 of the present disclosure, a solar panel comprises: (1) a solar panel comprises: (1) the article of any one of Aspects 31-72; and (2) one or more photovoltaic (PV) cells disposed beneath the second major surface of the substrate.

According to an Aspect 74 of the present disclosure, the solar panel of the Aspect 73 further comprises: a backsheet, wherein, the one or more PV cells is disposed between the backsheet and the article.

According to an Aspect 75 of the present disclosure, an insulated glass unit comprises: (1) a first outer pane comprising the article of any one of Aspects 31-72; and (2) a second outer pane separated from the first outer pane by a space.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiments, and together with the description serve to explain principles and operation of the various embodiments.

### BRIEF DESCRIPTION OF THE DRAWINGS

In the Drawings:

FIG. 1 is a graph plotting photon flux from the Sun as a function of wavelength for both (i) when measured outside of the Earth's atmosphere (AMOG) and (ii) when measured at Earth's surface (AM1.5G), illustrating that while the highest percentage of the photons from the Sun is associated with the wavelength range of from 450 nm to 900 nm and is thus usable by photovoltaic cells, a significant percentage of the photons is associated with either damaging ultraviolet (e.g., 200 nm to 350 nm) or unusable but heat generating infrared wavelength ranges (e.g., 1100 nm to 1800 nm);

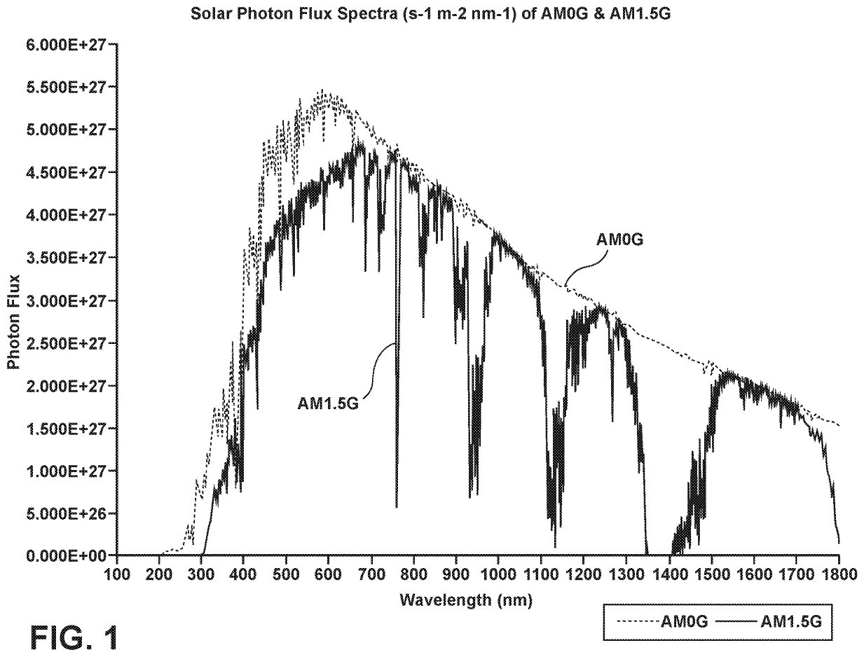

FIG. 2 is a perspective view of an article of the present disclosure, illustrating a substrate and a multilayer coating disposed on a first major surface of the substrate;

FIG. 3 is a cross-sectional view taken along the line III-III of FIG. 2, illustrating the multilayer coating including a plurality of multilayer sections, each of which includes at least two of (i) an LRI layer exhibiting a low index of refraction, (ii) an MLRI layer exhibiting a medium-low index of refraction, (iii) an MHRI layer exhibiting a medium-high index of refraction, and (iv) an HRI layer exhibiting a high index of refraction;

FIG. 4 is a perspective view of a solar panel that incorporates the article of FIG. 2 as a cover glass over one or more photovoltaic (PV) cells, illustrating the photons from the Sun having to transmit through the article to reach the PV cells;

FIG. 5 is an overhead plan view of the solar panel of FIG. 4, illustrating the article and the PV cells forming part of a package held by a frame;

FIG. 6 is a cross-sectional view of the solar panel taken through line VI-VI of FIG. 5, illustrating the package held within a C-Channel of the frame;

FIG. 7 is a magnified view of area VII of FIG. 6, illustrating a first polymer layer and a second polymer layer encapsulating the PV cells, which are together sandwiched between the article and a backsheet, with the multilayer coating of the article facing an external environment;

FIG. 8 is a front elevation view of an insulated glass unit incorporating the article of the present disclosure as a first outer pane;

FIG. 9 is an elevation view of a cross-section of the insulated glass unit taken through line IX-IX of FIG. 8, illustrating the multilayer coating of the article facing outward to an external environment and the insulated glass unit further including a second outer pane, which is a laminate and separated from the first outer pane by a space;

FIG. 10, pertaining to Examples 1 and 2, is a graph plotting transmittance through an article of the present disclosure with a multilayer coating as a function of wavelength, illustrating that the articles exhibit relatively high average transmittance across the visible wavelength range but relatively low average transmittance within the ultraviolet wavelength range;

FIG. 11, again pertaining to Examples 1 and 2, is a graph plotting reflectance off the article at the multilayer coating side as a function of wavelength, illustrating that the articles exhibit relatively low average reflectance across the visible wavelength range but relatively high average reflectance within the ultraviolet wavelength range;

FIG. 12, pertaining to Examples 3-5, is a graph plotting transmittance through an article of the present disclosure with a multilayer coating as a function of wavelength, illustrating that the articles exhibit relatively high average transmittance across the visible wavelength range but relatively low average transmittance within the ultraviolet wavelength range;

FIG. 13, again pertaining to Examples 3-5, is a graph plotting reflectance off the article at the multilayer coating side as a function of wavelength, illustrating that the articles exhibit relatively low average reflectance across the visible wavelength range but relatively high average reflectance within the ultraviolet wavelength range;

FIG. 14, pertaining to Examples 6 and 7, is a graph plotting transmittance through an article of the present disclosure with a multilayer coating as a function of wavelength, illustrating that the articles exhibit relatively high average transmittance across the visible wavelength range but relatively low average transmittance within the ultraviolet wavelength range;

FIG. 15, again pertaining to Examples 6 and 7, is a graph plotting reflectance off the article at the multilayer coating side as a function of wavelength, illustrating that the articles exhibit relatively low average reflectance across the visible wavelength range but relatively high average reflectance within the ultraviolet wavelength range;

FIG. 16, pertaining to Examples 8 and 9, is a graph plotting transmittance through an article of the present disclosure with a multilayer coating as a function of wavelength, illustrating that the articles exhibit relatively high average transmittance across the visible wavelength range but relatively low average transmittance within the ultraviolet wavelength range;

FIG. 17, again pertaining to Examples 8 and 9, is a graph plotting reflectance off the article at the multilayer coating side as a function of wavelength, illustrating that the articles exhibit relatively low average reflectance across the visible wavelength range but relatively high average reflectance within the ultraviolet wavelength range;

FIG. 18, pertaining to Example 10, is a graph plotting transmittance through an article of the present disclosure with a multilayer coating as a function of wavelength, illustrating that the article exhibits relatively high average transmittance across the visible wavelength range but relatively low average transmittance within the ultraviolet wavelength range;

FIG. 19, again pertaining to Example 10, is a graph plotting reflectance off the article at the multilayer coating side as a function of wavelength, illustrating that the article exhibits relatively low average reflectance across the visible wavelength range but relatively high average reflectance within the ultraviolet wavelength range;

FIG. 20, pertaining to Examples 11 and 12, is a graph plotting 2-surface transmittance as a function of wavelength, according to aspects of the disclosure;

FIG. 21, pertaining to Examples 11 and 12, is a graph first surface reflectance as a function of wavelength, according to aspects of the disclosure; and

FIG. 22, pertaining to Examples 11 and 12, as well as Comparative Example 4, is a graph plotting transmittance as a function of wavelength, according to aspects of the disclosure.

### DETAILED DESCRIPTION

Reference will now be made in detail to the present preferred embodiments, examples of which are illustrated in the accompanying drawings. Whenever possible, the same reference numerals will be used throughout the drawings to refer to the same or like parts.

Article 10 with a Multilayer Coating 14

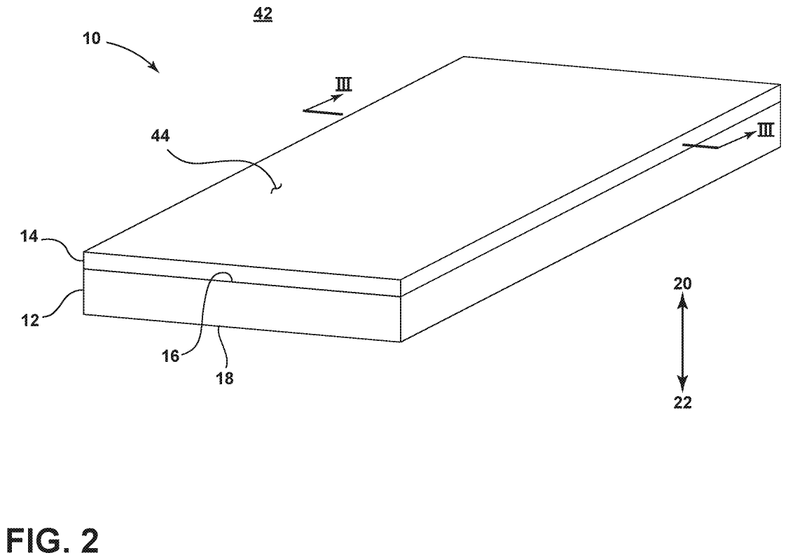

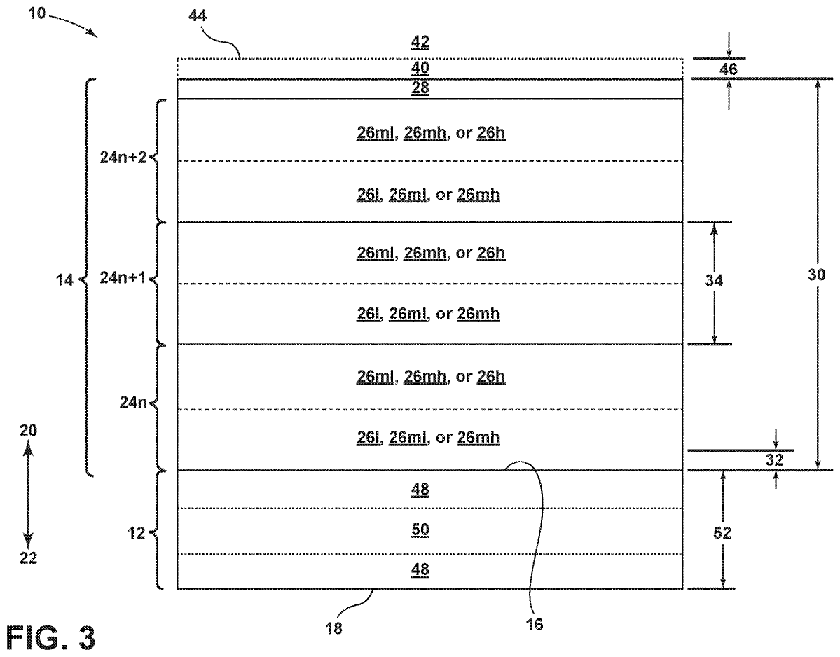

Referring to FIGS. 2 and 3, an article 10 includes a substrate 12 and a multilayer coating 14 disposed on the substrate 12. The substrate 12 includes a first major surface 16 and a second major surface 18. The first major surface 16 and the second major surface 18 face in generally opposite directions 20, 22. The first major surface 16 and the second major surface 18 can both be substantially planar but need not be, but rather can be at least partially curved. The multilayer coating 14 is disposed on the first major surface 16.

The multilayer coating 14 includes a plurality of multilayer sections 24. Each of the multilayer sections 24 is disposed successively with respect to one another on the first major surface 16. For example, the multilayer section 24n is disposed first on the first major surface 16 of the substrate 12, the multilayer section 24n+1 is then disposed on the multilayer section 24n, the multilayer section 24n+2 is disposed on the multilayer section 24n+1, and so on. In embodiments, the plurality of multilayer sections 24 of the multilayer coating 14 numbers within a range of from 3 to 15. For example, the multilayer coating 14 can include 3, 4, 5, 6, 7, 8, 9, 10, 11, 12, 13, 14, or 15 multilayer sections 24.

Each multilayer section 24 includes at least two layers 26. The at least two layers 26 can be distinguishable from one another via, for example, their respective compositions and/or optical properties (e.g., index of refraction). Indeed, both of the at least two layers 26 exhibit unique indices of refraction—the index of refraction that one layer 26 exhibits is different than the index of refraction that the other layer 26 of the at least two layers 26 exhibits. All of the multilayer sections 24 need not have the same number of layers 26. However, all of the multilayer sections 24 can have the same number of layers 26. In embodiments, the multilayer coating 14 has less than 20 layers.

The layer 26 of the at least two layers 26 disposed closest to the first major surface 16 is an LRI layer 26l, an MLRI layer 26ml, or an MHRI layer 26mh. The layer 26 of the at least two layers 26 disposed farther from the first major surface 16 of the substrate 12 exhibits a greater index of refraction than the closer layer 26 and is one of an MLRI layer 26ml, an MHRI layer 26mh, or an HRI layer 26h. The multilayer coating 14 further includes a capping LRI layer 28 that is disposed over the plurality of multilayer sections 24. The LRI layer 26l of the multilayer section 24 disposed closest to the first major surface 16 of the substrate 12 can be disposed directly on the first major surface 16 of the substrate 12, which can improve adhesion of the multilayer coating 14 onto the substrate 12.

The LRI layer 26l and the capping LRI layer 28 both exhibit a low index of refraction that is within a range of from 1.35 to 1.60. For example, the low index of refraction can be 1.35, 1.38, 1.40, 1.42, 1.44, 1.46, 1.48, 1.50, 1.52, 1.54, 1.56, 1.58, 1.60, or within any range bound by any two of those values (e.g., from 1.40 to 1.50, from 1.44 to 1.58, and so on).

The MLRI layer 26ml exhibits a medium-low index of refraction that is within a range of from 1.61 to 1.84. For example, the medium-low index of refraction can be 1.61, 1.62, 1.64, 1.66, 1.68, 1.70, 1.72, 1.74, 1.76, 1.78, 1.80, 1.82, 1.84, or within any range bound by any two of those values (e.g., from 1.66 to 1.78, from 1.70 to 1.82, and so on).

The MHRI layer 26mh exhibits a medium-high index of refraction that is within a range of from 1.85 to 2.10. For example, the medium-high index of refraction can be 1.85, 1.86, 1.88, 1.90, 1.92, 1.94, 1.96, 1.98, 2.00, 2.02, 2.04, 2.06, 2.08, 2.10, or within any range bound by any two of those values (e.g., from 1.86 to 1.98, from 1.90 to 2.06, and so on).

The HRI layer 26h exhibits a high index of refraction that is within a range of from 2.11 to 2.70. For example, the high index of refraction can be 2.11, 2.15, 2.20, 2.25, 2.30, 2.40, 2.45, 2.50, 2.55, 2.60, 2.65, 2.70, or within any range bound by any two of those values (e.g., from 2.15 to 2.20, from 2.15 to 2.40, and so on). All indices of refraction are as determined in accordance with ASTM E1967-19, where the wavelength of measurement is 589 nm.

The multilayer coating 14 has a total coating thickness 30. In embodiments, the total coating thickness 30 is within a range of from 100 nm to 10000 nm. For example, the total coating thickness 30 can be 100 nm, 200 nm, 250 nm, 300 nm, 400 nm, 450 nm, 500 nm, 600 nm, 700 nm, 800 nm, 900 nm, 1000 nm, 1100 nm, 1200 nm, 1300 nm, 1400 nm, 2000 nm, 2500 nm, 3000 nm, 3500 nm, 4000 nm, 4500 nm, 5000 nm, 5500 nm, 6000 nm, 6500 nm, 7000 nm, 7500 nm, 8000 nm, 8500 nm, 9000 nm, 9500 nm, 10000 nm, or within any range bound by any two of those values (e.g., from 250 nm to 1000 nm, from 250 nm to 1500 nm, from 3000 nm to 8500 nm, from 4000 nm to 6500 nm, and so on). The total coating thickness 30 can be less than 100 nm or greater than 10000 nm. The total coating thickness can be less than 450 nm. Reducing the total coating thickness 30 can reduce cost, while increasing the total coating thickness 30 can increase optical performance, hardness, or durability, and the criteria could be balanced, as within the ranges set forth above.

In embodiments, some, or each, of the plurality of multilayer sections 24 include only two layers 26. For example, the multilayer section 24 could include an MHRI layer 26mh disposed over an LRI layer 26l. As another example, the multilayer section 24 could include an HRI layer 26h disposed over an LRI layer 26l. As yet another example, the multilayer section 24 could include an HRI layer 26h disposed over an MHRI layer 26mh. As yet another example, the multilayer section 24 could include an MLRI layer 26ml disposed over an LRI layer 26l. Various combinations can be found in the same multilayer coating 14.

In embodiments, the multilayer coating 14 includes at least three layers 26, each of which exhibit unique indices of refraction. For example, in embodiments, at least one of the multilayer sections 24 includes at least three layers 26, each of which exhibit unique indices of refraction. In embodiments, at least one of the multilayer sections 24 includes exactly three layers 26, each of which exhibit unique indices of refraction. For example, such a multilayer section 24 can have exactly three layers 26 having an order of an LRI layer 26l disposed closest to the substrate 12, an MLRI layer 26ml disposed furthest from the substrate 12, and an MHRI layer 26mh sandwiched between the LRI layer 26l and the MLRI layer 26ml.

The compositions of the LRI layers 26l, the capping LRI layers 28, the MLRI layers 26ml, the MHRI layer 26mh, and the HRI layers 26h are not particularly limited but can be any composition that provides the low index of refraction associated with the layer. In embodiments, the LRI layers 26l, and the capping LRI layer 28 considered individually, are or include one or more of SiO₂, doped SiO₂, Al₂O₃, GeO₂, SiO, AlOₓN_{y}, SiOₓN_{y}, SiᵤAl_{y}OₓN_{y}, MgO, MgF₂, BaF₂, CaF₂, DyF₃, YbF₃, YF₃, and CeF₃. Doped SiO₂ means SiO₂ doped with a small amount of one or more other oxides, such as 1 mol % to 10 mol % of Al₂O₃ or ZrO₂. Doped SiO₂ may also include nitrogen doping, which can also be represented as SiOₓN_{y}. Doping the SiO₂ can enhance durability. The compositions are not particularly limited as long as the relative indices of refraction are exhibited.

In embodiments, each of the MLRI layers 26ml is or includes one or more of Al₂O₃, AlSiₓO_{y}N_{z}, AlOₓN_{y}, and SiOₓN_{y}. In embodiments, each of the MHRI layers 26mh is or includes one or more of AlSiₓO_{y}N_{z}, SiNₓ, AlOₓN_{y}, and SiOₓN_{y}. In embodiments, each of the HRI layers 26h is or includes one or more of Nb₂O₅, AlN, SiNₓ, AlOₓN_{y}, SiOₓN_{y}, ZrO₂, TiO₂, and CeO₂. In embodiments, at least one of the HRI layers 26h, MHRI layers 26mh, or MLRI layers 26ml is or includes SiOₓN_{y}. In embodiments, the HRI layer 26h of at least one of the plurality of multilayer sections 24 comprises CeO₂. The chemical formulas that use a letter subscript (e.g., AlOₓN_{y}) are atomic fraction formulas. In an atomic fraction formula, each of the subscript values can range from 0 to 1, the sum of all subscript values is 1, and the balance of the composition is the first element in the material. Thus, in the example of AlOₓN_{y}, x+y=1, and the balance is Al. If the atomic fraction of oxygen (denoted by x) is 0.1, then the atomic fraction of nitrogen (denoted by y) is 0.9. As another example, the value for the subscript “u” in SiᵤAlₓO_{y}N_{z} can be zero, and in such a case the material can be described as AlOₓN_{y} because the balance is the first remaining element, in this case Al, after the exclusion of Si with u being 0. The values of the subscripts for any particular atomic fraction formula cannot all be 0 such that it would result in a pure elemental form (e.g., pure silicon, pure aluminum metal, oxygen gas, etc.). Atomic fraction descriptions are described in many general textbooks and atomic fraction descriptions are often used to describe alloys. The index of refraction that AlOₓN_{y} and SiOₓN_{y} each exhibit is tunable depending on the concentrations of Al, Si, O, and N. The concentration of any one or more of Si, Al, O, and N can be varied to increase or decrease the index of refraction.

In embodiments, the multilayer coating 14 includes (a) at least one multilayer section 24 that includes both a layer 26 of SiO₂ (or some other LRI layer 26l) and a layer of SiNₓ (e.g., as the MHRI layer 26mh or HRI layer 26h) and (ii) at least one multilayer section 24 that includes both a layer 26 of SiO₂ (or some other LRI layer 26l) and a layer of TiO₂ (as the HRL layer 26h). In such embodiments, all of the multilayer sections 24 that include a layer 26 of SiO₂ (or some other LRI layer 26l) and a layer 26 of TiO₂ can be (but need not be) disposed closer to the first major surface 16 of the substrate 12 than the at least one sections 24 of the plurality of multilayer sections 24 that includes a layer 26 of SiO₂ (or some other LRI layer 26l) and a layer 26 of SiNₓ. Stated another way, the section(s) 24 of the multilayer coating 14 that include a layer 26 of TiO₂ can be sandwiched between the substrate 12 and other section(s) 24 of the multilayer coating 14 that include a layer 26 of SiNₓ. So positioning the layers 26 of TiO₂ under the section(s) 24 that include layers 26 of SiNₓ protect the layers 26 of TiO₂ from damage, while allowing the layers 26 of TiO₂ to provide UV block and optical benefits. In such instances, the multilayer coating 14 can be (but need not be) free of a layer 26 of TiO₂ in direct contact with a layer 26 of SiNₓ. The placement of a layer 26 of TiO₂ in direct contact with a layer 26 of SiNₓ can cause the formation of trace titanium nitride species at SiNₓ—TiO₂ interfaces, which can interfere with desired optical properties that the article 10 exhibits. To reduce or prevent the formation of such trace titanium nitride species at SiNₓ—TiO₂ interfaces, the multilayer coating 14 can include a layer 26 of SiO₂ having a layer thickness 32 that is less than 2.0 nm (e.g., 0.5 nm to 2.0 nm) disposed between and in direct contact with the layer 26 of TiO₂ and the layer 26 of SiNₓ.

Each of the layers 26 of the plurality of multilayer sections 24 has a layer thickness 32. Each of the layer thicknesses 32 can be unique. In embodiments, the layer thickness 32 of each layer of the plurality of multilayer sections 24 is within a range from 0.5 nm to 220 nm. For example, the layer thickness 32 can each individually be 0.5 nm, 0.6 nm, 0.7 nm, 0.8 nm, 0.9 nm, 1.0 nm, 2.0 nm, 3.0 nm, 4.0 nm, 5.0 nm, 6.0 nm, 7.0 nm, 8.0 nm, 9.0 nm, 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 110 nm, 120 nm, 130 nm, 140 nm, 150 nm, 160 nm, 170 nm, 180 nm, 190 nm, 200 nm, 210 nm, 220 nm, or within any range bound by any two of those values (e.g., from 25 nm to 110 nm, from 40 nm to 100 nm, and so on). In embodiments, the layer thickness 32 of any given of the layers 26 can be less than 2.0 nm.

Each of the plurality of multilayer sections 24 of the multilayer coating 14 has a section thickness 34. The section thickness 34 is the sum of the at least two layers 26 forming the multilayer section 24. Each of the section thicknesses 34 can be unique. In embodiments, each of the section thicknesses 34 are within a range of from 20 nm to 260 nm. For example, each of the section thicknesses 34 individually can be 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 100 nm, 210 nm, 220 nm, 230 nm, 240 nm, 250 nm, 260 nm, or within any range bound by any two of those values (e.g., from 30 nm to 100 nm, from 50 nm to 200 nm, and so on).

The total coating thickness 30 and each of the layer thicknesses 32 are all measured orthogonal to the first major surface 16 of the substrate 12. The measurements can be made by taking a cross-section of the article 10, capturing an image thereof with a scanning electron microscope, and then measuring the various layers. Alternatively, the values can be determined from parameters utilized during the deposition process used to form the multilayer coating 14.

In embodiments, a sum of the layer thicknesses 32 of the LRI layers 26l and the capping LRI layer 28 is within a range of from 50% to 90% of the total coating thickness 30. For example, the sum of the sum of the layer thicknesses 32 of the LRI layers 26l and the capping LRI layer 28 can be 50%, 51%, 52%, 53%, 54%, 55%, 56%, 57%, 58%, 59%, 60%, 61%, 62%, 63%, 64%, 65%, 66%, 67%, 68%, 59%, 70%, 71%, 72%, 73%, 75%, 75%, 76%, 77%, 78%, 79%, 80%, 81%, 82%, 83%, 84%, 85%, 86%, 87%, 88%, 89%, 90%, or within any range bound by any two of those values (e.g., from 64% to 82%, from 56% to 74%, and so on). The sum of the layer thicknesses 32 of the LRI layers 26l and the capping LRI layer 28 can be less than 50% or greater than 90%, in other embodiments.

The reflectance (and thus the transmittance) that article 10 exhibits is a function of the layer thicknesses 32 considered individually, the low indices of refraction of the capping LRI layer 28 and the LRI layers 26l included (if any), the medium-low indices of refraction of the MLRI layers 26ml included (if any), the medium-high indices of refraction of the MHRI layers 26mh included (if any), and the high indices of refraction of the HRI layers 26h included (if any), as a collection. Without being bound by theory, the multilayer coating 14 manipulates reflectance at any particular wavelength by utilizing principles of interference and wave behavior of electromagnetic radiation. The layer thicknesses 32 are engineered to achieve destructive interference for a specific wavelength range or ranges (e.g., from 250 nm to 300 nm, 300 nm to 350 nm, or from 250 nm to 350 nm, among other options), thus increasing reflectance within that range or ranges, while minimizing reflectance and thus permitting high transmittance for another specific wavelength range or ranges (e.g., from 450 nm to 900 nm). In general, the layer thickness 32 for any given layer 26 within any given multilayer section 24 will be different than the layer thickness 32 of all other layers 26 within all other multilayer sections 24 of the multilayer coating 14. However, the layer thickness 32 of any given layer 26 can be the same or repeated for one or more other layers 26 within the same multilayer section, or within different multilayer sections 24, of the multilayer coating 14.

In embodiments, the article 10 further includes a surface-modifying layer 40 upon the multilayer coating 14. The surface-modifying layer 40 is disposed further from the first major surface 16 of the substrate 12 than the multilayer coating 14 and is exposed to an external environment 42. The surface-modifying layer 40 forms a prime surface 44 of the article 10, which is exposed to the external environment 42. If the article 10 does not include the surface-modifying layer 40, then the capping LRI layer 28 of the multilayer coating 14 forms the prime surface 44 of the article 10.

The surface-modifying layer 40 changes a physical property or other behavior of the article 10. For example, a surface-modifying layer 40 can modify one or more of a water contact angle, an oleic contact angle, a visibility of a fingerprint (e.g., simulated fingerprint), and/or an ability to remove a fingerprint (e.g., by wiping). As such, the surface-modifying layer 40 can be a fingerprint hiding coating, an anti-fingerprint hiding coating, or an easy-to-clean coating. Examples of a suitable anti-fingerprint hiding layer and easy-to-clean coatings are described in the following U.S. patent applications: U.S. Patent Application Publication No. 2014/0113083, published on Apr. 24, 2014, entitled “Process for Making of Glass Article 10 with Optical and Easy-to-Clean Coatings”; U.S. Provisional Patent Application No. 63/603,156, filed on Nov. 28, 2023, entitled “Coated Articles with a Surface-modifying Layer and Methods of Making the Same”; U.S. Provisional Patent Application No. 63/546,775, filed on Nov. 1, 2023, entitled “Coated Articles with a Planarization Layer and a Surface-modifying Layer and Methods of Making the Same”; and U.S. Non-Provisional patent application Ser. No. 18/528,916, filed on Dec. 5, 2023, entitled “Coated Articles with an Anti-Fingerprint Coating or Surface-modifying Layer and Methods of Making the Same”, all of which are incorporated herein by reference in their entirety. The easy-to-clean coating can be a fluorine-containing material. Alternatively, the easy-to-clean coating (anti-fingerprint coating) can include a partial silica-like network having a ratio of Si—O—Si bonds to Si atoms in the coating from about 2 to about 3, the coating is fluorine-free, and the coating further comprises an alkyl silane at the exterior surface and bonded to Si—O groups in the anti-fingerprint coating. The easy-to-clean coating may have a thickness in the range from about 5 nm to about 50 nm and may include known materials such as fluorinated or non-fluorinated silanes. The easy-to-clean coating may alternately or additionally comprise a low-friction coating or surface treatment. Exemplary low-friction coating materials may include diamond-like carbon, silanes (e.g., fluorosilanes), phosphonates, alkenes, and alkynes. The surface-modifying layer 40 can exhibit hydrophobic and oleophobic properties.

In embodiments, the surface-modifying layer 40 is or includes an anti-soiling coating that includes a single layer of a silane such as the materials listed in the Table 1.5 below. The article 10, when used as a solar cover glass, as further described below, or for other applications, may benefit from the anti-soiling coating. This anti-soiling coating may be a hydrophobic, hydrophilic, or an omniphobic coating. The preference of hydrophobic vs hydrophilic can depend on local weather conditions, for example humidity, rain frequency, airborne dust or sand prevalence, and snow frequency. All embodiments of the multilayer coating 14 set forth in the Examples can have a thin hydrophobic or hydrophilic coating added to their top surface (e.g., over the capping LRI layer 28). In recent work, we have identified primer layers which enhance the durability of silane-containing coatings, which may include fluorosilane materials, as well as fluorine-free versions of these coatings which may be preferred from a cost and environmental standpoint (eliminating the use of PFAS). Example silane-containing materials, which may be fluorine-free are shown in the table below.

TABLE 1.5

| | Hydrophobic/ | Water CA | DIM CA | OA CA | Polar | Dispersive | Total |
|---|---|---|---|---|---|---|---|
| Name | Hydrophilic | (°) | (°) | (°) | (mN/m) | (mN/m) | (mN/m) |
| Methoxy terminated | Hydrophobic | 100.9 ± 0.3 | 72.1 ± 1.0 | 44.3 ± 0.9 | 1.1 ± 0.2 | 22.1 ± 1.0 | 23.3 ± 1.2 |
| PDMS | | | | | | | |
| Octadecyltrimethox | Hydrophobic | 105.7 ± 0.3 | 67.5 ± 0.8 | 47.5 ± 0.5 | 1.7 ± 0.2 | 24.9 ± 0.5 | 26.6 ± 0.7 |
| ysilane | | | | | | | |
| Methoxy terminated | Hydrophilic | 26.7 ± 5.2 | 40.8 ± 2.3 | 17.5 ± 1.5 | 37.9 ± 3.0 | 28.6 ± 1.2 | 66.5 ± 4.2 |
| PEO (9-12) | | | | | | | |
| Methoxy terminated | Hydrophilic | 41.7 ± 4.0 | 31.9 ± 2.5 | 13.5 ± 1.3 | 25.8 ± 2.8 | 34.2 ± 1.2 | 60.0 ± 4.0 |
| PEO (6-9) | | | | | | | |
| Hydroxy terminated | Hydrophilic | 54.4 ± 2.1 | 45.6 ± 1.7 | 13.5 ± 0.3 | 20.6 ± 1.6 | 29.2 ± 0.9 | 49.7 ± 2.6 |
| PEO (9-12) | | | | | | | |
| (11- | Hydrophobic | 91.6 ± 1.4 | 30.4 ± 1.2 | 20.5 ± 1.2 | 0.4 ± 0.2 | 43.9 ± 0.8 | 44.3 ± 0.8 |
| Bromoundecyl)trich | | | | | | | |
| lorosilane | | | | | | | |
| Ethoxy terminated | Hydrophobic | 92.2 ± 1.7 | 64.8 ± 2.2 | 41.4 ± 1.4 | 3.2 ± 1.4 | 21.5 ± 1.5 | 24.7 ± 2.9 |
| PDMS | | | | | | | |
| Chlorine terminated | Hydrophobic | 92.8 ± 0.3 | 65.3 ± 1.1 | 43.3 ± 0.9 | 2.8 ± 0.2 | 23.5 ± 0.7 | 26.3 ± 0.8 |
| PDMS | | | | | | | |
| Triethoxysilylethyl | Hydrophobic | 96.5 ± 0.4 | 66.7 ± 0.2 | 40.9 ± 0.5 | 1.8 ± 0.3 | 23.1 ± 0.3 | 24.9 ± 0.6 |
| terminated PDMS | | | | | | | |
| 1,8- | Hydrophobic | 98.0 ± 0.7 | 61.9 ± 1.0 | 21 ± 0.3 | 4.1 ± 0.4 | 26.9 ± 0.2 | 31 ± 0.5 |
| Bis(chlorodimethyls | | | | | | | |
| ily1)octane | | | | | | | |
| Chloropropyltrimeth | Hydrophobic | 99 ± 3.5 | 61.9 ± 0.5 | 32.9 ± 0.8 | 5 ± 3.0 | 26.9 ± 0.2 | 31.9 ± 3.2 |
| oxysilane | | | | | | | |

The anti-soiling coating may comprise a single layer of a silane coating material, such as the materials listed in the table above. In addition, the anti-soiling coating may also be comprised of a hydrophobic or hydrophilic surface modification on top of an optical silicon containing inorganic matrix layer. This combination of matrix layer plus surface functionalization has been shown to increase durability of the surface functionalization under repeated abrasion-type events. Surface functionalization includes perfluorinated, hydrocarbon, polydimethylsiloxane (PDMS), polyethylene glycol (PEG), or polyethylene oxide (PEO) surface modifier to create a hydrophobic or hydrophilic surface. Both have been shown to aid in preventing dust buildup in photovoltaic cell applications. See M. S. Mozumder et al. Solar Energy Materials and Solar Cells 189 (2019) 75-102. Functionalization can occur by condensation of reactive groups on the surface modifier to the silanol groups in the matrix. Suitable reactive head groups include mono, di or tri functional alkoxysilyl groups, silyl halides, or amino silyl groups. Functionalization can be simultaneously with the matrix or sequentially depositing the matrix and the functionalization. The thickness of the functionalization is thin, 0.5 to 10 nm. Suitable hydrophobic functionalizations include fluorinated materials such as perfluorpolyether silanes, perfluoralkylsilanes and perfluorinated polyoctahedralsilsesquioxanes, hydrocarbons including alkyls, alkenes and aromatics with six to 36 carbons, and polyorganosiloxanes including polydimethylsiloxane, polydiethylsiloxane, polydiphenylsioloxane, and polysiloxanes with mixtures of methyl, ethyl and phenyl groups. Suitable hydrophilic functionalization includes PEG-silanes, PEG-PDMS diblock copolymers, and PEO functional silanes.

The inorganic matrix can be comprised of silicon containing materials with smooth surface, a high density of silanols and an elastic modulus from about 15 to 70 GPa. The thickness of the silicon containing matrix layer can be in the range of 5 nm to 200 nm. Suitable silica matrix layers include films deposited from HSQ or polysilazanes by spin casting, dip coating, or spraying and cured either thermally or with UV or ion bombardment. Additionally, suitable silicon containing matrix layers include films deposited by physical vapor deposition (PVD) using ion assisted evaporation of organic modified cage silsesquioxane. The organic substituent at the vertices of the polyoctahedral silisequioxane promote vaporization and forms a leaving group after reaction with the ion beam. Suitable organic groups include vinyl, methyl, phenyl, isobutyl, and dimethylsilyl groups. Suitable ion sources include both gridless sources such as End-Hall sources, gridded source, and RF and ICP plasma sources. All these matrix materials are smooth, exhibiting a surface roughness (Ra)<0.5 nm when deposited upon a substrate with equal or lesser roughness. In addition, these materials exhibit a refractive index near silica, a high silanol concentration, and an elastic modulus of from 15 GPa to 70 GPa. In addition to increasing surface hydroxyl content, which can improve silane molecule bonding, these inorganic matrix materials can reduce the high frequency roughness of the coated surfaces, which we have found to improve abrasion resistance and lifetime of the hydrophobic, hydrophilic, or omniphobic silane-containing anti-soiling coating.

As an alternative or in addition to the above described inorganic matrix materials, the surface of the multilayer coating 14 (e.g., the capping LRI layer 28) of this invention may be treated by a water- or hydrogen-containing plasma, which serves to reduce the high frequency roughness and increase the hydroxyl and/or silanol density on the coating surface, improving silane molecule bonding and improving abrasion resistance and lifetime of the hydrophobic, hydrophilic, or omniphobic silane-containing anti-soiling coating.

Omniphobic coatings may include those that have a low contact angle hysteresis, meaning a small difference between advancing and receding contact angles. Some of these coatings have also been described as “liquid-like” coatings. These coatings have been shown to readily induce sliding of ice, mud, and other types of soiling from surfaces using only the force of gravity and a slight angular incline to the surface (which is common in solar panel applications).

Such coatings may exhibit contact angle hysteresis of less than 5 degrees, less than 2 degrees, or even less than 1 degree. Examples of such omniphobic coatings include PDMS polymer brushes with carefully controlled grafting and thickness parameters, e.g. having a brush thickness from about 2-6 nm, or between 3-5 nm, as described in Zhao, X., Khatir, B., Mirshahidi, K., Yu, K., Kizhakkedathu, J. N., & Golovin, K. (2021), “Macroscopic evidence of the liquidlike nature of nanoscale polydimethylsiloxane brushes,” ACS nano, 15 (8), 13559-13567.

In embodiments, the surface-modifying layer 40 has a thickness 46 in the range from 1 nm to 40 nm. For example, the thickness 46 of the surface-modifying layer 40 can be 1 nm, 2 nm, 5 nm, 8 nm, 10 nm, 12 nm, 15 nm, 18 nm, 20 nm, 22 nm, 25 nm, 28 nm, 30 nm, 32 nm, 35 nm, 38 nm, 40 nm, or within any range bound by any two of those values (e.g., from 2 nm to 32 nm, from 5 nm to 38 nm, and so on). The thickness 46 of the surface-modifying layer 40 is sufficiently thin so as to not suboptimally affect the transmittance and reflectance properties that the article 10 would otherwise exhibit due to the multilayer coating 14 without the surface-modifying layer 40. It may be advantageous, when the surface-modifying layer 40 is an anti-soiling coating, for the thickness 46 to be within a range of from 1 nm to 10 nm. In reference to the Examples below, the layer thickness 32 of the capping LRI layer 28 can be reduced by an amount equal to the thickness 56 of the surface-modifying layer 40 to compensate therefore.

The multilayer coating 14, and the surface-modifying layer 40 if included, may be formed using various deposition methods such as vacuum deposition techniques, for example, chemical vapor deposition (e.g., plasma enhanced chemical vapor deposition (PECVD), low-pressure chemical vapor deposition, atmospheric pressure chemical vapor deposition, and plasma-enhanced atmospheric pressure chemical vapor deposition), physical vapor deposition (e.g., reactive or nonreactive sputtering or laser ablation, including metal mode reactive sputtering), thermal or e-beam evaporation, and/or atomic layer deposition. Liquid-based methods may also be used such as spraying, dipping, spin coating, or slot coating (for example, using sol-gel materials). Where vacuum deposition is utilized, inline processes may be used to form the multilayer coating 14 (and the surface-modifying layer 40 if included) in one deposition run. In some instances, the vacuum deposition can be made by a linear PECVD source. Generally, vapor deposition techniques may include a variety of vacuum deposition methods which can be used to produce thin films. For example, physical vapor deposition uses a physical process (such as heating or sputtering) to produce a vapor of material, which is then deposited on the object which is coated.

In particular, TiO₂ may be deposited either as an amorphous, semi-crystalline, or polycrystalline material, where the crystalline phases may comprise anatase or rutile. The TiO₂ may be semi-crystalline or polycrystalline having at least 50% rutile by volume or at least 80% rutile by volume. The rutile phase has been shown to have the highest hardness among TiO₂ phases. Example thin film deposition techniques for depositing rutile have been described in, for example, Pradhan, Swati S., et al. “Low temperature stabilized rutile phase TiO₂ films grown by sputtering.” Thin Solid Films 520.6 (2012): 1809-1813, and also in Guillén, C., J. Montero, and J. Herrero. “Anatase and rutile TiO₂ thin films prepared by reactive DC sputtering at high deposition rates on glass and flexible polyimide substrates.” Journal of Materials Science 49 (2014): 5035-5042. Both references are incorporated herein by reference in their entireties.

Further, SiNₓ and SiOₓN_{y} can be deposited as amorphous materials with high hardness and high index of refraction through reactive sputtering or metal-mode reactive sputtering.

The substrate 12 can be made of any material so long as the article 10 exhibits the various properties mentioned herein, particularly transmittance. In embodiments, the substrate 12 has a glass composition or a glass-ceramic composition. The substrate 12 having the glass-ceramic composition differs from the substrate 12 having the glass composition in that the former has both an amorphous phase and a crystalline phase, while the latter includes an amorphous phase but no substantial crystalline phase.

The substrate 12 having the glass composition can be formed from any suitable process. In embodiments where the substrate 12 takes the form of a sheet, the substrate 12 can be formed via a float process or an overflow downdrawn fusion process, although other processes are envisioned. In the float process, a glass ribbon is formed on the surface of a molten metal bath, e.g., a molten tin bath, and after being removed from the bath is passed through an annealing lehr before being cut into individual sheets. In the case of the fusion process, a glass ribbon is formed by passing molten glass around the outside of a forming structure (known in the art as an “isopipe”) to produce two layers 26 of glass that fuse together at the bottom of the forming structure (the root of the isopipe) to form the glass ribbon. The glass ribbon is pulled away from the isopipe by pulling rollers and cooled as it moves vertically downward through a temperature-controlled housing. At, for example, the bottom of the housing (bottom of the draw), individual glass sheets are cut from the ribbon.

The glass-ceramic composition can be formed from the glass composition through a suitable heat-treatment process or formed directly where crystallization occurs upon casting and does not require a separate heat-treatment process. Suitable glass-ceramic compositions are set forth in Table 2 below.

TABLE 2

| composition | | | |
|---|---|---|---|
| (mol %) | Ex. A | Ex. B | Ex. C |
| SiO₂ | 70.39 | 70.77 | 68.98 |
| Al₂O₃ | 4.21 | 4.21 | 4.03 |
| P₂O₅ | 0.85 | 0.85 | 1.01 |
| Li₂O | 21.16 | 21.98 | 22.31 |
| Na₂O | 1.50 | 0.06 | 0.07 |
| K₂O | 0.13 | 0.07 | 0.07 |
| ZrO₂ | 1.71 | 2.01 | 2.78 |
| CaO | 0.01 | 0.02 | 0.71 |
| Fe₂O₃ | 0.02 | 0.02 | 0.02 |
| HfO₂ | 0.02 | 0.02 | 0.03 |
| SnO₂ | 0.01 | 0.01 | 0.01 |

After heat-treatment, the glass-ceramics resulting from the above compositions contain the following phase assemblages presented in Table 3.

TABLE 3

| | | lithium disilicate | petalite | |
|---|---|---|---|---|
| | Glass | (Li₂Si₂O₅) | (LiAlSi₄O₁₀) | other phases |
| Material | (wt %) | (wt %) | (wt %) | (wt %) |
| Ex. A | 19 | 43 | 38 | <2% |
| Ex. B | 12 | 45 | 43 | <2% |
| Ex. C | 13 | 44 | 42 | <2% |

Suitable glass compositions include an alkali aluminosilicate glass composition, a soda lime glass composition, an alkaline earth aluminosilicate glass composition, or an alkaline earth boro-aluminosilicate glass composition. Other glass compositions are envisioned however, and the list is not meant to be exhaustive.

The alkali aluminosilicate glass composition, if included as part of the substrate 12, includes alumina, at least one alkali metal, and SiO₂, such as greater than 50 mol % SiO₂. The alkali aluminosilicate glass composition can include at least 58 mol % SiO₂, and in still other embodiments at least 60 mol % SiO₂, wherein the ratio (Al₂O₃+B₂O₃)/Σ_{modifiers})>1, and where in the ratio the components are expressed in mol % and the modifiers are alkali metal oxides. A more particular example includes from 58 mol % to 72 mol % SiO₂; from 9 mol % to 17 mol % Al₂O₃; from 2 mol % to 12 mol % B₂O₃; from 8 mol % to 16 mol % Na₂O, and from 0 to 4 mol % K₂O, wherein the ratio ((Al₂O₃+B₂O₃)/Σ_{modifiers})>1.

The soda lime glass composition, if included as part of the substrate 12, includes SiO₂, Na₂O, and CaO. An example soda lime composition includes 72 mol % SiO₂, 1 mol % Al₂O₃, 14 mol % Na₂O, 4 mol % MgO, and 7 mol % CaO.

The alkaline earth boro-aluminosilicate glass composition, if included as part of the substrate 12, includes an alkaline earth metal, B₂O₃, alumina, and silica. An example alkaline earth boro-aluminosilicate glass composition comprises, on an oxide basis, from 65 wt % to 75 wt % SiO₂, from 7 wt % to 13 wt % Al₂O₃, from 5 wt % to 15 wt % B₂O₃, from 5 wt % to 15 wt % CaO, from 0 to 5 wt % BaO, from 0 to 3 wt % MgO, and from 0 to 5 wt % SrO. Another example alkaline earth boro-aluminosilicate glass composition comprises, on an oxide basis, from 65 mol % to 70 mol % SiO₂, from 3.0 mol % to 4.0 mol % B₂O₃, from 12.0 mol % to 13.0 mol % Al₂O₃, from 13.0 mol % to 14.0 mol % Na₂O, >0 mol % K₂O, from 1.7 mol % to 2.7 mol % MgO, >0 mol % Fe₂O₃, and >0 mol % SnO₂. Yet another example alkaline earth boro-aluminosilicate glass composition comprises, on an oxide basis, from 70 mol % to 80 mol % SiO₂, from 12.0 mol % to 13.0 mol % B₂O₃, from 3.0 mol % to 4.0 mol % Al₂O₃, from 5.0 mol % to 6.0 mol % Na₂O, from 0.5 mol % to 1.5 mol % K₂O, from 1.3 mol % to 2.3 mol % MgO, >0 mol % CaO, >0 mol % BaO, >0 mol % Fe₂O₃, >0 mol % TiO₂, >0 mol % SnO₂, and >0 mol % ZnO₂. These glass compositions are exemplary only and not intended to be limiting. Several more particular glass compositions are set forth in Table 4 below, at least several of which were also used in the modeling of various of the Examples discussed further below.

TABLE 4

| | Glass A | | Glass B | | Glass F |
|---|---|---|---|---|---|
| oxide | wt % | mol % | wt % | mol % | mol % |
| SiO₂ | 61.88 | 67.55 | 72.65 | 76.06 | 67.23 |
| B₂O₃ | 3.90 | 3.67 | 13.8 | 12.47 | 3.63 |
| Al₂O₃ | 19.69 | 12.67 | 5.65 | 3.49 | 12.72 |
| Li₂O | — | — | — | — | |
| Na₂O | 12.91 | 13.66 | 5.09 | 5.16 | 13.91 |
| K₂O | 0.02 | 0.01 | 1.39 | 0.93 | 0.01 |
| MgO | 1.43 | 2.33 | 1.12 | 1.75 | 2.34 |
| CaO | | | 0.02 | 0.01 | 0.05 |
| BaO | | | 0.004 | 0.002 | |
| Fe₂O₃ | 0.02 | 0.01 | 0.01-0.01 | 0.01-0.04 | 0.01 |
| TiO₂ | | | 0.01 | 0.01 | |
| SnO₂ | 0.22 | 0.10 | 0.15 | 0.06 | 0.09 |
| ZrO₂ | | | 0.02 | 0.01 | 0.01 |

In embodiments, the glass composition or the glass-ceramic composition of the substrate 12 includes one or more of elemental titanium, ionic titanium, and a titanium oxide. An example of such a composition includes (in mol %, on an oxide basis): from 69.0 to 79.0 SiO₂; from 6.40 to 7.40 Al₂O₃; from 0.50 to 4.50 CaO; from 5.0 to 10 Na₂O; from 1.0 to 5.0 K₂O; from 1.0 to 4.0 TiO₂, and optionally from 0.10 to 1.0 CeO₂. As the last component suggests, the glass composition or the glass-ceramic composition of the substrate 12 can include one or more of elemental cerium, ionic cerium, and a cerium oxide. All compositional ranges described in this disclosure may be either as analyzed after formation or as batched before formation. Several more particular glass compositions are set forth in Table 5 below, at least several of which were also used in the modeling of various of the Examples discussed further below.

TABLE 5

| | Glass C | Glass D | Glass E |
|---|---|---|---|
| oxide | mol % | mol % | mol % |
| SiO₂ | 74.54 | 74.29 | 74.04 |
| Al₂O₃ | 6.9 | 6.9 | 6.9 |
| MgO | 2.55 | 2.55 | 2.55 |
| CaO | 2.31 | 2.31 | 2.31 |
| Na₂O | 7.39 | 7.39 | 7.39 |
| K₂O | 3.66 | 3.66 | 3.66 |
| TiO₂ | 2.5 | 2.5 | 2.5 |
| CeO₂ | | 0.25 | 0.5 |
| SnO₂ | 0.15 | 0.15 | 0.15 |
| sum | 100 | 100 | 100 |

In embodiments, the glass composition exhibits absorption of photons associated with an ultraviolet wavelength and subsequent emittance of photons associated with a visible or a near-infrared wavelength. Such glass compositions are sometimes referred to as downshifting glass compositions. Example glass compositions that exhibit downshifting can include an oxide of europium (e.g., Eu₂O₃) and/or an oxide of cerium (e.g., CeO₂).

In embodiments, the substrate 12 further comprises a compressive stress region 48 at or near the first major surface 16. In such a circumstance, the substrate 12 can be referred to as a strengthened substrate 12. Similarly, the substrate 12 can include another compressive stress region 48 at or near the second major surface 18. In such instances, a tensile stress region 50 (e.g., a region of central tension) balances, and is disposed between the compressive stress regions 48. The compressive stress regions 48 strengthen the substrate 12. Photoelastic methods (e.g., transmission photoelasticity) can be utilized to determine whether a substrate 12 has the compressive stress regions 48. The strengthened substrate 12 can have a transparency greater than 85% in the visible spectrum from 450 nm to 900 nm.

The compressive stress regions 48 can be imparted to the substrate 12 through a variety of methods. Examples include chemical tempering (e.g., ion-exchange), thermal tempering, and lamination.

With ion-exchange, alkali cations within a source of such cations (e.g., a molten salt or “ion-exchange” bath) are exchanged with smaller alkali cations within the substrate 12. For example, potassium ions from the cation source are exchanged for sodium and/or lithium ions within the substrate 12 during ion-exchange by immersing the substrate 12 in a molten salt bath comprising a potassium salt such as, but not limited to, potassium nitrate (KNO₃). Other potassium salts that may be used in the ion-exchange process include, but are not limited to, potassium chloride (KCl), potassium sulfate (K₂SO₄), combinations thereof, and the like. The ion-exchange baths described herein may contain alkali ions other than potassium and their corresponding salts. For example, the ion-exchange bath may also include sodium salts such as sodium nitrate, sodium sulfate, sodium chloride, or the like. The exchange of the cations generates the compressive stress regions 48. The compressive stress region 48 extends from the first major surface 16 to a depth of compression (DOC) within the substrate 12 (not separately illustrated). Likewise, the other compressive stress region 48, if included, extends from the second major surface 18 to the DOC.

With thermal tempering, the substrate 12 is heated to a temperature near its softening point. The substrate 12 is then removed from the heating medium and the first major surface 16 and the second major surface 18 thereof are rapidly cooled to below the strain point of the glass of the substrate 12, e.g., the temperature at which a molten glass is deemed to have become rigid. Thus, the glass near the first major surface 16 and the second major surface 18 of the substrate 12 quickly contracts and rigidifies while the glass at an interior further away from the first major surface 16 and the second major surface 18 is still relatively more fluid and expanded. As the substrate 12 is cooled to a constant ambient temperature, the interior tries to contract more than the glass near the first major surface 16 and the second major surface 18 due to the slower cooling rate of the interior, but it is restrained by the rigidity of the glass near the first major surface 16 and the second major surface 18. Hence, when the substrate 12 temperatures reach equilibrium, the stresses at the first major surface 16 and the second major surface 18 become highly compressive and are balanced by tensile stress within the interior of the substrate 12. When the compressive stress regions 48 have been imparted by thermal tempering, the substrate 12 can be referred to as a tempered material. The tempered material can have a transparency greater than 85% in the visible spectrum from 450 nm to 900 nm.

With lamination, surface layers or skins of relatively low thermal expansion are fused to core layers of relatively high thermal expansion so that compressive stress can develop in the major surface regions as the substrate 12 (with the laminated layers) is cooled following fusion. Lamination is similar to thermal tempering in that, as the substrate 12 cools, the interior (with the relatively high thermal expansion) tries to contract but is restrained by the major surface regions (with the relatively low thermal expansion) that are contracting less upon cooling.

The substrate 12 has a thickness 52. The thickness 52 is the straight-line distance between the first major surface 16 and the second major surface 18 measured orthogonal to the first major surface 16. In embodiments, the thickness 52 of the substrate 12 is within a range of from 20 μm to 5.0 mm. In embodiments, the thickness 52 of the substrate 12 is 20 μm, 30 μm, 40 μm, 50 μm, 60 μm, 70 μm, 80 μm, 90 μm, 100 μm, 110 μm, 120 μm, 130 μm, 140 μm, 150 μm, 160 μm, 170 μm, 180 μm, 190 μm, 200 μm, 0.3 mm, 0.4 mm, 0.5 mm, 0.6 mm, 0.7 mm, 0.8 mm, 0.9 mm, 1.0 mm, 1.25 mm, 1.5 mm, 1.75 mm, 2.0 mm, 2.25 mm, 2.5 mm, 2.75 mm, 3.0 mm, 3.25 mm, 3.5 mm, 3.75 mm, 4.0 mm, 4.25 mm, 4.5 mm, 4.75 mm, or 5.0 mm, or within any range bound by any two of those values (e.g., from 20 μm to 200 μm, from 1.75 mm to 4.0 mm, from 0.4 mm to 2.75 mm, and so on). Thicknesses 52 less than 0.05 mm and greater than 5.0 mm are contemplated. The thicknesses 52 on the thinner end of the spectrum are likely to be useful for applications where reduced weight of the article 10 is beneficial, such as when the article 10 covers photovoltaic cells 106 integrated into a vehicle, satellite, or mobile device. The thickness 52 of the substrate 12 of the article 10 can be determined with a scanning electron microscope or a micrometer, among other ways.

The multilayer coating 14 exhibits beneficial physical properties. For example, the multilayer coating 14 exhibits a maximum hardness that is greater than or equal to 5 GPa measured at any depth within an indentation depth range of (i) from 0 to 500 nm into the total coating thickness or (ii) from 0 to the total coating thickness, whichever of (i) and (ii) is smaller, according to a Berkovich Indenter Hardness Test. As used herein, the “Berkovich Indenter Hardness Test” includes measuring the hardness of a material on a surface thereof by indenting the surface with a diamond Berkovich indenter. The Berkovich Indenter Hardness Test includes indenting the prime surface 44 of the article 10 with the diamond Berkovich indenter to form an indent to an indentation depth of about 100 nm, a depth of about 500 nm, or a depth of about 1000 nm and measuring the maximum hardness from this indentation along the entire indentation depth range (e.g., the maximum hardness measured at any depth in the range of from 0 to 100 nm, from 0 to 125 nm, from 0 to 500 nm, or from 0 to 1000 nm, including any sub-ranges selected from within these ranges), generally using the methods set forth in Oliver, W. C.; Pharr, G. M. An improved technique for determining hardness and elastic modulus using load and displacement sensing indentation experiments. J. Mater. Res., Vol. 7, No. 6, 1992, 1564-1583; and Oliver, W. C.; Pharr, G. M. Measurement of Hardness and Elastic Modulus by Instrument Indentation: Advances in Understanding and Refinements to Methodology. J. Mater. Res., Vol. 19, No. 1, 2004, 3-20. As used herein, hardness refers to a maximum hardness, and not an average hardness.

Typically, in nanoindentation measurement methods (such as by using a Berkovich diamond indenter) of a coating that is harder than the underlying substrate (e.g., substrate 12), the measured hardness may appear to increase initially due to development of the plastic zone at shallow indentation depths and then increases and reaches a maximum value or plateau at deeper indentation depths. Thereafter, hardness begins to decrease at even deeper indentation depths due to the effect of the underlying substrate 12. Where a substrate 12 having an increased hardness compared to the coating is utilized, the same effect can be seen; however, the hardness increases at deeper indentation depths due to the effect of the underlying substrate 12.

The indentation depth range and the hardness values at certain indentation depth range(s) can be selected to identify a particular hardness response of the multilayer coating 14 and layers thereof, described herein, without the effect of the substrate 12 underlying the multilayer coating 14. When measuring hardness of the multilayer film (when disposed on a substrate 12) with a Berkovich diamond indenter, the region of permanent deformation (plastic zone) of a material is associated with the hardness of the material. During indentation, an elastic stress field extends well beyond this region of permanent deformation. As indentation depth increases, the apparent hardness and modulus are influenced by stress field interactions with the underlying substrate 12. The substrate 12 influence on hardness occurs at deeper indentation depths (i.e., typically at depths greater than about 10% of the multilayer coating 14). Moreover, a further complication is that the hardness response requires a certain minimum load to develop full plasticity during the indentation process. Prior to that certain minimum load, the hardness shows a generally increasing trend.

At small indentation depths (which also may be characterized as small loads) (e.g., up to about 50 nm), the apparent hardness of a material appears to increase dramatically versus indentation depth. This small indentation depth regime does not represent a true metric of hardness but instead, reflects the development of the aforementioned plastic zone, which is related to the finite radius of curvature of the indenter. At intermediate indentation depths, the apparent hardness approaches maximum levels. At deeper indentation depths, the influence of the substrate 12 becomes more pronounced as the indentation depths increase. Hardness may begin to drop dramatically once the indentation depth exceeds about 30% of the total thickness of the multilayer coating 14.

In embodiments, the maximum hardness that the multilayer coating 14 exhibits over an indentation depth range of (i) from 0 to 500 nm into the total coating thickness or (ii) from 0 to the total coating thickness, whichever of (i) and (ii) is smaller, according to the Berkovich Indenter Hardness Test, is greater than or equal to 6 GPa. In embodiments, the maximum hardness that the multilayer coating 14 exhibits is greater than or equal to 7 GPa, greater than or equal to 8 GPa, greater than or equal to 9 GPa, greater than or equal to 10 GPa, greater than or equal to 11 GPa, or even greater than or equal to 12 GPa. In embodiments, the maximum hardness that the multilayer coating 14 exhibits is within a range of from 5 GPa to 15 GPa. For example, the maximum hardness that the multilayer coating 14 exhibits can be 4 GPa, 5 GPa, 6 GPa, 7 GPa, 8 GPa, 9 GPa, 10 GPa, 11 GPa, 12 GPa, 13 GPa, 14 GPa, 15 GPa, or within any range bound by any two of those values (e.g., from 7 GPa to 12 GPa, from 8 GPa to 11 GPa, and so on).

In embodiments, for the multilayer section 24 disposed furthest from the first major surface 16 of the substrate 12, the layer thickness 32 of the layer 26 of the at least two layers 26 that exhibits the greater index of refraction than the other of the at least two layers 26 is greater than or equal to 80 nm, greater than or equal to 100 nm, or even greater than or equal to 120 nm (e.g., 300 nm), or within any range bound by any two of those values (e.g., from 80 nm to 145 nm, from 80 nm to 300 nm, and so on). Stated another way, for the multilayer section 24 disposed beneath the capping LRI layer 28, the higher index layer 26 (e.g., MHRI layer 26mh or HRI layer 26h) can have a layer thickness 32 that is greater than or equal to 80 nm. A particular example is a layer 26 of SiNₓ under the capping LRI layer 28. A relatively thick layer 26 so positioned near the capping LRI layer 28 can increase the hardness and thus durability of the multilayer coating 14.

Similarly, at least 10% of a 300 nm thick topmost portion of the total coating thickness 30 is made of material forming one or more of the HRI layers 26h, MHRI layer 26mh, or both. By “topmost portion,” it is meant furthest away from the first major surface 16 of the substrate 12. Materials that form HRI layers 26h or MHRI layer 26mh tend to impart hardness to the multilayer coating 14. Placing such material(s) toward the prime surface 44 of the article 10 at the topmost portion of about 300 nm in thickness imparts the multilayer coating 14 with the maximum hardness described herein (e.g., greater than or equal to 5 GPa). For example, considering the 300 nm thick topmost portion of the total coating thickness 30, at least 30 nm of that 300 nm thick topmost portion is the sum of the layer thicknesses 32 of one or more HRI layers 26h, MHRI layer 26mh, or combinations thereof. In embodiments, at least 30% of a 300 nm thick topmost portion of the total coating thickness 30 is made of material forming one or more of the HRI layers 26h, MHRI layers 26mh, or both. At least 35%, at least 40%, at least 45%, or even at least 50%, of the 300 nm thick topmost portion of the total coating thickness 30 is made of material forming one or more of the HRI layers 26h, MHRI layers 26mh, or both. For example, the percentage of the 300 nm thick topmost portion of the total coating thickness 30 that is made of material forming one or more of the HRI layers 26h, MHRI layers 26mh, or both, can be 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, or within any range bound by any two of those values (e.g., from 10% to 55%, from 32% to 42%, and so on).

In addition to beneficial physical properties like hardness, the article 10 exhibits beneficial transmittance and reflectance properties. As used herein, the term “transmittance” is defined as the percentage of incident optical power within a given wavelength range transmitted through a material (e.g., the article 10, the substrate 12, or the multilayer coating 14 or portions thereof). The term “reflectance” is similarly defined as the percentage of incident optical power within a given wavelength range that is reflected from a material (e.g., the article 10, the substrate 12, or the multilayer coating 14 film or portions thereof). Transmittance and reflectance are measured using a specific linewidth. As used herein, an “average transmittance” refers to the average amount of incident optical power transmitted through a material over a defined wavelength regime. “Transmittance” as used here is generally two-surface transmittance, unless noted otherwise, which is measured for the article 10 with the multilayer coating 14 on the first major surface 16 and uncoated substrate on the second major surface 18, where the uncoated glass surface 18 will typically reduce the transmittance by about 4% (meaning the max transmittance possible as measured for these article 10 configurations, with only one surface coated with the multilayer coating 14, is typically ~96%). As used herein, an “average reflectance” refers to the average amount of incident optical power reflected by the material over the defined wavelength regime. The average first-surface reflectance is determined by removing the reflections from the second major surface 18 of the substrate 12, such as through using index-matching oils on the second major surface 18 coupled to an absorber, or other known methods. Average reflectance thus generally refers to the first-surface reflectance, unless noted otherwise.

In embodiments, the article 10 exhibits an average transmittance through the article 10, at an angle of incidence of 0 degrees from orthogonal to the first major surface, that is less than or equal to 50%, less than or equal to 40%, less than or equal to 30%, less than or equal to 20%, less than or equal to 10%, less than or equal to 5.0%, or even less than or equal to 1.0% across the wavelength range of from 300 nm to 350 nm. The article 10 exhibits relatively low transmittance across ultraviolet wavelength ranges. For example, the average transmittance through the article 10, at an angle of incidence of 0 degrees from orthogonal to the first major surface 16, that the article 10 exhibits across that ultraviolet wavelength range can be >0%, 0.02%, 0.05%, 0.10%, 0.50%, 0.60%, 0.70%, 0.80%, 0.90%, 1.00%, 1.5%, 2.0%, 2.5%, 3.0%, 3.5%, 4.0%, 4.5%, 5.0%, 5.5%, 6.0%, 6.5%, 7.0%, 7.5%, 8.0%, 8.5%, 9.0%, 9.5%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, or within any range bound by any two of those values (e.g., from >0% to 5.0%, from >0% to 2.0%, from >0% to 10%, from >0% to 20%, from >0% to 50%, and so on).

In embodiments, the article 10 exhibits an average transmittance through the article 10, at an angle of incidence of 0 degrees from orthogonal to the first major surface, that is greater than or equal to 85.0% across the wavelength range of from 450 nm to 900 nm. The article 10 exhibits relatively high transmittance across visible wavelength ranges. In embodiments, the article 10 exhibits an average transmittance through the article 10, at an angle of incidence of 0 degrees from orthogonal to the first major surface 16, that is greater than or equal to 94.0%, greater than or equal to 94.7%, greater than or equal to 94.8%, greater than 95.0%, or even greater than 95.5% across the range of from 450 nm to 900 nm. For example, the average transmittance through the article 10, at an angle of incidence of 0 degrees from orthogonal to the first major surface 16, that the article 10 exhibits across that wavelength range can be 85.0%, 86.0%, 87.0%, 88.0%, 89.0%, 90.0%, 91.0%, 92.0%, 93.0%, 94.0%, 94.1%, 94.2%, 94.3%, 94.4%, 94.5%, 94.6%, 94.7%, 94.8%, 94.9%, 95.0%, 95.1%, 95.2%, 95.3%, 95.4%, 95.5%, 95.6%, 95.7%, 95.8%, or within any range bound by any two of those values (e.g., from 94.0%, to 95.8%, from 94.1% to 95.0%, and so on).

In embodiments, the article 10 exhibits an average transmittance through the article 10, at an angle of incidence of 0 degrees from orthogonal to the first major surface, that is less than or equal to 85.0%, less than or equal to 80%, less than or equal 70%, less than or equal 60%, or even less than 50% across the wavelength range of from 1300 nm to 1400 nm. The article 10 exhibits relatively low transmittance across heat-generating infrared wavelength ranges. For example, the average transmittance through the article 10, at an angle of incidence of 0 degrees from orthogonal to the first major surface 16, that the article 10 exhibits across that wavelength range can be 45%, 46%, 47%, 48%, 49%, 50%, 51%, 52%, 53%, 54%, 55%, 56% 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85.0%, or within any range bound by any two of those values (e.g., from 70% to 85.0%, from 72% to 77%, and so on).

In embodiments, the article 10 exhibits an average transmittance through the article 10, at an angle of incidence of 0 degrees from orthogonal to the first major surface, that is less than or equal to 80%, or even less than or equal to 70%, across any one or more of the following wavelength ranges: from 1300 nm to 1400 nm, from 1400 nm to 1500 nm, from 1500 nm to 1600 nm, from 1600 nm to 1700 nm, and from 1700 nm to 1800 nm. For example, the average transmittance through the article 10, at an angle of incidence of 0 degrees from orthogonal to the first major surface 16, that article 10 exhibits across one or more of those infrared wavelength ranges can be 34%, 35%, 40%, 45%, 50%, 55%, 60%, 65%, 70%, 75%, 80%, or within any range bound by any two of those values (e.g., from 34% to 80%, from 40% to 60%, and so on). In embodiments, the article 10 exhibits an average transmittance through the article 10, at an angle of incidence of 0 degrees from orthogonal to the first major surface, that is less than or equal to 80%, or even less than or equal to 70%, across the entire wavelength range of from 1300 nm to 1800 nm.

In embodiments, the article 10 exhibits an average first-surface reflectance, at an angle of incidence of 5 degrees from orthogonal to the first major surface, that is greater than or equal to 25.0%, greater than or equal to 30%, greater than or equal to 40%, greater than or equal to 50%, or greater than or equal to 60% across the wavelength range of from 250 nm to 300 nm. In embodiments, the article exhibits an average first-surface reflectance, at an angle of incidence of 5 degrees from orthogonal to the first major surface, that is greater than or equal to 30% across the wavelength range of from 250 nm to 300 nm. For example, the average first-surface reflectance, at an angle of incidence of 5 degrees from orthogonal to the first major surface 16, that the article 10 exhibits across the wavelength range of from 250 nm to 300 nm can be 25.0%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, or within any range bound by any two of those values (e.g., from 25.0% to 42%, from 31% to 41%, from 25.0% to 68%, and so on).

In embodiments, the article 10 exhibits an average first-surface reflectance, at an angle of incidence of 5 degrees from orthogonal to the first major surface 16, that is less than or equal to 1.10%, less than or equal to 1.00%, less than 0.80%, less than or equal to 0.50%, or even less than 0.35% across one or more of the following wavelength ranges: from 700 nm to 750 nm, from 750 nm to 800 nm, from 800 nm to 850 nm, and from 850 nm to 900 nm. For example, in such embodiments, the average first-surface reflectance, at an angle of incidence of 5 degrees from orthogonal to the first major surface 16, that the article 10 exhibits across one or more of those visible wavelength ranges can be 0.30%, 0.32%, 0.35%, 0.40%, 0.45%, 0.50%, 0.55%, 0.60%, 0.65%, 0.70%, 0.75%, 0.80%, 0.85%, 0.90%, 0.95%, 1.00%, 1.05%, 1.10%, or within any range bound by any two of those values (e.g., from 0.30% to 1.10%, from 0.45% to 0.95%, and so on).

In embodiments, the article 10 exhibits an average first-surface reflectance, at an angle of incidence of 5 degrees from orthogonal to the first major surface 16, that is less than or equal to 1.15%, less than 1.00%, less than 0.80%, or even less than 0.60% across all of the following wavelength ranges: from 700 nm to 750 nm, from 750 nm to 800 nm, from 800 nm to 850 nm, and from 850 nm to 900 nm. For example, the average first-surface reflectance, at an angle of incidence of 5 degrees from orthogonal to the first major surface 16, that the article 10 exhibits across all of those visible wavelength ranges can be 0.58%, 0.59%, 0.60%, 0.65%, 0.70%, 0.75%, 0.80%, 0.85%, 0.90%, 0.95%, 1.00%, 1.05%, 1.10%, 1.15%, or within any range bound by any two of those values (e.g., from 0.58% to 1.15%, from 0.75% to 0.95%, and so on).

In embodiments, the average first-reflectance, at an angle of incidence of 5 degrees from orthogonal to the first major surface 16, that the article 10 exhibits is less than or equal to 0.9% across one or more, or across all, of the following wavelength ranges: from 500 nm to 550 nm, from 550 nm to 600 nm, from 600 nm to 650 nm, from 650 nm to 700 nm, from 700 nm to 750 nm, from 750 nm to 800 nm, from 800 nm to 850 nm, and from 850 nm to 900 nm. For example, the average first-surface reflectance, at an angle of incidence of 5 degrees from orthogonal to the first major surface 16, that the article 10 exhibits across one or more, or across all, of those visible wavelength ranges can be within a range of from 0.3% to 0.9% or from 0.4% to 0.9% across all of those visible wavelength ranges.

In embodiments, the article 10 exhibits an average first-surface reflectance, at an angle of incidence of 5 degrees from orthogonal to the first major surface 16, that is less than or equal to 2.0%, less than or equal to 1.50%, less than or equal to 1.00%, less than or equal to 0.9%, or even less than or equal to 0.50% across the wavelength range of from 450 nm to 900 nm. For example, the average first-surface reflectance, at an angle of incidence of 5 degrees from orthogonal to the first major surface 16, that the article 10 exhibits across that visible wavelength range can be 0.40%, 0.50%, 0.60%, 0.65%, 0.70%, 0.75%, 0.80%, 0.85%, 0.90%, 0.95%, 1.00%, 1.05%, 1.10%, 1.15%, 1.20%, 1.25%, 1.30%, 1.35%, 1.40%, 1.45%, 1.50%, 1.60%, 1.70%, 1.80%, 1.90%, 2.00%, or within any range bound by any two of those values (e.g., from 0.60% to 1.50%, from 0.70% to 1.00%, and so on).

In embodiments, the article 10 exhibits an average first-surface reflectance, at an angle of incidence of 5 degrees from orthogonal to the first major surface 16, that is less than or equal to 0.50%, or even less than or equal to 0.35%, across one or more of the following wavelength ranges: from 550 nm to 600 nm, from 600 nm to 650 nm, from 650 nm to 700 nm, and from 750 nm to 800 nm. For example, the average first-surface reflectance, at an angle of incidence of 5 degrees from orthogonal to the first major surface 16, that the article 10 exhibits across one or more of those visible wavelength ranges can be 0.30%, 0.32%, 0.34%, 0.36%, 0.38%, 0.40%, 0.42%, 0.44%, 0.46%, 0.48%, 0.50%, or within any range bound by any two of those values (e.g., from 0.30% to 0.50%, from 0.32% to 0.44%, and so on).

In embodiments, the article 10 exhibits an average first-surface reflectance, at an angle of incidence of 5 degrees from orthogonal to the first major surface 16, that is less than or equal to 0.60% or even less than or equal to 0.45% across all of the following wavelength ranges: from 550 nm to 600 nm, from 600 nm to 650 nm, from 650 nm to 700 nm, and from 750 nm to 800 nm. For example, the average first-surface reflectance, at an angle of incidence of 5 degrees from orthogonal to the first major surface 16, that the article 10 exhibits across all of those visible wavelength ranges can be 0.40%, 0.41%, 0.42%, 0.44%, 0.44%, 0.45%, 0.46%, 0.47%, 0.48%, 0.49%, 0.50%, %, 0.51%, 0.52%, 0.54%, 0.54%, 0.55%, 0.56%, 0.57%, 0.58%, 0.59%, 0.60%, or within any range bound by any two of those values (e.g., from 0.40% to 0.50%, from 0.42% to 0.48%, and so on).

In embodiments, the article 10 exhibits an average first-surface reflectance, at an angle of incidence of 5 degrees from orthogonal to the first major surface 16, that is less than or equal to 2.0%, less than or equal to 1.5%, less than or equal to 1.0%, less than or equal to 0.5%, or even less than 0.4% across one or more of the following wavelength ranges: from 800 nm to 850 nm, from 850 nm to 900 nm, from 900 nm to 950 nm, from 950 nm to 1000 nm, and from 1000 nm to 1050 nm. For example, the average first-surface reflectance, at an angle of incidence of 5 degrees from orthogonal to the first major surface 16, that the article 10 exhibits across one or more of those wavelength ranges can be 0.30%, 0.35%, 0.40%, 0.45%, 0.50%, 0.60%, 0.70%, 0.80%, 0.90%, 1.0%, 1.10%, 1.2%, 1.3%, 1.4%, 1.5%, 1.6%, 1.7%, 1.8%, 1.9%, 2.0%, or within any range bound by any two of those values (e.g., from 0.30% to 2.0%, from 0.45% to 2.0%, from 0.50% to 1.4%, and so on).

In embodiments, the article 10 exhibits an average first-surface reflectance, at an angle of incidence of 5 degrees from orthogonal to the first major surface 16, that is less than or equal to 2.00%, less than or equal to 1.50%, or even less than 1.10%, across all of the following wavelength ranges: from 800 nm to 850 nm, from 850 nm to 900 nm, from 900 nm to 950 nm, and from 950 nm to 1000 nm. For example, the average first-surface reflectance, at an angle of incidence of 5 degrees from orthogonal to the first major surface 16, that the article 10 exhibits across all of those wavelength ranges can be 1.05%, 1.08%, 1.10%, 1.12%, 1.14%, 1.16%, 1.18%, 1.20%, 1.22%, 1.24%, 1.26%, 1.28%, 1.30%, 1.32%, 1.34%, 1.36%, 1.38%, 1.40%, 1.42%, 1.44%, 1.46%, 1.48%, 1.50%, 1.52%, 1.54%, 1.56%, 1.58%, 1.60%, 1.62%, 1.64%, 1.66%, 1.68%, 1.70%, 1.72%, 1.74%, 1.76%, 1.78%, 1.80%, 1.82%, 1.84%, 1.86%, 1.88%, 1.90%, 1.92%, 1.94%, 1.96%, 1.98%, 2.00%, or within any range bound by any two of those values (e.g., from 1.05% to 2.00%, from 1.70% to 2.00%, from 1.80% to 1.94%, and so on).

In embodiments, the article exhibits an average first-surface reflectance, at an angle of incidence of 5 degrees from orthogonal to the first major surface, that is greater than or equal to 20%, greater than or equal to 30%, greater than or equal to 40%, greater than or equal to 50%, greater than or equal to 60%, greater than or equal to 70%, or even greater than or equal to 80% across the wavelength range of from 300 nm to 350 nm. For example, the average first-surface reflectance, at an angle of incidence of 5 degrees from orthogonal to the first major surface 16, that the article 10 exhibits across the wavelength range of from 300 nm to 350 nm can be 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 89%, or within any range bound by any two of those values (e.g., from 45% to 75%, from 50% to 60%, and so on).

In embodiments, the article 10 exhibits an average transmittance through the article 10, at an angle of incidence of 0 degrees from orthogonal to the first major surface 16, that is less than or equal to 12.0% (or less than or equal to 10%, or less than or equal to 2.0%, or less than or equal to 0.5%, or even less than or equal to 0.3%) across the wavelength range of from 250 nm to 300 nm. For example, the average transmittance through the article 10, at an angle of incidence of 0 degrees from orthogonal to the first major surface 16, that the article 10 exhibits across that ultraviolet wavelength range can be 0%, >0%, 0.01%, 0.02%, 0.03%, 0.04%, 0.05%, 0.10%, 0.20%, 0.50%, 1.00%, 2.00%, 3.00%, 4.00%, 5.00%, 6.00%, 7.00%, 8.00%, 9.00%, 10.0%, 11.0%, 12.0%, or within any range bound by any two of those values (e.g., from 0% to 12.0%, from greater>0% to 12.0%, and so on).

In embodiments, the article 10 exhibits an average transmittance through the article 10, at an angle of incidence of 0 degrees from orthogonal to the first major surface 16, that is less than or equal to 25%, less than or equal to 10%, less than or equal to 1.0%, or even less than or equal to 0.1% across the wavelength range of from 250 nm to 350 nm. For example, the average transmittance through the article 10, at an angle of incidence of 0 degrees from orthogonal to the first major surface 16, that the article 10 exhibits can be >0, 0.1%, 0.2%, 0.3%, 0.4%, 0.5%, 1.0%, 2.0%, 3.0%, 4.0%, 5.0%, 6.0%, 7.0%, 8.0%, 9.0%, 10%, 11%, 12%, 13%, 14%, 15%, 16%, 17%, 18%, 19%, 20%, 21%, 22%, 23%, 24%, 25%, or within any range bound by any two of those values (e.g., from 0.1% to 25%, from 1.0% to 10%, and so on).

In embodiments, the article 10 exhibits an ultraviolet cutoff wavelength within a range of from 320 nm to 390 nm. For purposes of this disclosure, the ultraviolet cutoff wavelength is the wavelength at which the transmittance that the article 10 exhibits is 50% along a transmittance spectra transition from relatively low transmittance at ultraviolet wavelengths to relatively high transmittance at visible wavelengths. For example, the ultraviolet cutoff wavelength that the article 10 exhibits can be 320 nm, 321 nm, 322 nm, 323 nm, 324 nm, 325 nm, 326 nm, 327 nm, 328 nm, 329 nm, 330 nm, 331 nm, 332 nm, 333 nm, 334 nm, 335 nm, 336 nm, 337 nm, 338 nm, 339 nm, 340 nm, 341 nm, 342 nm, 343 nm, 344 nm, 345 nm, 346 nm, 347 nm, 348 nm, 349 nm, 350 nm, 351 nm, 352 nm, 353 nm, 354 nm, 355 nm, 356 nm, 357 nm, 358 nm, 359 nm, 360 nm, 361 nm, 362 nm, 363 nm, 364 nm, 365 nm, 366 nm, 367 nm, 368 nm, 369 nm, 370 nm, 371 nm, 372 nm, 373 nm, 374 nm, 375 nm, 376 nm, 377 nm, 378 nm, 379 nm, 380 nm, 381 nm, 382 nm, 383 nm, 384 nm, 385 nm, 386 nm, 387 nm, 388 nm, 389 nm, 390 nm or within any range bound by any two of those values (e.g., from 340 nm to 380 nm, from 360 nm to 368 nm, from 358 nm to 369 nm, and so on).

In embodiments, the article exhibits a UV cut sharpness (85-5) that is less than or equal to 75 nm, less than or equal to 50 nm, less than or equal to 25 nm, or even less than or equal to 20 nm. The “UV cut sharpness (85-5)” is the wavelength range separation between the wavelength at which the article 10 exhibits 85% transmittance and the wavelength at which the article 10 exhibits 5% transmittance along the transmittance spectra transition from relatively low transmittance at ultraviolet wavelengths to relatively high transmittance at visible wavelengths. For example, the UV cut sharpness (85-5) can be 18 nm, 19 nm, 20 nm, 25 nm, 30 nm, 35 nm, 40 nm, 45 nm, 50 nm, 55 nm, 60 nm, 65 nm, 70 nm, 75 nm, or within any range bound by any two of those values (e.g., from 18 nm to 75 nm, from 25 nm to 40 nm, and so on). A similar metric, UV cut sharpness (90-2) is additionally mentioned herein, and is the wavelength range separation between the wavelength at which the article 10 exhibits 90% transmittance and the wavelength at which the article 10 exhibits 2% transmittance along the transmittance spectra transition from relatively low transmittance at ultraviolet wavelengths to relatively high transmittance at visible wavelengths. In embodiments, the UV cut sharpness (90-2) can be less than or equal to 120 nm, less than or equal to 100 nm, less than or equal to 80 nm, less than or equal to 60 nm, less than or equal to 40 nm, or even less than or equal to 30 nm. For example the UV cut sharpness (90-2) can be 25 nm, 30 nm, 35 nm, 40 nm, 45 nm, 50 nm, 55 nm, 60 nm, 65 nm, 70 nm, 75 nm, 80 nm, 90 nm, 100 nm, 110 nm, 120 nm, or within any range bound by any two of those values (e.g., from 25 nm to 120 nm, from 30 nm to 100 nm, and so on).

In embodiments, the article 10 exhibits an average transmittance, at an angle of incidence of 0 degrees from orthogonal to the first major surface 16, that is greater than or equal to 50% (or even greater than or equal to 65%) across the wavelength range of from 350 nm to 400 nm. For example, the average transmittance through the article 10, at an angle of incidence of 0 degrees from orthogonal to the first major surface 16, that the article 10 exhibits across that wavelength range can be 50%, 55%, 60%, 65%, 70%, 75%, 80%, 85%, 90%, or within any range bound by any two of those values (e.g., from 50% to 90%, from 55% to 85%, and so on).

In embodiments, the article 10 exhibits an average transmittance, at an angle of incidence of 0 degrees from orthogonal to the first major surface 16, that is greater than or equal to 92% (or even greater than 93%, or even greater than 94%, or even greater than 95%) across one or more, or across all of the following wavelength ranges: from 950 nm to 1000 nm, from 1000 nm to 1050 nm, and from 1050 nm to 1100 nm. For example, the average transmittance through the article 10, at an angle of incidence of 0 degrees from orthogonal to the first major surface 16, that the article 10 exhibits across any one of those wavelength ranges can be 92.0%, 92.2%, 92.4%, 92.6%, 92.8%, 93.0%, 93.2%, 93.4%, 93.6%, 93.8%, 94.0%, 94.0%, 94.2%, 94.4%, 94.8%, 95.0%, 95.2%, 95.4%, 95.5%, or within any range bound by any two of those values (e.g., from 92.0% to 95.5%, from 93.0% to 94.0%, and so on).

In embodiments, the article 10 exhibits an average transmittance, at an angle of incidence of 0 degrees from orthogonal to the first major surface 16, that is greater than or equal to 93.0% (or even greater than or equal to 95.0%) across the wavelength range of from 400 nm to 1100 nm. For example, the average transmittance through the article 10, at an angle of incidence of 0 degrees from orthogonal to the first major surface 16, that the article 10 exhibits across that wavelength range can be 93.0%, 93.1%, 93.2%, 93.3%, 93.4%, 93.5%, 93.6%, 93.7%, 93.8%, 939%, 94.0%, 94.1%, 94.2%, 94.3%, 94.4%, 94.5%, 94.6%, 94.7%, 94.8%, 94.9%, 95.0%, 95.1%, 95.2%, 95.3%, 95.4%, 95.5%, or within any range bound by any two of those values (e.g., from 93.0% to 95.5%, from 93.5% to 95.3%, and so on).

In embodiments, the article 10 exhibits an average transmittance through the article, at an angle of incidence of 0 degrees from orthogonal to the first major surface, that is less than or equal to 82.0%, less than or equal to 70%, less than or equal to 60%, less than or equal to 50%, % or even less than or equal to 40$ across the wavelength range of from 1600 nm to 1700 nm. For example, the average transmittance through the article 10, at an angle of incidence of 0 degrees from orthogonal to the first major surface 16, that the article 10 exhibits across that wavelength range can be 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, or within any range bound by any two of those values (e.g., from 35% to 82%, from 70% to 86%, from 72% to 77%, and so on).

The article 10 with the multilayer coating 14 addresses the problems described in the Background. First, the multilayer coating 14 is more durable than the typical porous SiO₂ antireflective coating. The incorporation of material such as TiO₂, SiNₓ, and similar material that form the HRI layers 26h or MHRI layers 26mh impart hardness to the multilayer coating 14, especially when present at the topmost 300 nm of the total coating thickness 30 (e.g., the 300 nm closest to the external environment 42 and furthest from the substrate 12). Second, via reflecting a significant portion of electromagnetic radiation within ultraviolet ranges or via absorbing such radiation within the substrate 12 or within the multilayer coating 14, the article 10 reduces the amount of ultraviolet electromagnetic radiation that would have otherwise impinged upon and degraded the encapsulant and other components of a solar panel 100. This benefit is magnified when the article 10 is used with a space-based application, because the Earth's atmosphere is not there to filter out some of the ultraviolet electromagnetic radiation before it encounters the article 10. Third, when embodiments of the multilayer coating 14 that reflect a significant amount of infrared electromagnetic radiation are utilized, the heat generation that transmittance of such electromagnetic radiation would have caused is reduced.

Solar Panel 100 with the Article 10 Having the Multilayer Coating 14

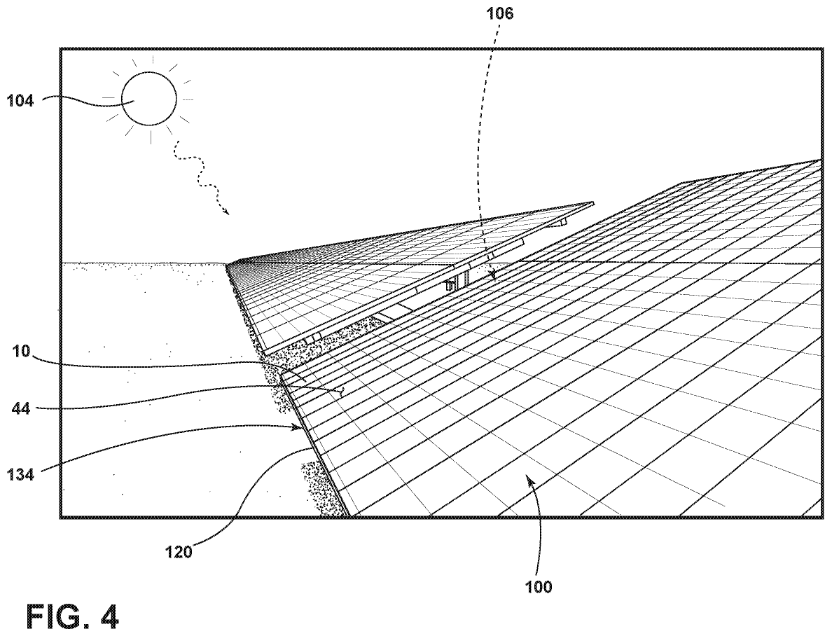

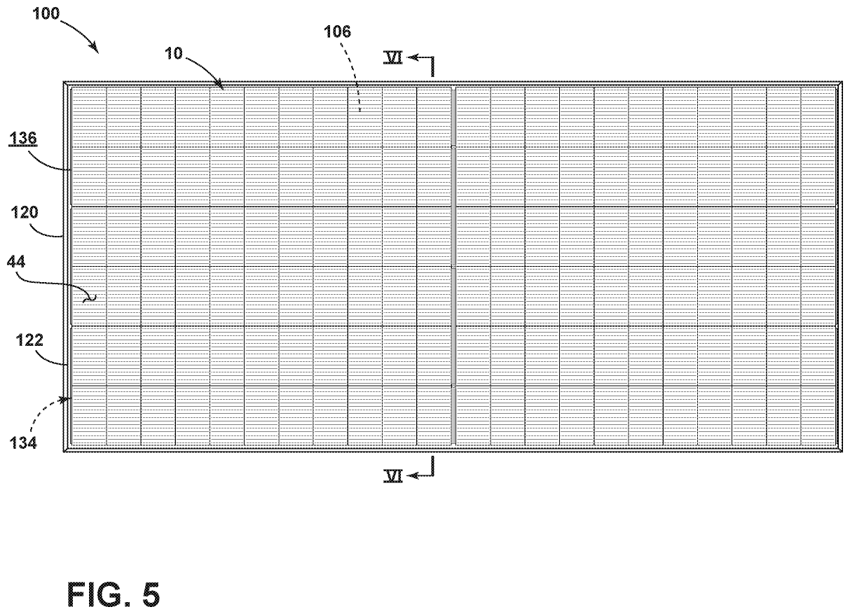

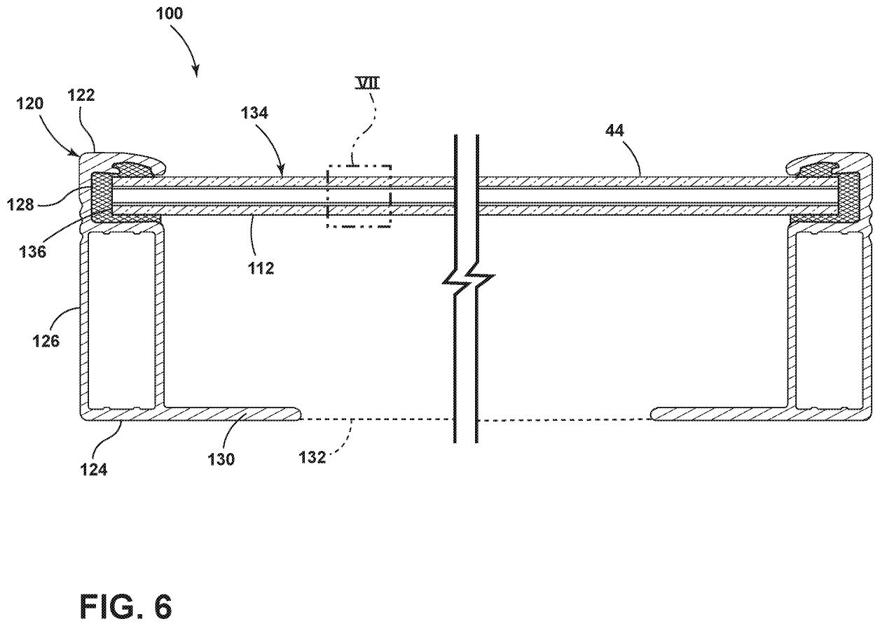

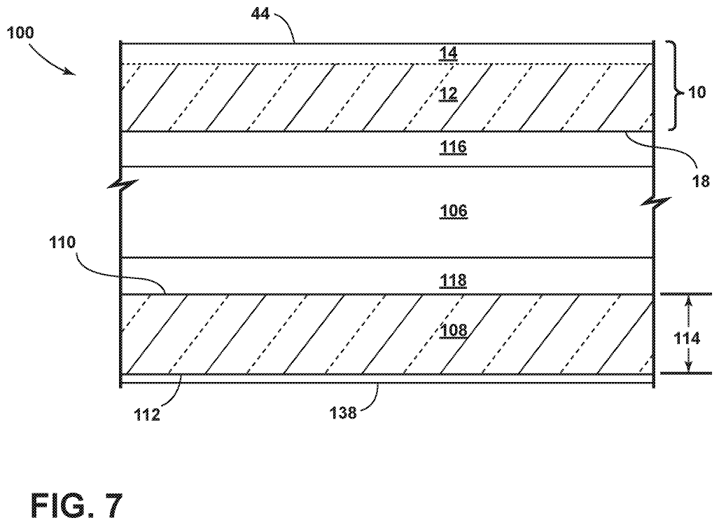

Referring now to FIGS. 4-7, a solar panel 100 is herein described that includes the article 10 and one or more photovoltaic (PV) cells 106 disposed beneath the second major surface 18 of the substrate 12. During use of the solar panel 100, photons from the Sun 104 enter the solar panel 100 through the article 10 and impinge upon the one or more PV cells 106. The type of PV cells 106 is not particularly limited, though in preferred embodiments, the PV cells 106 are monocrystalline silicon PV cells 106. Alternatively, the one or more PV cells 106 can rely on thin film amorphous silicon, cadmium telluride (CdTe), copper indium gallium selenide (CIGS), perovskite, or Si-perovskite tandem, or other known hybrid or tandem technologies. In embodiments of silicon-based solar cells, the cells may be based on either n-type or p-type architectures, and the solar cells may be doped with elements such as phosphorous, boron, or gallium, forming p-n junctions. The silicon-based solar cell architecture may be of any type, e.g. back surface field (BSF), passivated emitter rear cells (PERC), heterojunction (HJT or SHJ), tunnel oxide passivated contacts (TOPCon), or interdigitated back contact (IBC) cell types. Further description of these and other silicon-based cell architectures can be found in Vodapally, S. N., & Ali, M. H. (2022), “A comprehensive review of solar photovoltaic (PV) technologies, architecture, and its applications to improved efficiency,” Energies, 16(1), 319 and in Nayak, P. K., Mahesh, S., Snaith, H. J., & Cahen, D. (2019), “Photovoltaic solar cell technologies: analysing the state of the art,” Nature Reviews Materials, 4 (4), 269-285, both of which are incorporated here by reference.

The prime surface 44 of the article 10 is intended to face the Sun 104, such as during daytime hours for terrestrial applications. A second major surface 18 of the article 10 (e.g., the second major surface 18 of the substrate 12) faces inward into the solar panel 100 in the opposite direction as the prime surface 44 of the article 10. The one or more PV cells 106 faces the second major surface 18 of the article 10. The multilayer coating 14 on the article 10 beneficially provides the solar panel 100 with a durable anti-reflective (within the visible range) coating associated with an exterior facing surface (e.g., the prime surface 44) above the one or more PV cells 106 that, in embodiments, includes both SiO₂ layering (e.g., the LRI layers 26l) and layering with an index of refraction that is greater than 1.45, such as with the MLRI layers 26ml, the MHRI layers 26mh, and the HRI layers 26h (or some combination thereof). The article 10 thus acts as a front cover for the solar panel 100, and the substrate 12 component of the article 10, in embodiments, is or includes glass (e.g., has a glass composition).

In embodiments, the solar panel 100 further includes a backsheet 108. The one or more PV cells 106 is disposed between the article 10 and the backsheet 108. The backsheet 108 can be thought of as a rear cover of the solar panel 100. The backsheet 108 (e.g., rear cover) can have a glass composition. The glass composition of the backsheet 108 can be the same as the composition of the substrate 12 of the article 10 but need not be. For example, the glass composition of the backsheet 108 can be substantially free of alkali ions (meaning, e.g., that alkali ions are not intentionally added to the batch from which the glass composition was made). Further, the backsheet 108 can also include the multilayer coating 14 of the present disclosure to enhance the performance of the backsheet 108, such as when the solar panel 100 is intended to be used in a bifacial manner. To expand, having the one or more PV cells 106 sandwiched between the article 10 and the backsheet 108 having a glass composition allows the one or more PV cells 106 to receive photons transmitting through both the article 10 and the backsheet 108. That arrangement in theory should increase the electricity production of the solar panel 100 compared to if the one or more PV cells 106 received photons transmitted only through the article 10 and not the backsheet 108 as well.

The backsheet 108 has an inward major surface 110, an outward major surface 112, and a thickness 114 between the inward major surface 110 and the outward major surface 112. The inward major surface 110 faces the one or more PV cells 106. The outward major surface 112 faces outward out of the solar panel 100. The thickness 114 of the backsheet 108 can be less than or equal to 2 mm. For example, the thickness 114 can be 0.3 mm, 0.4 mm, 0.5 mm, 0.6 mm, 0.7 mm, 0.8 mm, 0.9 mm, 1.0 mm, 1.1 mm, 1.2 mm, 1.3 mm, 1.4 mm, 1.5 mm, 1.6 mm, 1.7 mm, 1.8 mm, 1.9 mm, 2.0 mm, 2.1 mm, 2.2 mm, 2.3 mm, 2.4 mm, 2.5 mm, 2.6 mm, 2.7 mm, 2.8 mm, 2.9 mm, 3.0 mm, 3.1 mm, 3.2 mm, 3.3 mm, 3.4 mm, 3.5 mm, 3.6 mm, 3.7 mm, 3.8 mm, 3.9 mm, 4.0 mm, or within any range bound by any of two of those values (e.g., from 0.3 mm to 4.0 mm, from 0.3 mm to 1.0 mm, from 0.5 mm to 0.9 mm, from 0.6 mm to 1.3 mm, and so on). The thickness 114 of the backsheet 108 being less than 0.3 mm or greater than 4.0 mm is also envisioned.

A first polymer layer 116 can be disposed between the article 10 and the one or more PV cells 106. Similarly, a second polymer layer 118 can be disposed between the backsheet 108 and the one or more PV cells 106. The first polymer layer 116 and the second polymer layer 118 can reduce migration of ions (e.g., Na⁺, K⁺) from the article 10 and the backsheet 108, respectively, to the one or more PV cells 106 that could cause potential-induced degradation, which is degradation of the one or more PV cells 106 that lowers efficiency thereof. The first polymer layer 116 and the second polymer layer 118 can be formed of a transparent polymer, such as ethylene-vinyl acetate (EVA). The first polymer layer 116 and the second polymer layer 118 can encapsulate the one or more PV cells 106.

In embodiments where the one or more PV cells comprise e.g. an amorphous silicon, a perovskite, a CdTe, or a hybrid or tandem technology incorporating these or other materials which can be coated directly onto glass, one or more layers of the solar cell may be coated directly onto the second major surface 18 of the article 10, without an intervening polymer layer between the solar cell element and the article 10. These layers coated onto the second major surface 18 of the article 10 may include e.g. a transparent conductive oxide (TCO) layer, a patterned metal contact layer, and/or a semiconductor material layer, such as a perovskite or a CdTe material layer. Various architectures of amorphous silicon, perovskite and CdTe-based solar cells can be found in Roy, P., Sinha, N. K., Tiwari, S., & Khare, A. (2020), “A review on perovskite solar cells: Evolution of architecture, fabrication techniques, commercialization issues and status,” Solar Energy, 198, 665-688, and in Lee, T. D., & Ebong, A. U. (2017), “A review of thin film solar cell technologies and challenges,” Renewable and Sustainable Energy Reviews, 70, 1286-1297, both of which are incorporated here by reference.

In embodiments, the solar panel 100 further includes a frame 120. When the solar panel 100 is oriented horizontally such that the prime surface 44 of the article 10 is horizontal and facing upwards, the frame 120 defines a top 122 and a bottom 124 of the solar panel 100 where the top 122 is the most elevated portion of the solar panel 100 and the bottom 124 is the least elevated portion of the solar panel 100, excluding wiring that may extend from the solar panel 100. In a more detailed example, the frame 120 includes a sidewall 126, a C-channel 128 that is contiguous with the sidewall 126, and a tab 130 that extends inward relative to the sidewall 126. The C-channel 128 is disposed at or near the top 122 of the frame 120, and the tab 130 is disposed at or near the bottom 124 of the frame 120. The tab 130 forms a plane 132 that is generally parallel to the outward major surface 112 of the backsheet 108. The article 10, the one or more PV cells 106, and the backsheet 108 are all coupled to each other as a package 134. The sidewall 126 extends around a perimeter 136 of the package 134 with the perimeter 136 of the package 134 secured within the C-channel 128 of the frame 120.

The article 10 with the multilayer coating 14 thereupon is particularly beneficial for the solar panel 100 application, for a variety of reasons. Among them, the article 10 limits transmittance within the ultraviolet wavelength range, especially across the wavelength range of 250 nm to 300 nm, thus limiting degradation of solar panel 100 components, while simultaneously imparting significant anti-reflectance (increased transmittance) across one or more visible wavelength ranges, thus allowing more photons beneficial to electricity production to reach the surface of the one or more PV cells 106.

Insulated Glass Unit 200 with the Article 10 Having the Multilayer Coating 14

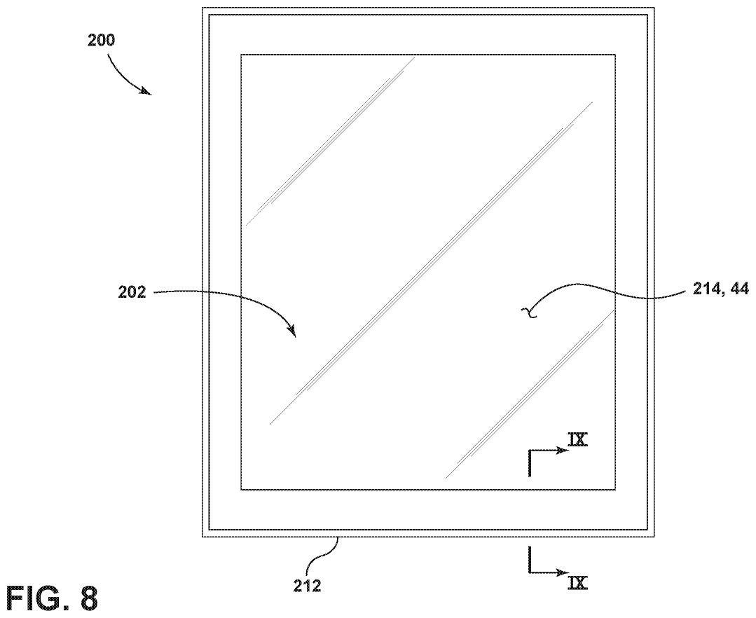

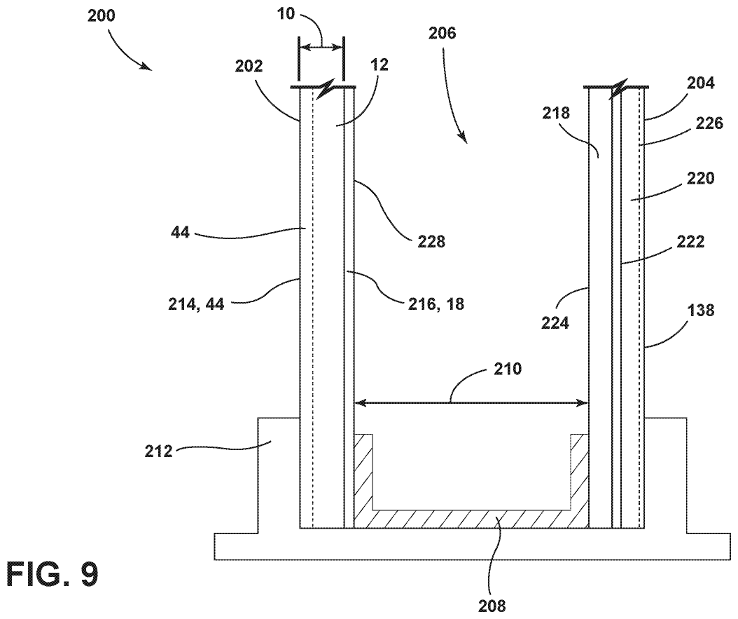

Referring now to FIGS. 8 and 9, an Insulated Glass Unit (IGU) 200 includes a first outer pane 202 that is or includes the article 10 and a second outer pane 204. A space 206 separates the first outer pane 202 and the second outer pane 204. The first outer pane 202 and the second outer pane 204 are disposed substantially parallel to each other.

The insulated glass unit 200 can further include a spacer 208 between the first outer pane 202 and the second outer pane 204 to further define the space 206 and help establish a distance 210 between the first outer pane 202 and the second outer pane 204. The distance 210 can be any value, but can be from 50 μm to 50 mm, such as from 5 mm to 25 mm. The spacer 208 may be an edge seal formed around respective edges of the first outer pane 202 and the second outer pane 204, a metallic pillar between the surfaces of the first outer pane 202 and the second outer pane 204, a low thermal conduction material, or a glass bump attached to or formed integral with one or both of the first outer pane 202 and the second outer pane 204. The insulated glass unit 200 can further include a frame 212 around the edges of the first outer pane 202 and the second outer pane 204. The space 206 may be sealed and include an insulating gas such as air, argon, krypton, xenon, and combinations thereof. The space 206 may be sealed and include a pressure less than atmospheric pressure. The first outer pane 202 can be considered to be the outside glass pane (e.g., intended to face an exterior during use). The second outer pane 204 can be considered to be the inside glass pane (e.g., intended to face an interior during use). The insulated glass unit 200 may be part of a window or a door, among other options. Although the insulated glass unit 200 is illustrated and described herein as a double pane structure, the insulated glass unit 200 can be a triple pane structure or a structure including any number of additional panes.

The first outer pane 202 includes an outside surface 214 opposite an inside surface 216. In embodiments, the outside surface 214 is directly exposed to the exterior environment (e.g., outside). In embodiments, the inside surface 216 is adjacent the space 206 between the first outer pane 202 and the second outer pane 204. In embodiments where the article 10 is the first outer pane 202, the prime surface 44 of the article 10 is the outside surface 214 while the second major surface 18 of the article 10 is the inside surface 216. The first outer pane 202 can be a laminate with the article 10 forming one layer of the laminate and another glass layer being laminated to the article 10. In such embodiments, the other glass layer can provide the inside surface 216 of the first outer pane 202.

For completeness, the second outer pane 204 is illustrated as a laminate that includes a first glass layer 218, a second glass layer 220, and an interlayer 222 disposed between the first glass layer 218 and the second glass layer 220. In embodiments, the first glass layer 218 is or includes soda lime glass. The interlayer 222 can assist with bonding the first glass layer 218 and the second glass layer 220 together. Examples of the interlayer 222 include polyvinyl butyral (PVB), polycarbonate, acoustic PVB, ethylene vinyl acetate (EVA), thermoplastic polyurethane (TPU), thermoplastic polyolefin (TPO), a silicone, an ionomer, a thermoplastic material, and/or combinations thereof. In some embodiments, no interlayer 222 is utilized and the first glass layer 218 and the second glass layer 220 directly contact each other.

The first glass layer 218 provides an outside surface 224 of the second outer pane 204. The outside surface 224 is adjacent the space 206 between the first outer pane 202 and the second outer pane 204. The second glass layer 220 provides an inside surface 226 of the second outer pane 204. In embodiments, the inside surface 224 is directly exposed to the interior of a building.

### EXAMPLES

Example 1—For Example 1, an article with a multilayer coating of the present disclosure was modeled to determine average transmittance through the article and average first-surface reflectance off the surface closest to the multilayer coating. This Example, as well as the others that follow (except where noted otherwise), were modeled using optical transfer matrix simulations, using input parameters (index of refraction and extinction coefficient vs. wavelength) from experimentally fabricated and measured sputtered thin film materials. We have found this modeling approach to yield good agreement with fabricated multilayer film optical properties in numerous prior experiments. The design of the article consisting of a substrate (Glass C above) and a multilayer coating is as follows in Table 6 below.

TABLE 6
Example 1

| | | | | Index of | Extinction | | Section |
|---|---|---|---|---|---|---|---|
| | | | | Refraction@ | Coefficient@ | Thickness | Thickness |
| Medium | Layer | Category | Material | 550 nm | 550 nm | (nm) | (nm) |
| Incident | | | Air | 1 | 0 | | |
| Capping | 1 | LRI Layer | SiO₂ | 1.462 | 0 | 111.8 | |
| Layer | | | | | | | |
| Multilayer | 2 | HRI Layer | TiO₂ | 2.478 | 0 | 23.1 | 57.8 |
| Section 4 | 3 | LRI Layer | SiO₂ | 1.462 | 0 | 34.7 | |
| Multilayer | 4 | HRI Layer | TiO₂ | 2.478 | 0 | 37 | 72.1 |
| Section 3 | 5 | LRI Layer | SiO₂ | 1.462 | 0 | 35.1 | |
| Multilayer | 6 | HRI Layer | TiO₂ | 2.478 | 0 | 25.7 | 80.9 |
| Section 2 | 7 | LRI Layer | SiO₂ | 1.462 | 0 | 55.2 | |
| Multilayer | 8 | HRI Layer | TiO₂ | 2.478 | 0 | 10.9 | 35.9 |
| Section 1 | 9 | LRI Layer | SiO₂ | 1.462 | 0 | 25 | |
| Substrate | | | Glass C | 1.514 | 0 | 0.1 mm | |
| Emergent | | | Air | 1 | 0 | | |
| Total Coating | | | | | | 358.4 | |
| Thickness | | | | | | | |
| (nm) | | | | | | | |
| Max Layer | | | | | | 55.2 | |
| Thickness | | | | | | | |
| (nm) | | | | | | | |
| Min Layer | | | | | | 10.9 | |
| Thickness | | | | | | | |
| (nm) | | | | | | | |
| ΣLRI | | | | | | 261.8 | |
| thicknesses | | | | | | | |
| (nm) | | | | | | | |
| LRI thickness | | | | | | 73% | |
| % | | | | | | | |
| HI/MHI % | | | | | | 29% | |
| (top 300 nm) | | | | | | | |

“Incident” refers to the material (in this case, air) that the model assumes is disposed above the prime surface of the article. Likewise, “emergent” refers to the material (in this case, air) that the model assumes is disposed below the second major surface of the article (provided by the substrate). Layers 1 through 9 refer to the layers of the multilayer coating. “Max Layer Thickness” refers to the maximum thickness of all the layer thicknesses of the multilayer coating excluding the capping LRI layer. “Min Layer Thickness” refers to the minimum thickness of all the layer thicknesses of the multilayer coating excluding the capping LRI layer. “ΣLRI thicknesses” refers to the sum of the layer thicknesses of all the LRI layers including the capping LRI layer. “LRI thickness %” refers to the percentage of the total coating thickness that is the sum of the LRI thicknesses. “HI/MHI % (top 300 nm)” refers to the percentage of the top-most 300 nm (closest to the incident air) of the total coating thickness that is made of material forming HRI layers or MHRI layers.

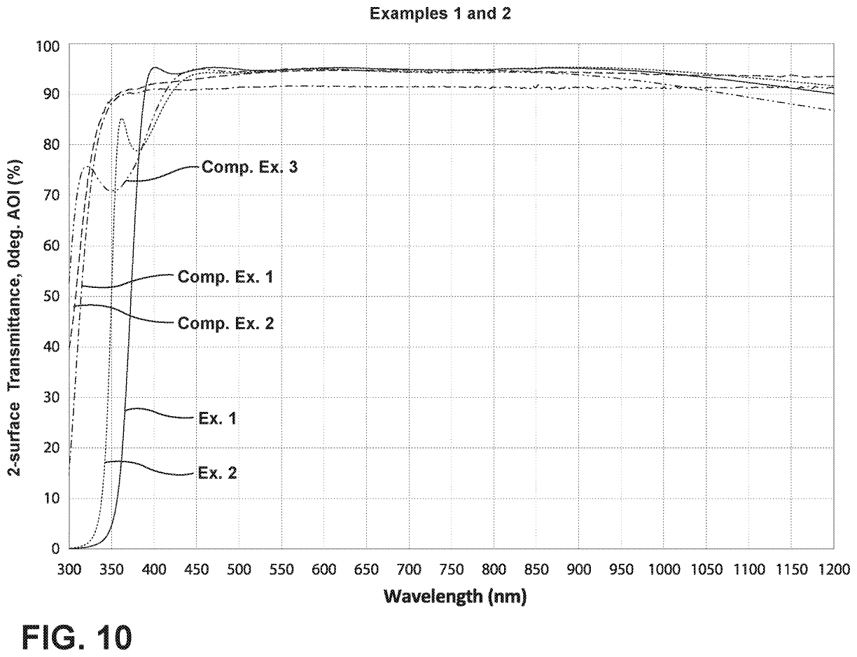

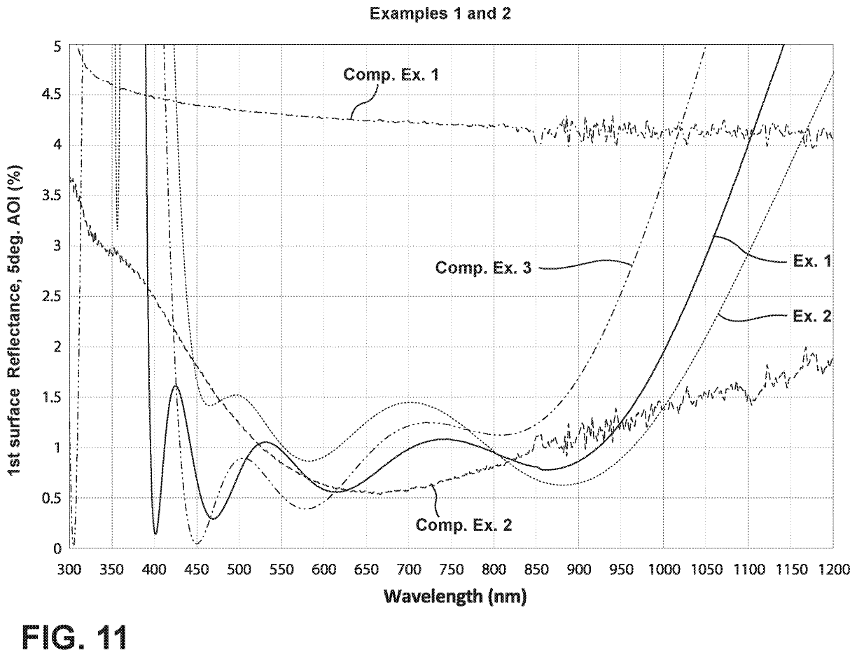

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 10 and 11, respectively. As FIG. 10 shows, the UV transmission bandedge (cutoff) wavelength for Example 1 (50% threshold) is ~373 nm. A physical embodiment of the multilayer coating of Example 1 would exhibit a hardness of greater than 8 GPa, based on an empirical model built on prior experiments with similar coatings. Example 1, as well as Examples 2-6 that follow, are modeled on thin glass substrates of only 0.1 mm thickness, which can be useful for lightweight applications such as solar panels on satellites.

Example 2—For Example 2, an article with a multilayer coating of the present disclosure was modeled to determine average transmittance through the article and average first-surface reflectance off the surface closest to the multilayer coating, in the same manner as Example 1. The design of the article consisting of a substrate (Glass C above) and a multilayer coating is as follows in Table 7 below.

TABLE 7
Example 2

| | | | | Index of | Extinction | | Section |
|---|---|---|---|---|---|---|---|
| | | | | Refraction@ | Coefficient@ | Thickness | Thickness |
| Medium | Layer | Category | Material | 550 nm | 550 nm | (nm) | (nm) |
| Incident | | | Air | 1 | 0 | | |
| Capping Layer | 1 | Capping | SiO₂ | 1.462 | 0 | 123.8 | |
| Multilayer | 2 | HRI Layer | TiO₂ | 2.379 | 0 | 18.65 | 56.27 |
| Section 4 | 3 | LRI Layer | SiO₂ | 1.462 | 0 | 37.62 | |
| Multilayer | 4 | HRI Layer | TiO₂ | 2.379 | 0 | 23.33 | 58.92 |
| Section 3 | 5 | LRI Layer | SiO₂ | 1.462 | 0 | 35.59 | |
| Multilayer | 6 | HRI Layer | TiO₂ | 2.379 | 0 | 22.18 | 74.65 |
| Section 2 | 7 | LRI Layer | SiO₂ | 1.462 | 0 | 52.47 | |
| Multilayer | 8 | HRI Layer | TiO₂ | 2.379 | 0 | 10.39 | 19.25 |
| Section 1 | 9 | LRI Layer | SiO₂ | 1.462 | 0 | 8.86 | |
| | Substrate | | Glass C | 1.514 | 0 | 0.1 mm | |
| | Emergent | | Air | 1 | 0 | | |
| Total Coating | | | | | | 332.9 | |
| Thickness | | | | | | | |
| (nm) | | | | | | | |
| Max Layer | | | | | | 52.47 | |
| Thickness | | | | | | | |
| (nm) | | | | | | | |
| Min Layer | | | | | | 8.86 | |
| Thickness | | | | | | | |
| (nm) | | | | | | | |
| ΣLRI | | | | | | 258.34 | |
| thicknesses | | | | | | | |
| (nm) | | | | | | | |
| LRI thickness | | | | | | 78% | |
| % | | | | | | | |
| HI/MHI % | | | | | | 21% | |
| (top 300 nm) | | | | | | | |

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 10 and 11, respectively. It is noted that for applications with a combined intermediate level of abrasion resistance and ultraviolet degradation concern, it may be advantageous to use multilayer coatings that include TiO₂ and SiO₂ to take advantage of the ultraviolet blocking effects of TiO₂ and the high optical transmittance and low reflectance in the visible wavelength range enabled by the high index contrast between TiO₂ and SiO₂. A physical embodiment of the multilayer coating of Example 2 would exhibit a hardness of greater than 8 GPa, based on an empirical model built on prior experiments with similar coatings.

Example 3—For Example 3, an article with a multilayer coating of the present disclosure was modeled to determine average transmittance through the article and average first-surface reflectance off the surface closest to the multilayer coating, in the same manner as Example 1. The design of the article consisting of a substrate (Glass C above) and a multilayer coating is as follows in Table 8 below.

TABLE 8
Example 3

| | | | | Index of | Extinction | | Section |
|---|---|---|---|---|---|---|---|
| | | | | Refraction@ | Coefficient@ | Thickness | Thickness |
| Medium | Layer | Category | Material | 550 nm | 550 nm | (nm) | (nm) |
| Incident | | | Air | 1 | 0 | | |
| Capping | 1 | Capping | SiO₂ | 1.462 | 0 | 88.6 | |
| Layer | | | | | | | |
| Multilayer | 2 | | SINₓ | 2.05 | 0.0002 | 52.45 | 165.65 |
| Section 5 | 3 | HRI Layer | TiO₂ | 2.379 | 0 | 99.65 | |
| | 4 | LRI Layer | SiO₂ | 1.462 | 0 | 13.55 | |
| Multilayer | 5 | MHRI Layer | SINₓ | 2.05 | 0.0002 | 53.59 | 108.01 |
| Section 4 | 6 | LRI Layer | SiO₂ | 1.462 | 0 | 54.42 | |
| Multilayer | 7 | MHRI Layer | SINₓ | 2.05 | 0.0002 | 21.52 | 97.76 |
| Section 3 | 8 | LRI Layer | SiO₂ | 1.462 | 0 | 76.24 | |
| Multilayer | 9 | MHRI Layer | SINₓ | 2.05 | 0.0002 | 17.21 | 87.8 |
| Section 2 | 10 | LRI Layer | SiO₂ | 1.462 | 0 | 70.59 | |
| Multilayer | 11 | MHRI Layer | SiNₓ | 2.05 | 0.0002 | 11.52 | 47.43 |
| Section 1 | 12 | LRI Layer | SiO₂ | 1.462 | 0 | 35.91 | |
| | Substrate | | Glass C | 1.514 | 0 | 0.1 mm | |
| | Emergent | | Air | 1 | 0 | | |
| Total | | | | | | 595.3 | |
| Coating | | | | | | | |
| Thickness | | | | | | | |
| (nm) | | | | | | | |
| Max Layer | | | | | | 99.65 | |
| Thickness | | | | | | | |
| (nm) | | | | | | | |
| Min Layer | | | | | | 11.52 | |
| Thickness | | | | | | | |
| (nm) | | | | | | | |
| ΣLRI | | | | | | 339.31 | |
| thicknesses | | | | | | | |
| (nm) | | | | | | | |
| LRI | | | | | | 57% | |
| thickness | | | | | | | |
| % | | | | | | | |
| HI/MHI % | | | | | | 51% | |
| (top 300 | | | | | | | |
| nm) | | | | | | | |

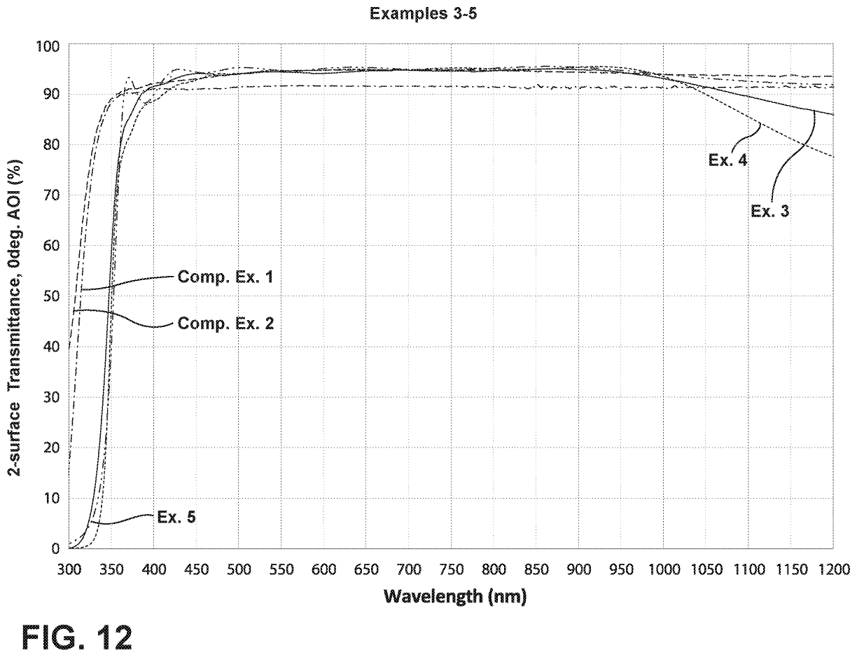

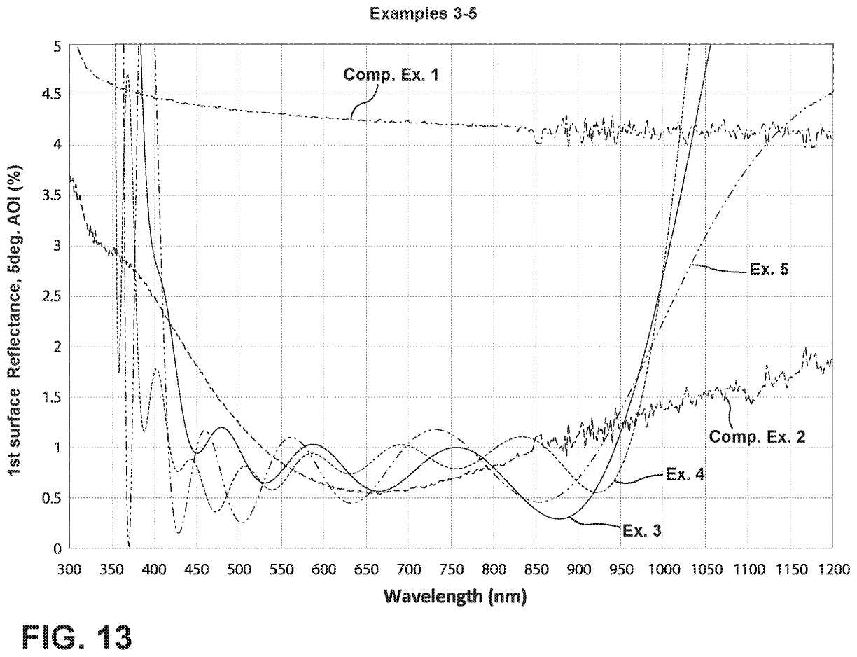

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 12 and 13, respectively. A physical embodiment of the multilayer coating of Example 3 would exhibit a hardness of greater than 9 GPa, based on an empirical model built on prior experiments with similar coatings. The UV transmission bandedge (cutoff) wavelength for Example 3 (50% threshold) is ~347 nm.

Example 4—For Example 4, an article with a multilayer coating of the present disclosure was modeled to determine average transmittance through the article and average first-surface reflectance off the surface closest to the multilayer coating, in the same manner as Example 1. The design of the article consisting of a substrate (Glass E above with CeO₂) and a multilayer coating is as follows in Table 9 below.

TABLE 9
Example 4

| | | | | Index of | Extinction | | Section |
|---|---|---|---|---|---|---|---|
| | | | | Refraction@ | Coefficient@ | Thickness | Thickness |
| Medium | Layer | Category | Material | 550 nm | 550 nm | (nm) | (nm) |
| Incident | | | Air | 1 | 0 | | |
| Capping Layer | 1 | Capping | SiO₂ | 1.462 | 0 | 97.58 | |
| Multilayer | 2 | MHRI Layer | SiNₓ | 2.05 | 0.0002 | 47.54 | 57.1 |
| Section 11 | 3 | LRI Layer | SiO₂ | 1.462 | 0 | 9.56 | |
| Multilayer | 4 | MHRI Layer | SiNₓ | 2.05 | 0.0002 | 75.31 | 109.81 |
| Section 10 | 5 | LRI Layer | SiO₂ | 1.462 | 0 | 34.5 | |
| Multilayer | 6 | MHRI Layer | SiNₓ | 2.05 | 0.0002 | 20.03 | 133.91 |
| Section 9 | 7 | LRI Layer | SiO₂ | 1.462 | 0 | 113.88 | |
| Multilayer | 8 | MHRI Layer | SiNₓ | 2.05 | 0.0002 | 10.69 | 74.65 |
| Section 8 | 9 | LRI Layer | SiO₂ | 1.462 | 0 | 63.96 | |
| Multilayer | 10 | MHRI Layer | SiNₓ | 2.05 | 0.0002 | 36.26 | 69.91 |
| Section 7 | 11 | LRI Layer | SiO₂ | 1.462 | 0 | 33.65 | |
| Multilayer | 12 | MHRI Layer | SiNₓ | 2.05 | 0.0002 | 46.96 | 91.14 |
| Section 6 | 13 | LRI Layer | SiO₂ | 1.462 | 0 | 44.18 | |
| Multilayer | 14 | MHRI Layer | SiNₓ | 2.05 | 0.0002 | 24.92 | 106.73 |
| Section 5 | 15 | LRI Layer | SiO₂ | 1.462 | 0 | 81.81 | |
| Multilayer | 16 | MHRI Layer | SiNₓ | 2.05 | 0.0002 | 9.8 | 107.07 |
| Section 4 | 17 | LRI Layer | SiO₂ | 1.462 | 0 | 97.27 | |
| Multilayer | 18 | MHRI Layer | SiNₓ | 2.05 | 0.0002 | 5.46 | 13.72 |
| Section 3 | 19 | LRI Layer | SiO₂ | 1.462 | 0 | 8.26 | |
| Multilayer | 20 | MHRI Layer | SINₓ | 2.05 | 0.0002 | 4.33 | 80.25 |
| Section 2 | 21 | LRI Layer | SiO₂ | 1.462 | 0 | 75.92 | |
| Multilayer | 22 | MHRI Layer | SiNₓ | 2.05 | 0.0002 | 8.71 | 46.06 |
| Section 1 | 23 | LRI Layer | SiO₂ | 1.462 | 0 | 37.35 | |
| | Substrate | | Glass E | 1.518 | 0 | 0.1 mm | |
| | Emergent | | Air | 1 | 0 | | |
| Total Coating | | | | | | 987.9 | |
| Thickness | | | | | | | |
| (nm) | | | | | | | |
| Max Layer | | | | | | 113.88 | |
| Thickness | | | | | | | |
| (nm) | | | | | | | |
| Min Layer | | | | | | 4.33 | |
| Thickness | | | | | | | |
| (nm) | | | | | | | |
| ΣLRI | | | | | | 697.92 | |
| thicknesses | | | | | | | |
| (nm) | | | | | | | |
| LRI thickness | | | | | | 71% | |
| % | | | | | | | |
| HI/MHI % | | | | | | 48% | |
| (top 300 nm) | | | | | | | |

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 12 and 13, respectively. A physical embodiment of the multilayer coating of Example 4 would exhibit a hardness of greater than 10 GPa, based on an empirical model built on prior experiments with similar coatings. It is noted that for environments with high wind and abrasive sand impact, it may be advantageous to use a coating design which includes SiNₓ and/or SiOₓN_{y} with SiO₂ to maximize the hardness and abrasion resistance of the coating. The design for Example 4 utilizes SiO₂ & SiNₓ on CeO₂-containing glass, which absorbs some of the UV spectra, to achieve the UV blocking cutoff at ~350 nm with similar performance to Examples 2 & 3. Example 4 uses the addition of CeO₂ to the glass substrate to reduce transmittance below 350 nm. The use of such glass allows for coating designs with low absorbing, high durability materials such as for Example 4, using SiO₂ & SiNₓ which have relatively low absorption in the UV range of wavelengths.

Example 5—For Example 5, an article with a multilayer coating of the present disclosure was modeled to determine average transmittance through the article and average first-surface reflectance off the surface closest to the multilayer coating, in the same manner as Example 1. The design of the article consisting of a substrate (Glass C above) and a multilayer coating is as follows in Table 10 below.

TABLE 10
Example 5

| | | | | Index of | Extinction | | Section |
|---|---|---|---|---|---|---|---|
| | | | | Refraction@ | Coefficient@ | (Thickness | Thickness |
| Medium | Layer | Category | Material | 550 nm | 550 nm | nm) | (nm) |
| Incident | | | Air | 1 | 0 | | |
| Capping Layer | 1 | Capping | MgF₂ | 1.389 | 0 | 122.85 | |
| Multilayer | 2 | MHRI Layer | SINₓ | 2.05 | 0.0002 | 31.07 | 71.09 |
| Section 6 | 3 | LRI Layer | MgF₂ | 1.389 | 0 | 40.02 | |
| Multilayer | 4 | MHRI Layer | SiNₓ | 2.05 | 0.0002 | 47.51 | 86.81 |
| Section 5 | 5 | LRI Layer | MgF₂ | 1.389 | 0 | 39.3 | |
| Multilayer | 6 | MHRI Layer | SiNₓ | 2.05 | 0.0002 | 38.49 | 91.96 |
| Section 4 | 7 | LRI Layer | MgF₂ | 1.389 | 0 | 53.47 | |
| Multilayer | 8 | MHRI Layer | SiNₓ | 2.05 | 0.0002 | 31.88 | 92.25 |
| Section 3 | 9 | LRI Layer | MgF₂ | 1.389 | 0 | 60.37 | |
| Multilayer | 10 | MHRI Layer | SiNₓ | 2.05 | 0.0002 | 28.81 | 94.27 |
| Section 2 | 11 | LRI Layer | MgF₂ | 1.389 | 0 | 65.46 | |
| Multilayer | 12 | MHRI Layer | SINₓ | 2.05 | 0.0002 | 19.94 | 61.67 |
| Section 1 | 13 | LRI Layer | MgF₂ | 1.389 | 0 | 41.73 | |
| | Substrate | | Glass C | 1.514 | 0 | 0.1mm | |
| | Emergent | | Air | 1 | 0 | | |
| Total Coating | | | | | | 620.9 | |
| Thickness (nm) | | | | | | | |
| Max Layer | | | | | | 65.46 | |
| Thickness (nm) | | | | | | | |
| Min Layer | | | | | | 19.94 | |
| Thickness (nm) | | | | | | | |
| ΣLRI | | | | | | 423.2 | |
| thicknesses (nm) | | | | | | | |
| LRI thickness % | | | | | | 68% | |
| HI/MHI % | | | | | | 33% | |
| (top 300 nm) | | | | | | | |

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 12 and 13, respectively. A physical embodiment of the multilayer coating of Example 5 would exhibit a hardness of greater than 7 GPa, based on an empirical model built on prior experiments with similar coatings. The UV transmission bandedge (cutoff) wavelength for Example 5 (50% threshold) is ~353 nm.

Example 6—For Example 6, an article with a multilayer coating of the present disclosure was modeled to determine average transmittance through the article and average first-surface reflectance off the surface closest to the multilayer coating, in the same manner as Example 1. The design of the article consisting of a substrate (Glass C above) and a multilayer coating is as follows in Table 11 below.

TABLE 11
Example 6

| | | | | Index of | Extinction | | Section |
|---|---|---|---|---|---|---|---|
| | | | | Refraction | Coefficient | Thickness | Thickness |
| Medium | Layer | Category | Material | @550 nm | @550 nm | (nm) | (nm) |
| Incident | | | Air | 1 | 0 | | |
| Capping Layer | 1 | Capping | SiO₂ | 1.461 | 0 | 109.54 | |
| Multilayer | 2 | HRI Layer | Nb₂O₅ | 2.356 | 0 | 8.92 | 41.99 |
| Section 4 | 3 | LRI Layer | SiO₂ | 1.461 | 0 | 33.07 | |
| Multilayer | 4 | HRI Layer | Nb₂O₅ | 2.356 | 0 | 12.57 | 48.35 |
| Section 3 | 5 | LRI Layer | SiO₂ | 1.461 | 0 | 35.78 | |
| Multilayer | 6 | HRI Layer | Nb₂O₅ | 2.356 | 0 | 11.15 | 47.76 |
| Section 2 | 7 | LRI Layer | SiO₂ | 1.461 | 0 | 36.61 | |
| Multilayer | 8 | HRI Layer | Nb₂O₅ | 2.356 | 0 | 8 | 16.02 |
| Section 1 | 9 | LRI Layer | SiO₂ | 1.461 | 0 | 8.02 | |
| | Substrate | | Glass C | 1.514 | 0 | 0.1 mm | |
| | Emergent | | Air | 1 | 0 | | |
| Total Coating | | | | | | 263.7 | |
| Thickness (nm) | | | | | | | |
| Max Layer | | | | | | 36.61 | |
| Thickness (nm) | | | | | | | |
| Min Layer | | | | | | 8 | |
| Thickness (nm) | | | | | | | |
| ΣLRI | | | | | | 223.02 | |
| thicknesses | | | | | | | |
| (nm) | | | | | | | |
| LRI thickness | | | | | | 85% | |
| % | | | | | | | |
| HI/MHI % (top | | | | | | 15% | |
| 300 nm) | | | | | | | |

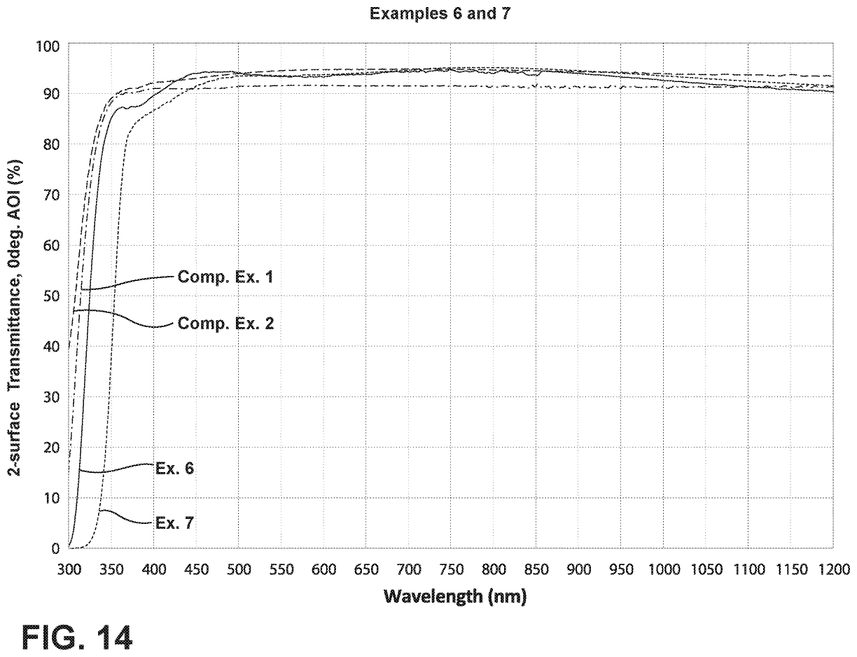

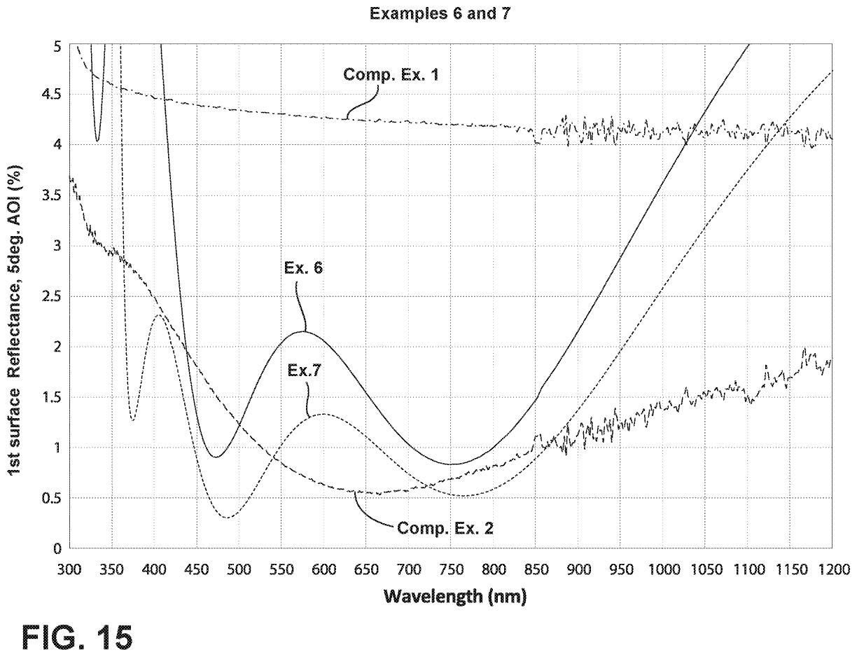

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 14 and 15, respectively. A physical embodiment of the multilayer coating of Example 6 would exhibit a hardness of greater than 7 GPa, based on an empirical model built on prior experiments with similar coatings. The design for Example 6 uses Niobia (Nb₂O₅) and SiO₂, which contributes to enabling the shorter-wavelength UV cutoff bandedge relative to other Examples. As the graph of FIG. 14 shows, the UV transmission bandedge (cutoff) wavelength for Example 6 (50% threshold) is about 325 nm.

Example 7—For Example 7, an article with a multilayer coating of the present disclosure was modeled to determine average transmittance through the article and average first-surface reflectance off the surface closest to the multilayer coating, in the same manner as Example 1. The design of the article consisting of a substrate (Glass E above) and a multilayer coating is as follows in Table 12 below.

TABLE 12
Example 7

| | | | | Index of | Extinction | | Section |
|---|---|---|---|---|---|---|---|
| | | | | Refraction | Coefficient | Thickness | Thickness |
| Medium | Layer | Category | Material | @550 nm | @550 nm | (nm) | (nm) |
| Incident | | | Air | 1 | 0 | | |
| Capping Layer | 1 | Capping | MgF₂ | 1.389 | 0 | 120 | |
| Multilayer | 2 | HRI Layer | TiO₂ | 2.478 | 0 | 11.73 | 57.9 |
| Section 4 | 3 | LRI Layer | MgF₂ | 1.389 | 0 | 46.17 | |
| Multilayer | 4 | HRI Layer | TiO₂ | 2.478 | 0 | 12.12 | 38 |
| Section 3 | 5 | LRI Layer | MgF₂ | 1.389 | 0 | 25.88 | |
| Multilayer | 6 | HRI Layer | CeO₂ | 2.478 | 0.017 | 8 | 48.08 |
| Section 2 | 7 | LRI Layer | SiO₂ | 1.462 | 0 | 40.08 | |
| Multilayer | 8 | HRI Layer | CeO₂ | 2.478 | 0.017 | 8 | 23 |
| Section 1 | 9 | LRI Layer | SiO₂ | 1.462 | 0 | 15 | |
| | Substrate | | Glass E | 1.518 | 0 | 0.1 mm | |
| | Emergent | | Air | 1 | 0 | | |
| Total Coating | | | | | | 287 | |
| Thickness | | | | | | | |
| (nm) | | | | | | | |
| Max Layer | | | | | | 46.17 | |
| Thickness | | | | | | | |
| (nm) | | | | | | | |
| Min Layer | | | | | | 8 | |
| Thickness | | | | | | | |
| (nm) | | | | | | | |
| ΣLRI | | | | | | 247.13 | |
| thicknesses | | | | | | | |
| (nm) | | | | | | | |
| LRI thickness | | | | | | 86% | |
| % | | | | | | | |
| HI/MHI % (top | | | | | | 14% | |
| 300 nm) | | | | | | | |

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 14 and 15, respectively. It is noted that, for space-based applications with high ultraviolet blocking needs but no environmental moisture or weathering concerns, it may be advantageous to incorporate MgF₂ and CeO₂ materials for their good optical and/or ultraviolet blocking performance. A physical embodiment of the multilayer coating of Example 7 would exhibit a hardness of greater than 6 GPa, based on an empirical model built on prior experiments with similar coatings. The UV transmission bandedge (cutoff) wavelength for Example 7 (50% threshold) is ~354 nm. This coating design utilizes four materials; SiO₂, TiO₂, MgF₂, & CeO₂. This design also uses CeO₂-containing glass, which contributes to the UV blocking.

Example 8—For Example 8, an article with a multilayer coating of the present disclosure was modeled to determine average transmittance through the article and average first-surface reflectance off the surface closest to the multilayer coating, in the same manner as Example 1. The design of the article consisting of a substrate (Glass B above) and a multilayer coating is as follows in Table 13 below.

TABLE 13
Example 8

| | | | | Index of | Extinction | | Section |
|---|---|---|---|---|---|---|---|
| | | | | Refraction | Coefficient | Thickness | Thickness |
| Medium | Layer | Category | Material | @550 nm | @550 nm | (nm) | (nm) |
| Incident | | | Air | 1 | 0 | | |
| Capping Layer | 1 | Capping | SiO₂ | 1.462 | 0 | 111.6 | |
| Multilayer | 2 | HRI Layer | TiO₂ | 2.379 | 0 | 29.6 | 53.2 |
| Section 5 | 3 | LRI Layer | SiO₂ | 1.462 | 0 | 23.6 | |
| Multilayer | 4 | HRI Layer | TiO₂ | 2.379 | 0 | 51.2 | 77.6 |
| Section 4 | 5 | LRI Layer | SiO₂ | 1.462 | 0 | 26.4 | |
| Multilayer | 6 | HRI Layer | TiO₂ | 2.379 | 0 | 31.2 | 82.6 |
| Section 3 | 7 | LRI Layer | SiO₂ | 1.462 | 0 | 51.4 | |
| Multilayer | 8 | HRI Layer | TiO₂ | 2.379 | 0 | 13.6 | 88.7 |
| Section 2 | 9 | LRI Layer | SiO₂ | 1.462 | 0 | 75.1 | |
| Multilayer | 10 | MLRI Layer | SiOₓN_{y} | 1.751 | 0.00005 | 13.4 | 84.5 |
| Section 1 | 11 | LRI Layer | SiO₂ | 1.462 | 0 | 71.1 | |
| | Substrate | | Glass B | 1.482 | 0 | 2 mm | |
| | Emergent | | Air | 1 | 0 | | |
| Total Coating | | | | | | 498.2 | |
| Thickness | | | | | | | |
| (nm) | | | | | | | |
| Max Layer | | | | | | 75.1 | |
| Thickness | | | | | | | |
| (nm) | | | | | | | |
| Min Layer | | | | | | 13.4 | |
| Thickness | | | | | | | |
| (nm) | | | | | | | |
| ΣLRI | | | | | | 359.2 | |
| thicknesses | | | | | | | |
| (nm) | | | | | | | |
| LRI thickness | | | | | | 72% | |
| % | | | | | | | |
| HI/MHI % (top | | | | | | 37% | |
| 300 nm) | | | | | | | |

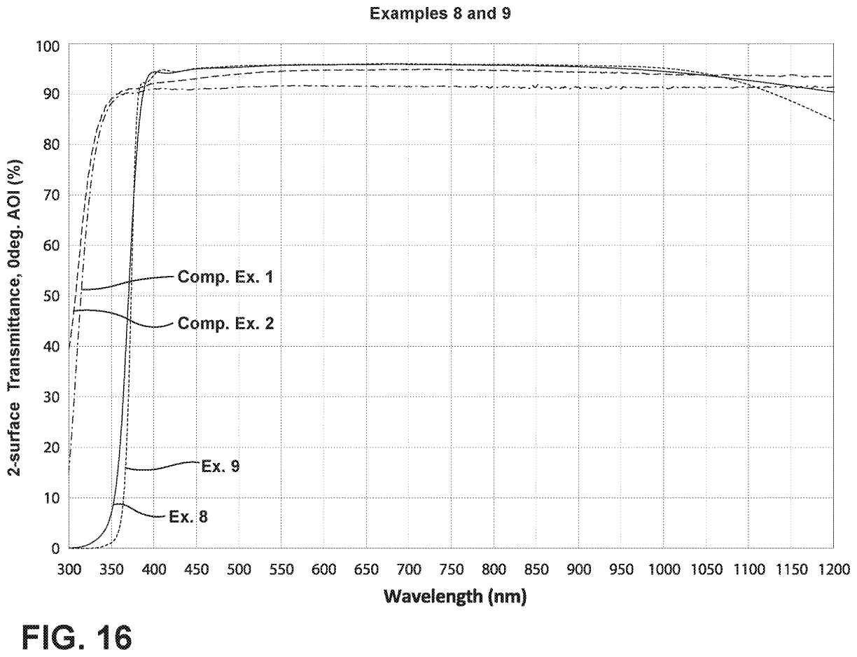

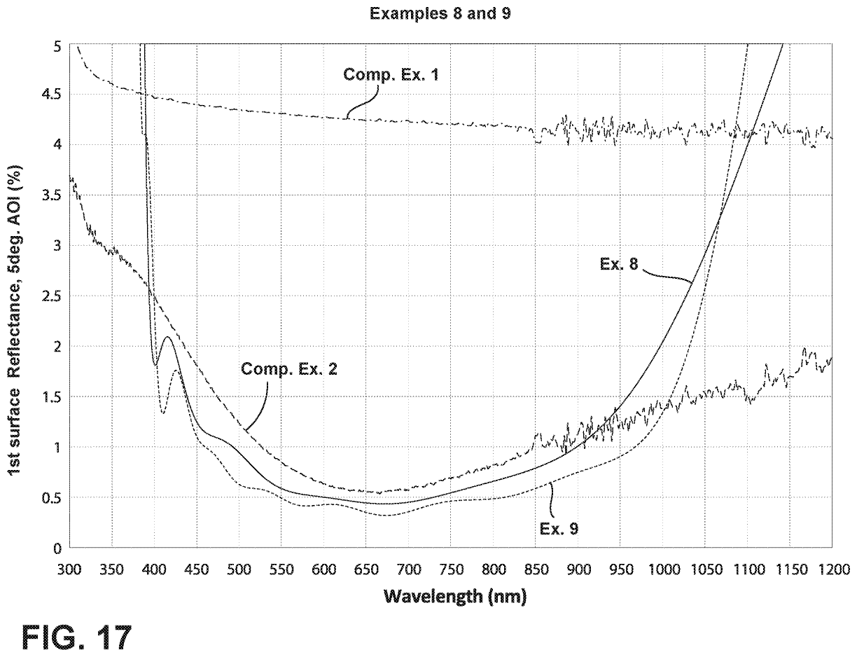

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 16 and 17, respectively. A physical embodiment of the multilayer coating of Example 8 would exhibit a hardness of greater than 7 GPa, based on an empirical model built on prior experiments with similar coatings. The UV transmission bandedge (cutoff) wavelength for Example 8 (50% threshold) is ~370 nm. Example 8 (and Examples 9 and 10 that follow) use 2 mm thick glass substrates, which may be advantageous over thinner glasses for terrestrial applications where mechanical resistance to e.g. hail impacts is beneficial.

Example 9—For Example 9, an article with a multilayer coating of the present disclosure was modeled to determine average transmittance through the article and average first-surface reflectance off the surface closest to the multilayer coating, in the same manner as Example 1. The design of the article consisting of a substrate (Glass B above) and a multilayer coating is as follows in Table 14 below.

TABLE 14
Example 9

| | | | | Index of | Extinction | | Section |
|---|---|---|---|---|---|---|---|
| | | | | Refraction | Coefficient | Thickness | Thickness |
| Medium | Layer | Category | Material | @550 nm | @550 nm | (nm) | (nm) |
| Incident | | | Air | 1 | 0 | | |
| Capping Layer | 1 | Capping | SiO₂ | 1.462 | 0 | 105.4 | |
| Multilayer | 2 | HRI Layer | TiO₂ | 2.379 | 0 | 29.8 | 43.1 |
| Section 9 | 3 | LRI Layer | SiO₂ | 1.462 | 0 | 13.3 | |
| Multilayer | 4 | HRI Layer | TiO₂ | 2.379 | 0 | 76.2 | 97.7 |
| Section 8 | 5 | LRI Layer | SiO₂ | 1.462 | 0 | 21.5 | |
| Multilayer | 6 | HRI Layer | TiO₂ | 2.379 | 0 | 27.2 | 84.4 |
| Section 7 | 7 | LRI Layer | SiO₂ | 1.462 | 0 | 57.2 | |
| Multilayer | 8 | MLRI Layer | SiOₓN_{y} | 1.804 | 0.00005 | 24.6 | 142.2 |
| Section 6 | 9 | LRI Layer | SiO₂ | 1.462 | 0 | 117.6 | |
| Multilayer | 10 | HRI Layer | TiO₂ | 2.379 | 0 | 12.8 | 72.3 |
| Section 5 | 11 | LRI Layer | SiO₂ | 1.462 | 0 | 59.5 | |
| Multilayer | 12 | HRI Layer | TiO₂ | 2.379 | 0 | 25.5 | 72.5 |
| Section 4 | 13 | LRI Layer | SiO₂ | 1.462 | 0 | 47 | |
| Multilayer | 14 | HRI Layer | TiO₂ | 2.379 | 0 | 25 | 79.9 |
| Section 3 | 15 | LRI Layer | SiO₂ | 1.462 | 0 | 54.9 | |
| Multilayer | 16 | HRI Layer | TiO₂ | 2.379 | 0 | 14.4 | 78.3 |
| Section 2 | 17 | LRI Layer | SiO₂ | 1.462 | 0 | 63.9 | |
| Multilayer | 18 | MLRI Layer | SiOₓN_{y} | 1.804 | 0.00005 | 15.6 | 35.6 |
| Section 1 | 19 | LRI Layer | SiO₂ | 1.462 | 0 | 20 | |
| | Substrate | | Glass B | 1.482 | 0 | 2 mm | |
| | Emergent | | Air | 1 | 0 | | |
| Total Coating | | | | | | 811.3 | |
| Thickness | | | | | | | |
| (nm) | | | | | | | |
| Max Layer | | | | | | 117.6 | |
| Thickness | | | | | | | |
| (nm) | | | | | | | |
| Min Layer | | | | | | 12.8 | |
| Thickness | | | | | | | |
| (nm) | | | | | | | |
| ΣLRI | | | | | | 560.3 | |
| thicknesses | | | | | | | |
| (nm) | | | | | | | |
| LRI thickness | | | | | | 69% | |
| % | | | | | | | |
| HI/MHI % (top | | | | | | 44% | |
| 300 nm) | | | | | | | |

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 16 and 17, respectively. A physical embodiment of the multilayer coating of Example 9 would exhibit a hardness of greater than 7 GPa, based on an empirical model built on prior experiments with similar coatings. The UV transmission bandedge (cutoff) wavelength for Example 9 (50% threshold) is ~373 nm.

Example 10—For Example 10, an article with a multilayer coating of the present disclosure was modeled to determine average transmittance through the article and average first-surface reflectance off the surface closest to the multilayer coating, in the same manner as Example 1. The design of the article consisting of a substrate (Glass B above) and a multilayer coating is as follows in Table 15 below.

TABLE 15
Example 10

| | | | | Index of | Extinction | | Section |
|---|---|---|---|---|---|---|---|
| | | | | Refraction | Coefficient | Thickness | Thickness |
| Medium | Layer | Category | Material | @550 nm | @550 nm | (nm) | (nm) |
| Incident | | | Air | 1 | 0 | | |
| Capping Layer | 1 | Capping | SiO₂ | 1.462 | 0 | 101.5 | |
| Multilayer | 2 | HRI Layer | TiO₂ | 2.379 | 0 | 24.6 | 34.8 |
| Section 12 | 3 | LRI Layer | SiO₂ | 1.462 | 0 | 10.2 | |
| Multilayer | 4 | HRI Layer | TiO₂ | 2.379 | 0 | 92.3 | 117.2 |
| Section 11 | 5 | LRI Layer | SiO₂ | 1.462 | 0 | 24.9 | |
| Multilayer | 6 | HRI Layer | TiO₂ | 2.379 | 0 | 19.4 | 226.3 |
| Section 10 | 7 | LRI Layer | SiO₂ | 1.462 | 0 | 206.9 | |
| Multilayer | 8 | HRI Layer | TiO₂ | 2.379 | 0 | 19.6 | 45.3 |
| Section 9 | 9 | LRI Layer | SiO₂ | 1.462 | 0 | 25.7 | |
| Multilayer | 10 | HRI Layer | TiO₂ | 2.379 | 0 | 81.2 | 90.9 |
| Section 8 | 11 | MHRI Layer | SiNₓ | 2.05 | 0.00017 | 9.7 | |
| Multilayer | 12 | HRI Layer | TiO₂ | 2.379 | 0 | 35.8 | 68.2 |
| Section 7 | 13 | LRI Layer | SiO₂ | 1.462 | 0 | 32.4 | |
| Multilayer | 14 | HRI Layer | TiO₂ | 2.379 | 0 | 16.2 | 223.9 |
| Section 6 | 15 | LRI Layer | SiO₂ | 1.462 | 0 | 207.7 | |
| Multilayer | 16 | MHRI Layer | SiNₓ | 2.05 | 0.00017 | 22.5 | 43.1 |
| Section 5 | 17 | LRI Layer | SiO₂ | 1.462 | 0 | 20.6 | |
| Multilayer | 18 | MLRI Layer | SiOₓN_{y} | 1.718 | 0.00005 | 10.5 | 179.9 |
| Section 4 | 19 | MHRI Layer | SiNₓ | 2.05 | 0.00017 | 146.7 | |
| | 20 | LRI Layer | SiO₂ | 1.462 | 0 | 22.7 | |
| Multilayer | 21 | MHRI Layer | SiNₓ | 2.05 | 0.00017 | 30 | 84 |
| Section 3 | 22 | LRI Layer | SiO₂ | 1.462 | 0 | 54 | |
| Multilayer | 23 | MHRI Layer | SiNₓ | 2.05 | 0.00017 | 12.5 | 98.7 |
| Section 2 | 24 | LRI Layer | SiO₂ | 1.462 | 0 | 86.2 | |
| Multilayer | 25 | MLRI Layer | SiOₓN_{y} | 1.718 | 0.00005 | 8 | 70.1 |
| Section 1 | 26 | LRI Layer | SiO₂ | 1.462 | 0 | 62.1 | |
| | Substrate | | Glass B | 1.482 | 0 | 2 mm | |
| | Emergent | | Air | 1 | 0 | | |
| Total Coating | | | | | | 1383.9 | |
| Thickness | | | | | | | |
| (nm) | | | | | | | |
| Max Layer | | | | | | 207.7 | |
| Thickness | | | | | | | |
| (nm) | | | | | | | |
| Min Layer | | | | | | 8 | |
| Thickness | | | | | | | |
| (nm) | | | | | | | |
| ΣLRI | | | | | | 864.6 | |
| thicknesses | | | | | | | |
| (nm) | | | | | | | |
| LRI thickness | | | | | | 62% | |
| % | | | | | | | |
| HI/MHI % (top | | | | | | 45% | |
| 300 nm) | | | | | | | |

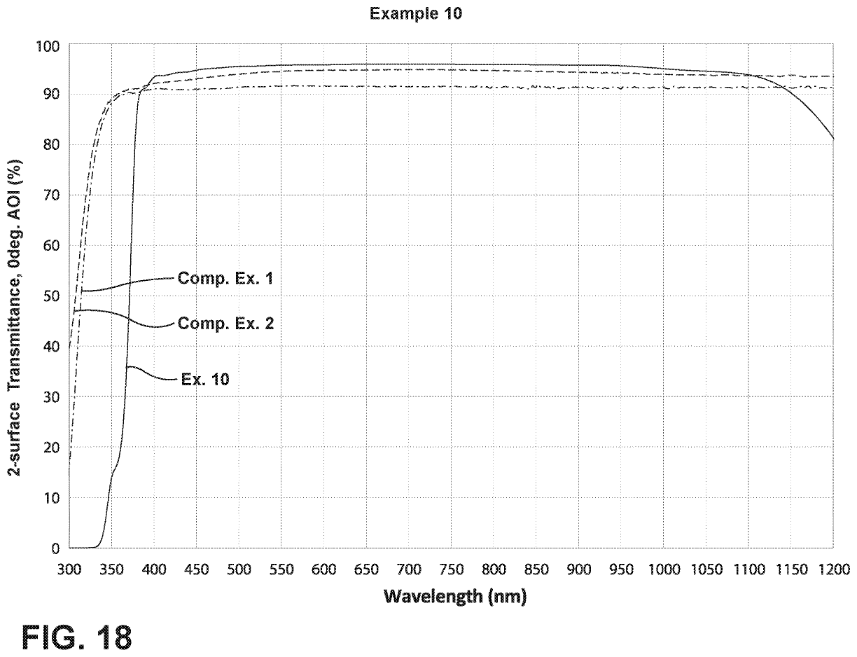

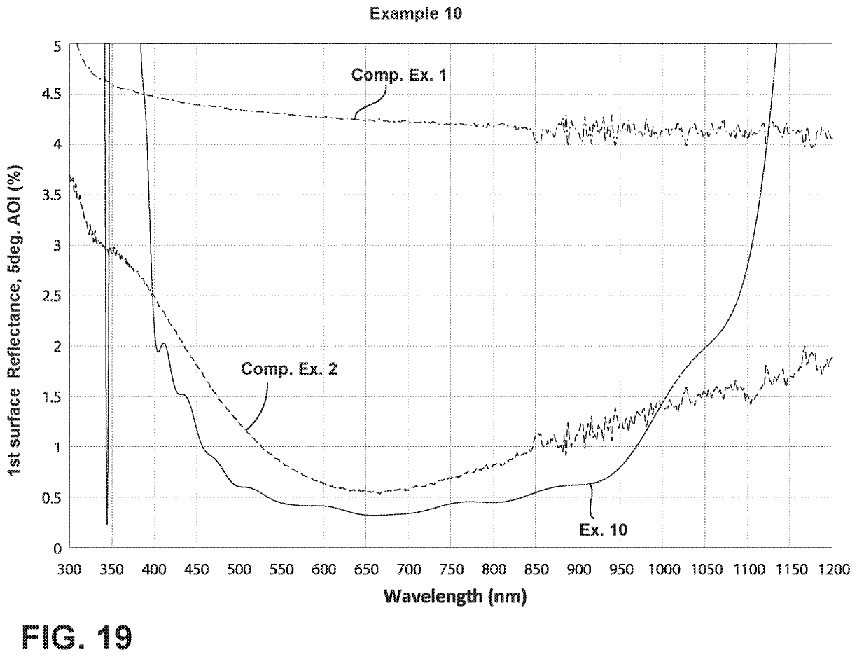

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 18 and 19, respectively. A physical embodiment of the multilayer coating of Example 1 would exhibit a hardness of greater than 7 GPa, based on an empirical model built on prior experiments with similar coatings. The UV transmission bandedge (cutoff) wavelength for Example 10 (50% threshold) is ~371 nm. In addition to the UV blocking and visible-NIR anti-reflective properties, Example 10 has an additional function of blocking near-infrared energy in the 1200 nm to 1800 nm wavelength range, as shown further below. This blocking of near-IR wavelengths from 1200 nm and beyond can contribute to reduced absorption and thermal heating of the solar cell and module. Reduced heating lowers the operating temperature of the solar cell, which in turn increases the electrical power conversion efficiency of the solar cell. Although wavelengths from 1200 nm to 1800 nm are below the bandgap of silicon and thus may not be absorbed by pure silicon, wavelengths longer than 1200 are significantly absorbed by highly doped silicon of the types used in solar cells, and in some cases the absorption of these NIR wavelengths below the Si bandgap can approach or exceed 30% at the module level, contributing significantly to thermal heating of the panel. Reflecting NIR energy beyond 1200 nm thus contributes to cooling the solar panel and increasing its power generation efficiency. Thus, Example 10 combines three functions which can be beneficial to solar module operation: 1) UV blocking at wavelengths less than 350 nm; 2) Low reflection and high transmission at solar cell operating wavelengths from 400 nm to 1200 nm; and 3) Near-IR blocking at wavelengths of 1200 nm to 1800 nm.

Example 11—For Example 11, an article with a multilayer coating of the present disclosure was modeled to determine average transmittance through the article and average first-surface reflectance off the surface closest to the multilayer coating, in the same manner as Example 1. The design of the article consisting of a substrate (Glass C above) and a multilayer coating is as follows in Table 16 below.

TABLE 16
Example 11

| | | | | Index of | Extinction | | Section |
|---|---|---|---|---|---|---|---|
| | | | | Refraction | Coefficient | Thickness | Thickness |
| Medium | Layer | Category | Material | @550 nm | @550 nm | (nm) | (nm) |
| Incident | | | Air | 1 | 0 | | |
| Capping Layer | 1 | Capping | SiO₂ | 1.462 | 0 | 104.9 | |
| Multilayer | 2 | HRI Layer | TiO₂ | 2.464 | 0 | 23.6 | 41.2 |
| Section 5 | 3 | LRI Layer | SiO₂ | 1.462 | 0 | 17.6 | |
| Multilayer | 4 | HRI Layer | TiO₂ | 2.464 | 0 | 59.3 | 70.2 |
| Section 4 | 5 | LRI Layer | SiO₂ | 1.462 | 0 | 10.8 | |
| Multilayer | 6 | HRI Layer | TiO₂ | 2.464 | 0 | 38.4 | 70.2 |
| Section 3 | 7 | LRI Layer | SiO₂ | 1.462 | 0 | 31.9 | |
| Multilayer | 8 | HRI Layer | TiO₂ | 2.464 | 0 | 19.3 | 74.4 |
| Section 2 | 9 | LRI Layer | SiO₂ | 1.462 | 0 | 55.1 | |
| Multilayer | 10 | HRI Layer | SiNₓ | 2.050 | 0.00017 | 14.1 | 57.7 |
| Section 1 | 11 | LRI Layer | SiO₂ | 1.462 | 0 | 43.7 | |
| | Substrate | | Glass C | 1.514 | 0 | 0.1 mm | |
| | Emergent | | Air | 1 | 0 | | |
| Total Coating | | | | | | 418.6 | |
| Thickness | | | | | | | |
| (nm) | | | | | | | |
| Max Layer | | | | | | 59.3 | |
| Thickness | | | | | | | |
| (nm) | | | | | | | |
| Min Layer | | | | | | 10.8 | |
| Thickness | | | | | | | |
| (nm) | | | | | | | |
| ΣLRI | | | | | | 264.0 | |
| thicknesses | | | | | | | |
| (nm) | | | | | | | |
| LRI thickness | | | | | | 63.1% | |
| % | | | | | | | |
| HI/MHI % (top | | | | | | 44.9% | |
| 300 nm) | | | | | | | |

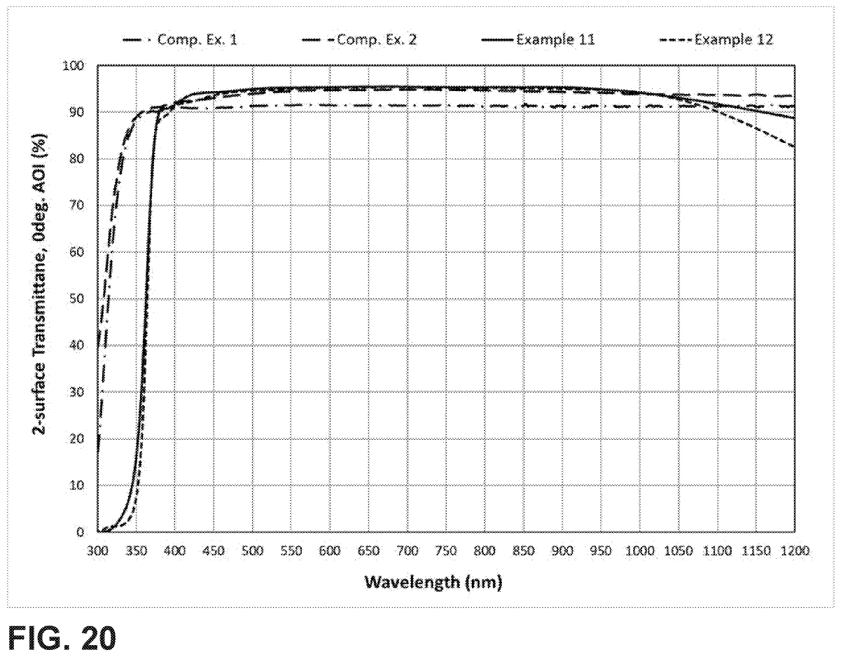

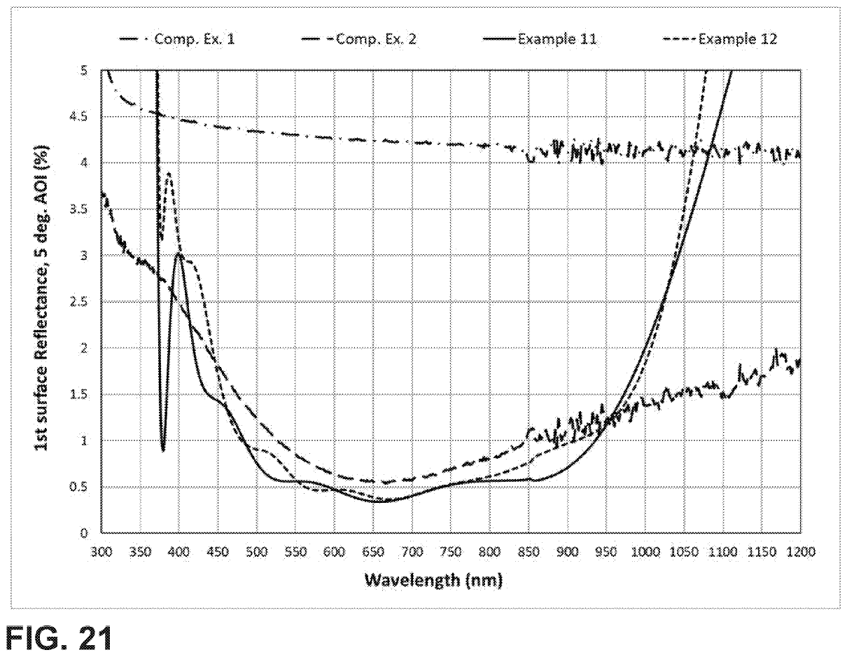

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 20 and 21, respectively. A physical embodiment of the multilayer coating of Example 11 would exhibit a hardness of greater than 8 GPa (equal to ~9.5 GPa), based on an empirical model built on prior experiments with similar coatings. The UV transmission bandedge (cutoff) wavelength for Example 11 (50% threshold) is ~363 nm. In addition to the UV blocking and visible-NIR anti-reflective properties, Example 11 has an additional function of blocking near-infrared energy in the 1200 nm to 1800 nm wavelength range, as shown further below. This blocking of near-IR wavelengths from 1200 nm and beyond can contribute to reduced absorption and thermal heating of the solar cell and module. Reduced heating lowers the operating temperature of the solar cell, which in turn increases the electrical power conversion efficiency of the solar cell. Although wavelengths from 1200 nm to 1800 nm are below the bandgap of silicon and thus may not be absorbed by pure silicon, wavelengths longer than 1200 are significantly absorbed by highly doped silicon of the types used in solar cells, and in some cases the absorption of these NIR wavelengths below the Si bandgap can approach or exceed 30% at the module level, contributing significantly to thermal heating of the panel. Reflecting NIR energy beyond 1200 nm thus contributes to cooling the solar panel and increasing its power generation efficiency. Example 11 has a two-surface transmission less than 85% from 1300 to 1800 nm, and less than 82% from 1400 to 1800 nm. Thus, Example 11 combines three functions which can be beneficial to solar module operation: 1) UV blocking at wavelengths less than 350 nm; 2) Low reflection and high transmission at solar cell operating wavelengths from 400 nm to 1200 nm; and 3) Near-IR blocking at wavelengths of 1200 nm to 1800 nm. Example 11 also has a low coating thickness of less than 425 nm, which generally translates to lower manufacturing costs, such as when formed via sputter deposition. The multilayer coating of Example 11 may advantageously be applied on a thin (e.g. 30 μm to 150 μm thick) glass substrate, which can be beneficial for space-based solar applications where light weight of the solar module is an important factor. The UV-blocking behavior of the Example 11 multilayer coating enables a thinner glass substrate to be used, which generally translates into a glass with lower UV absorption and higher visible to near-IR (e.g. 380-1200 nm or 400-900 nm) transmission, since strongly UV-absorbing glasses typically have some parasitic absorption in the visible to near-IR ranges.

Example 12—For Example 12, an article with a multilayer coating of the present disclosure was modeled to determine average transmittance through the article and average first-surface reflectance off the surface closest to the multilayer coating, in the same manner as Example 1. The design of the article consisting of a substrate (Glass C above) and a multilayer coating is as follows in Table 17 below.

TABLE 17
Example 12

| | | | | Index of | Extinction | | Section |
|---|---|---|---|---|---|---|---|
| | | | | Refraction | Coefficient | Thickness | Thickness |
| Medium | Layer | Category | Material | @550 nm | @550 nm | (nm) | (nm) |
| Incident | | | Air | 1 | 0 | | |
| Capping Layer | 1 | Capping | SiO₂ | 1.462 | 0 | 102.1 | |
| Multilayer | 2 | HRI Layer | SiNₓ | 2.050 | 0.00017 | 143.6 | 183.0 |
| Section 8 | 3 | LRI Layer | SiO₂ | 1.462 | 0 | 39.4 | |
| Multilayer | 4 | HRI Layer | SiNₓ | 2.050 | 0.00017 | 17.9 | 138.9 |
| Section 7 | 5 | LRI Layer | SiO₂ | 1.462 | 0 | 121.0 | |
| Multilayer | 6 | HRI Layer | SiNₓ | 2.050 | 0.00017 | 15.0 | 68.9 |
| Section 6 | 7 | LRI Layer | SiO₂ | 1.462 | 0 | 53.9 | |
| Multilayer | 8 | HRI Layer | SiNₓ | 2.050 | 0.00017 | 54.6 | 80.2 |
| Section 5 | 9 | LRI Layer | SiO₂ | 1.462 | 0 | 25.6 | |
| Multilayer | 10 | HRI Layer | TiO₂ | 2.464 | 0 | 31.5 | 65.9 |
| Section 4 | 11 | LRI Layer | SiO₂ | 1.462 | 0 | 34.5 | |
| Multilayer | 12 | HRI Layer | TiO₂ | 2.464 | 0 | 23.8 | 72.6 |
| Section 3 | 13 | LRI Layer | SiO₂ | 1.462 | 0 | 48.8 | |
| | 14 | HRI Layer | TiO₂ | 2.464 | 0 | 12.5 | 69.5 |
| Multilayer | 15 | LRI Layer | SiO₂ | 1.462 | 0 | 57.0 | |
| Section 2 | | | | | | | |
| Multilayer | 16 | HRI Layer | SiNₓ | 2.050 | 0.00017 | 9.1 | 29.2 |
| Section 1 | 17 | LRI Layer | SiO₂ | 1.462 | 0 | 20.0 | |
| | Substrate | | Glass C | 1.514 | 0 | 0.1 mm | |
| | Emergent | | Air | 1 | 0 | | |
| Total Coating | | | | | | 810.3 | |
| Thickness | | | | | | | |
| (nm) | | | | | | | |
| Max Layer | | | | | | 143.6 | |
| Thickness | | | | | | | |
| (nm) | | | | | | | |
| Min Layer | | | | | | 9.1 | |
| Thickness | | | | | | | |
| (nm) | | | | | | | |
| ΣLRI | | | | | | 502.4 | |
| thicknesses | | | | | | | |
| (nm) | | | | | | | |
| LRI thickness | | | | | | 62% | |
| % | | | | | | | |
| HI/MHI % (top | | | | | | 52.8% | |
| 300 nm) | | | | | | | |

The model calculated reflectance off the prime surface (“1-side” or “1st surface”) of the article as a function of wavelength. In addition, the model calculated transmittance through the entire article (referred to as “2-side” or “2-surface” transmittance). The calculations were tabulated and graphed. The graphs for transmittance and reflectance are reproduced as FIGS. 20 and 21, respectively. A physical embodiment of the multilayer coating of Example 1 would exhibit a hardness of greater than 10 GPa (equal to about 11 GPa), based on an empirical model built on prior experiments with similar coatings. The UV transmission bandedge (cutoff) wavelength for Example 12 (50% threshold) is ~365 nm. In addition to the UV blocking and visible-NIR anti-reflective properties, Example 12 has an additional function of blocking near-infrared energy in the 1200 nm to 1800 nm wavelength range, as shown further below. This blocking of near-IR wavelengths from 1200 nm and beyond can contribute to reduced absorption and thermal heating of the solar cell and module. Reduced heating lowers the operating temperature of the solar cell, which in turn increases the electrical power conversion efficiency of the solar cell. As described above, blocking near-IR in the 1200 nm to 1800+ nm wavelength range (e.g. from 1200 nm to 2000 nm) can increase solar panel efficiency through lowering solar cell operating temperature. Example 12 has a two-surface transmission less than 75% from 1300 to 1800 nm, and less than 72% from 1400 to 1800 nm. Thus, Example 12 combines three functions which can be beneficial to solar module operation: 1) UV blocking at wavelengths less than 350 nm; 2) Low reflection and high transmission at solar cell operating wavelengths from 400 nm to 1200 nm; and 3) Near-IR blocking at wavelengths of 1200 nm to 1800 nm. Similar to Example 11, Example 12 was preferably designed for coating on a thin (e.g. 30 μm to 150 μm thick) glass substrate, which can be beneficial for space-based solar applications where light weight of the solar module is an important factor. The UV-blocking behavior of the Example 12 coating enables a thinner glass to be used, which generally translates into a glass with lower UV absorption and higher visible to near-IR (e.g. 380-1200 nm or 400-900 nm) transmission, since strongly UV-absorbing glasses typically have some parasitic absorption in the visible to near-IR ranges.

A notable design feature of Example 12 is the relatively thick 143.6 nm layer 2 of SiNₓ, which imparts high hardness to the overall coated article. In addition, the TiO₂ layers are all placed below multiple layers of SiNₓ (and SiO₂), leading to overall improvements in hardness, damage resistance, and abrasion resistance for the overall coating stack, stemming from the high hardness of SiNₓ and robust adhesion and chemical durability of the SiNₓ/SiO₂ layers and interfaces. Thus, in this design, the SiNₓ and SiNₓ/SiO₂ layers are used as protective layers over the TiO₂ layers, while the TiO₂ layers offer optical performance (e.g. reflectance and transmittance) as well as UV blocking benefits. In addition, over 50% of the top 300 nm of the coating consists of high index and high hardness SiNₓ material. Preferable designs may comprise an SiNₓ layer that is greater than 80 nm, 100 nm, 120 nm, or 140 nm in thickness. This thick SiNₓ layer is preferably located at least partially within the top 200 nm, top 300 nm, or top 500 nm of the full coating stack to impart hardness near the external surface for damage resistance.

While Example 12 contains multiple layers of both SiNₓ (to improve hardness) and TiO₂ (to optimize transmission, reflection, and UV blocking), another important feature of the Example 12 design is that SiNₓ and TiO₂ layers are not immediately in contact with one another, having intervening layers of SiO₂. We have found that this design strategy can reduce the visible-NIR absorption of coatings, by avoiding the formation of trace titanium nitride species at SiNₓ—TiO₂ interfaces. In some designs that do contain SiNₓ—TiO₂ interfaces, such as Example 10, we have further found that placing very thin (e.g. 0.5-1.0 nm) layers of SiO₂ in between the SiNₓ and TiO₂ layers causes only small modifications to the optical properties or layer design, while avoiding parasitic absorption from titanium nitride formation. Thus, Example 10 can be readily modified by placing ~0.5-1.0 nm layers of SiO₂ in between SiNₓ and TiO₂ at every SiNₓ—TiO₂ interface.

Comparative Example 1—For Comparative Example 1, a commercially available solar cover glass without any form of anti-reflective coating was obtained. Reflectance off the prime surface (“1-side” or “1st surface”) of the article as a function of wavelength was measured. In addition, transmittance through the entire article (referred to as “2-side” or “2-surface” transmittance) was measured. The calculations were tabulated and graphed. The graphs for transmittance and reflectance are reproduced in FIGS. 10-21 along with each of the Examples for comparison. Comparative Example 1 has a 50% T UV bandedge of 315 nm, which is generally considered to lead to an inadequate level of UV blocking for targeted applications.

Comparative Example 2—For Comparative Example 2, a commercially available solar cover glass with a porous sol-gel anti-reflective coating was obtained. The design of the article consisting of a substrate (soda lime glass composition) and an anti-reflective coating (single layer) is as follows in Table 16 below.

TABLE 16
Comparative Example 2

| | | | Index of | Physical |
|---|---|---|---|---|
| | | | refraction @ | Thickness |
| Medium | Layer | Material | 550 nm | (nm) |
| Incident | | Air | 1 | |
| | 1 | Porous SiO₂ | ~1.33 | ~100 |
| Substrate | | Soda lime glass | ~1.5 | ~2 mm |
| Emergent | | Air | 1 | |
| Total | | | | ~100 |
| Thickness (nm) | | | | |

Reflectance off the prime surface (“1-side” or “1st surface”) of the article as a function of wavelength was measured. In addition, transmittance through the entire article (referred to as “2-side” or “2-surface” transmittance) was measured. The calculations were tabulated and graphed. The graphs for transmittance and reflectance are reproduced in FIGS. 10-19 along with each of the Examples for comparison. Comparative Example 2 has a 50% T UV bandedge of 308 nm, which is generally considered to lead to an inadequate level of UV blocking for targeted applications.

Comparative Example 3—For Comparative Example 3, an article with an anti-reflective coating was modeled to determine average transmittance through the article and average first-surface reflectance off the surface closest to the anti-reflective coating, in the same manner as Example 1. The design of the article consisting of a substrate (Glass F above) and an anti-reflective coating is as follows in Table 17 below.

TABLE 17
Comp. Ex. 3

| | | | | Index of | Extinction | | Section |
|---|---|---|---|---|---|---|---|
| | | | | Refraction@550 | Coefficient | Thickness | Thickness |
| Medium | Layer | Category | Material | nm | @550 nm | (nm) | (nm) |
| Incident | | | Air | 1 | 0 | | |
| Capping | 1 | Capping | SiO₂ | 1.471 | 0 | 94.6 | |
| Layer | | | | | | | |
| Multilayer | 2 | MHRI Layer | SiNₓ | 2.028 | 0.00057 | 158.5 | 195.7 |
| Section 2 | 3 | LRI Layer | SiO₂ | 1.456 | 0 | 37.2 | |
| Multilayer | 4 | MHRI Layer | SiNₓ | 2.041 | 0.00037 | 23.1 | 48.1 |
| Section 1 | 5 | LRI Layer | SiO₂ | 1.449 | 0 | 25 | |
| | Substrate | | Glass F | 1.508 | 0 | 1.1 mm | |
| | Emergent | | Air | 1 | 0 | | |
| Total | | | | | | 338.4 | |
| Coating | | | | | | | |
| Thickness | | | | | | | |
| (nm) | | | | | | | |
| Max Layer | | | | | | 158.5 | |
| Thickness | | | | | | | |
| (nm) | | | | | | | |
| Min Layer | | | | | | 23.1 | |
| Thickness | | | | | | | |
| (nm) | | | | | | | |
| ΣLRI | | | | | | 156.8 | |
| thickness | | | | | | | |
| (nm) | | | | | | | |
| LRI | | | | | | 46% | |
| thickness | | | | | | | |
| % | | | | | | | |
| HI/MHI % | | | | | | 61% | |
| (top 300 | | | | | | | |
| nm) | | | | | | | |

Reflectance off the prime surface (“1-side” or “1st surface”) of the article as a function of wavelength was measured. In addition, transmittance through the entire article (referred to as “2-side” or “2-surface” transmittance) was measured. The calculations were tabulated and graphed. The graphs for transmittance and reflectance are reproduced in FIGS. 10 and 11 along with several of the Examples for comparison. Comparative Example 3 has a 50% T UV bandedge of 299 nm, which is generally considered to lead to an inadequate level of UV blocking for targeted applications.

Comparative Example 4—For Comparative Example 4, Glass E with no coating and 100 μm thickness was included to illustrate the comparison between the experimentally measured transmission of a CeO₂-doped glass at 100 μm thickness, designed for UV blocking through bulk absorption in the glass, and the various modeled coated glasses of the invention. Comparative Example 4 has a 50% T UV bandedge of 344 nm, which is a relevant level of UV blocking for some applications. One of the advantages of a coated glass over a bulk absorbing glass such as Comp. Ex. 4, as in some of the Examples, is that they can have a sharper or steeper UV cutoff function than a bulk absorber like a doped glass or polymer. This advantage of coatings over bulk absorbers can be especially relevant for applications where thin glass is desirable, for example in space-based photovoltaics where lightweight panels are important to reduce launch costs. The UV cutoff sharpness can be defined as a wavelength bandwidth between two transmission thresholds in the UV range, for example, the bandwidth between 90% UV edge transmission and 2% UV edge transmission, or the bandwidth between 85% UV edge transmission and 5% UV edge transmission. We will refer to these two metrics as “UV cut sharpness (90-2)” and “UV cut sharpness (85-5)”, respectively. These are calculated simply by subtracting the wavelength of the lower UV edge transmission value from the wavelength of the higher UV edge transmission value to give a bandwidth metric, as illustrated in Table 18 below for all Examples. These UV cutoff sharpness values are particularly relevant for articles having preferred UV blocking performance for solar applications, for example, articles that have <50% average transmittance in the range from 300-350 nm. Articles with UV bandedges below 300 nm are less preferred. If there are oscillations in the transmission spectrum, for example if the transmission increases above 85% then drops below 85%, the wavelength values that result in the widest calculated UV sharpness metric should be used (meaning that the transmission should remain above 85% at wavelengths longer than the defined 85% T UV wavelength, and should remain below 5% at wavelengths shorter than the defined 5% T UV wavelength).

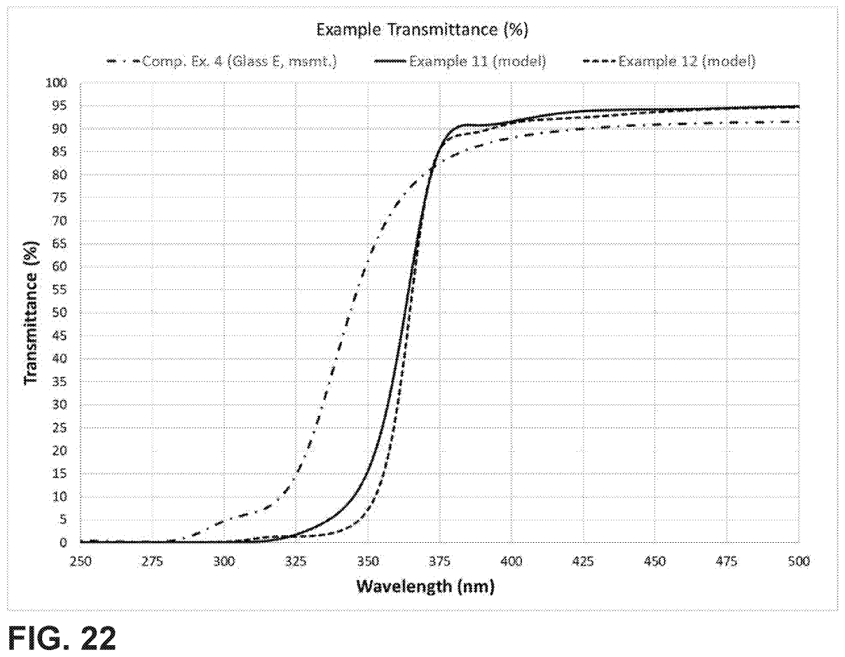

Reflectance off the prime surface (“1-side” or “1st surface”) of the article as a function of wavelength was measured. In addition, transmittance through the entire article (referred to as “2-side” or “2-surface” transmittance) was measured. The calculations were tabulated and graphed. The graph for transmittance for Comparative Example 4 is reproduced in at FIGS. 20-22 along with Examples 11 and 12 for comparison.

Measured and calculated (as indicated) transmittance data for Comparative Examples 1~4 and Examples 1-12 is consolidated in Table 18 below for ready comparison. Transmittance data reported in any particular row is an average of the transmittance data points measured within the stated wavelength range. For example, “450-500” means the average transmittance (in percentage) for measured/calculated values within the wavelength range of from 450 nm to 500 nm.

TABLE 18
Avg. 2-surface % T

| wavelength | Comp. Ex. 1 | Comp. Ex. 2 | Comp. Ex. 3 | Ex. 1 | Ex. 2 | Ex. 3 | Ex. 4 | Ex. 5 |
|---|---|---|---|---|---|---|---|---|
| range (nm) | (msmt.) | (msmt.) | (model) | (model) | (model) | (model) | (model) | (model) |
| 200-250 | | | 0.21 | 0 | 0.01 | 0 | 0 | 0.55 |
| 250-300 | | | 12.8 | 0.01 | 0.02 | 0.01 | 0.01 | 0.3 |
| 300-350 | 65 | 71.7 | 71.3 | 1.05 | 8.26 | 14.97 | 7.41 | 9.75 |
| 350-400 | 90.2 | 90.9 | 77 | 53.56 | 78.89 | 83.74 | 79.94 | 82.73 |
| 400-450 | 91 | 92.6 | 92.2 | 94.53 | 90.34 | 92.91 | 91.15 | 93.66 |
| 450-500 | 91.1 | 93.5 | 94.7 | 95.18 | 94.24 | 93.9 | 93.7 | 94.64 |
| 500-550 | 91.5 | 94.3 | 94.7 | 94.78 | 94.48 | 94.32 | 94.38 | 95.02 |
| 550-600 | 91.6 | 94.6 | 95.1 | 95.03 | 94.9 | 94.21 | 94.61 | 94.77 |
| 600-650 | 91.5 | 94.7 | 94.9 | 95.23 | 94.8 | 94.33 | 94.85 | 95.26 |
| 650-700 | 91.5 | 94.8 | 94.5 | 95.04 | 94.54 | 94.67 | 94.76 | 95.07 |
| 700-750 | 91.5 | 94.8 | 94.4 | 94.86 | 94.53 | 94.6 | 94.96 | 94.76 |
| 750-800 | 91.4 | 94.7 | 94.4 | 94.87 | 94.76 | 94.52 | 95.09 | 94.92 |
| 800-850 | 91.3 | 94.6 | 94.4 | 95.04 | 95.09 | 94.73 | 94.91 | 95.3 |
| 850-900 | 91.3 | 94.4 | 94.2 | 95.18 | 95.32 | 94.93 | 95.1 | 95.42 |
| 900-950 | 91.3 | 94.3 | 93.6 | 95.01 | 95.27 | 94.66 | 95.36 | 95.04 |
| 950-1000 | 91.3 | 94 | 92.7 | 94.53 | 94.94 | 93.74 | 94.51 | 94.32 |
| 1000-1050 | 91.3 | 93.8 | 91.6 | 93.78 | 94.4 | 92.25 | 91.82 | 93.53 |
| 1050-1100 | 91.3 | 93.7 | 90.3 | 92.85 | 93.7 | 90.46 | 87.75 | 92.82 |
| 1100-1200 | 91.4 | 93.6 | 88.4 | 91.25 | 92.52 | 87.67 | 81.32 | 92.13 |
| 1200-1300 | 91.4 | 93.4 | 86 | 89.1 | 90.92 | 84.43 | 75.25 | 91.76 |
| 1300-1400 | 91.5 | 93.3 | 84.1 | 87.24 | 89.53 | 82.01 | 72.86 | 91.78 |
| 1400-1500 | 91.5 | 93 | 82.6 | 85.74 | 88.4 | 80.31 | 73.17 | 91.83 |
| 1500-1600 | 91.7 | 93 | 81.5 | 84.62 | 87.53 | 79.14 | 75.06 | 91.74 |
| 1600-1700 | 91.7 | 92.8 | 80.8 | 83.81 | 86.88 | 78.33 | 77.69 | 91.47 |
| 1700-1800 | 91.5 | 92.1 | 80.4 | 83.2 | 86.37 | 77.71 | 80.46 | 91.03 |
| 450-900 avg. | 91.4 | 94.5 | 94.6 | 95.0 | 94.7 | 94.5 | 94.7 | 95.0 |

TABLE 18
Avg. 2-surface % T

| wavelength | Comp. Ex. 1 | Comp. Ex. 2 | Comp. Ex. 3 | Ex. 6 | Ex. 7 | Ex. 8 | Ex. 9 | Ex. 10 |
|---|---|---|---|---|---|---|---|---|
| range (nm) | (msmt.) | (msmt.) | (model) | (model) | (model) | (model) | (model) | (model) |
| 200-250 | | | 0.21 | 0 | 0 | 0.02 | 0 | 0 |
| 250-300 | | | 12.8 | 0.03 | 0 | 0.02 | 0 | 0 |
| 300-350 | 65 | 71.7 | 71.3 | 45.91 | 7.02 | 1.73 | 0.2 | 2.07 |
| 350-400 | 90.2 | 90.9 | 77 | 87.5 | 76.03 | 58.15 | 51.9 | 58.87 |
| 400-450 | 91 | 92.6 | 92.2 | 92.12 | 89.13 | 94.46 | 94.63 | 94.1 |
| 450-500 | 91.1 | 93.5 | 94.7 | 94.22 | 92.67 | 95.15 | 95.35 | 95.17 |
| 500-550 | 91.5 | 94.3 | 94.7 | 93.62 | 93.54 | 95.51 | 95.67 | 95.59 |
| 550-600 | 91.6 | 94.6 | 95.1 | 93.33 | 93.6 | 95.74 | 95.83 | 95.78 |
| 600-650 | 91.5 | 94.7 | 94.9 | 93.66 | 93.9 | 95.82 | 95.89 | 95.88 |
| 650-700 | 91.5 | 94.8 | 94.5 | 94.14 | 94.37 | 95.88 | 95.98 | 95.95 |
| 700-750 | 91.5 | 94.8 | 94.4 | 94.44 | 94.88 | 95.85 | 95.92 | 95.94 |
| 750-800 | 91.4 | 94.7 | 94.4 | 94.31 | 95.11 | 95.76 | 95.88 | 95.89 |
| 800-850 | 91.3 | 94.6 | 94.4 | 94.1 | 95.03 | 95.66 | 95.84 | 95.86 |
| 850-900 | 91.3 | 94.4 | 94.2 | 94.16 | 94.73 | 95.52 | 95.72 | 95.77 |
| 900-950 | 91.3 | 94.3 | 93.6 | 93.64 | 94.28 | 95.25 | 95.59 | 95.72 |
| 950-1000 | 91.3 | 94 | 92.7 | 92.96 | 93.76 | 94.79 | 95.36 | 95.35 |
| 1000-1050 | 91.3 | 93.8 | 91.6 | 92.27 | 93.22 | 94.1 | 94.65 | 94.75 |
| 1050-1100 | 91.3 | 93.7 | 90.3 | 91.62 | 92.69 | 93.2 | 93.02 | 94.27 |
| 1100-1200 | 91.4 | 93.6 | 88.4 | 90.85 | 91.98 | 91.57 | 88.54 | 89.3 |
| 1200-1300 | 91.4 | 93.4 | 86 | 89.98 | 91.2 | 89.22 | 81 | 68.81 |
| 1300-1400 | 91.5 | 93.3 | 84.1 | 89.47 | 90.63 | 87 | 74.45 | 47.55 |
| 1400-1500 | 91.5 | 93 | 82.6 | 89.05 | 90.24 | 85.12 | 70.38 | 36.96 |
| 1500-1600 | 91.7 | 93 | 81.5 | 88.64 | 90 | 83.64 | 68.76 | 34.26 |
| 1600-1700 | 91.7 | 92.8 | 80.8 | 88.14 | 89.87 | 82.56 | 69.01 | 36.7 |
| 1700-1800 | 91.5 | 92.1 | 80.4 | 87.6 | 89.79 | 81.79 | 70.53 | 43.3 |
| 450-900 avg. | 91.4 | 94.5 | 94.6 | 94.0 | 94.2 | 95.7 | 95.8 | 95.8 |

TABLE 18
Avg. 2-surface % T

| wavelength | Comp. Ex. 1 | Comp. Ex. 2 | Comp. Ex. 3 | Comp. Ex. 4 | Ex. 11 | Ex. 12 |
|---|---|---|---|---|---|---|
| range (nm) | (msmt.) | (msmt.) | (model) | (msmt.) | (model) | (model) |
| 200-250 | | | 0.21 | 1.0 | 0.0 | 0.0 |
| 250-300 | | | 12.8 | 1.1 | 0.0 | 0.0 |
| 300-350 | 65 | 71.7 | 71.3 | 23.1 | 3.6 | 1.9 |
| 350-400 | 90.2 | 90.9 | 77 | 79.9 | 69.5 | 65.7 |
| 400-450 | 91 | 92.6 | 92.2 | 89.8 | 93.5 | 92.5 |
| 450-500 | 91.1 | 93.5 | 94.7 | 91.2 | 94.5 | 94.3 |
| 500-550 | 91.5 | 94.3 | 94.7 | 91.6 | 95.1 | 94.8 |
| 550-600 | 91.6 | 94.6 | 95.1 | 91.8 | 95.2 | 95.2 |
| 600-650 | 91.5 | 94.7 | 94.9 | 91.9 | 95.4 | 95.3 |
| 650-700 | 91.5 | 94.8 | 94.5 | 92.0 | 95.5 | 95.4 |
| 700-750 | 91.5 | 94.8 | 94.4 | 92.0 | 95.4 | 95.4 |
| 750-800 | 91.4 | 94.7 | 94.4 | 92.1 | 95.3 | 95.3 |
| 800-850 | 91.3 | 94.6 | 94.4 | 92.1 | 95.3 | 95.2 |
| 850-900 | 91.3 | 94.4 | 94.2 | 92.1 | 95.4 | 95.1 |
| 900-950 | 91.3 | 94.3 | 93.6 | 92.2 | 95.1 | 95.0 |
| 950-1000 | 91.3 | 94 | 92.7 | 92.2 | 94.6 | 94.6 |
| 1000-1050 | 91.3 | 93.8 | 91.6 | 92.2 | 93.6 | 93.6 |
| 1050-1100 | 91.3 | 93.7 | 90.3 | 92.2 | 92.4 | 91.6 |
| 1100-1200 | 91.4 | 93.6 | 88.4 | 92.3 | 90.2 | 86.5 |
| 1200-1300 | 91.4 | 93.4 | 86 | 92.3 | 87.2 | 78.7 |
| 1300-1400 | 91.5 | 93.3 | 84.1 | 92.4 | 84.3 | 72.5 |
| 1400-1500 | 91.5 | 93 | 82.6 | 92.5 | 81.9 | 69.0 |
| 1500-1600 | 91.7 | 93 | 81.5 | 92.5 | 80.0 | 68.1 |
| 1600-1700 | 91.7 | 92.8 | 80.8 | 92.5 | 78.6 | 69.1 |
| 1700-1800 | 91.5 | 92.1 | 80.4 | 92.4 | 77.6 | 71.3 |
| 450-900 avg. | 91.4 | 94.5 | 94.6 | 91.9 | 95.2 | 95.1 |

Measured and calculated (as indicated) reflectance data for Comparative Examples 1-4 and Examples 1-12 is consolidated in Table 19 below for ready comparison. Reflectance data reported in any particular row is an average of the transmittance data points measured within the stated wavelength range. For example, “450-500” means the average reflectance (in percentage) for measured/calculated values within the wavelength range of from 450 nm to 500 nm.

TABLE 19
Avg. 1-surface % R

| wavelength | Comp. Ex. 1 | Comp. Ex. 2 | Comp. Ex. 3 | Ex. 1 | Ex. 2 | Ex. 3 | Ex. 4 | Ex. 5 |
|---|---|---|---|---|---|---|---|---|
| range (nm) | (msmt.) | (msmt.) | (model) | (model) | (model) | (model) | (model) | (model) |
| 200-250 | | | 23.5 | 17.37 | 20.38 | 8.84 | 22.38 | 17.41 |
| 250-300 | | | 28.8 | 32.54 | 15.11 | 31.28 | 39.09 | 66.42 |
| 300-350 | 4.8 | 3.2 | 12.1 | 67.94 | 40.08 | 13.29 | 77.44 | 87.65 |
| 350-400 | 4.5 | 2.7 | 18.7 | 41.74 | 13.15 | 6.66 | 3.48 | 11.22 |
| 400-450 | 4.43 | 2.14 | 2.78 | 1.06 | 5.54 | 1.84 | 1.08 | 1.34 |
| 450-500 | 4.37 | 1.5 | 0.5 | 0.46 | 1.49 | 1.09 | 0.56 | 0.78 |
| 500-550 | 4.32 | 1.02 | 0.75 | 0.98 | 1.3 | 0.74 | 0.69 | 0.6 |
| 550-600 | 4.29 | 0.727 | 0.43 | 0.76 | 0.91 | 0.95 | 0.85 | 0.97 |
| 600-650 | 4.26 | 0.584 | 0.68 | 0.6 | 1.07 | 0.79 | 0.79 | 0.52 |
| 650-700 | 4.24 | 0.562 | 1.09 | 0.84 | 1.38 | 0.61 | 0.96 | 0.78 |
| 700-750 | 4.21 | 0.635 | 1.24 | 1.06 | 1.4 | 0.88 | 0.89 | 1.14 |
| 750-800 | 4.2 | 0.753 | 1.17 | 1.03 | 1.14 | 0.94 | 0.85 | 0.95 |
| 800-850 | 4.16 | 0.9 | 1.16 | 0.87 | 0.81 | 0.58 | 1.07 | 0.57 |
| 850-900 | 4.14 | 1.06 | 1.43 | 0.8 | 0.64 | 0.32 | 0.88 | 0.53 |
| 900-950 | 4.13 | 1.19 | 2.08 | 1.03 | 0.75 | 0.69 | 0.63 | 1.01 |
| 950-1000 | 4.13 | 1.32 | 3.08 | 1.58 | 1.12 | 1.88 | 1.6 | 1.8 |
| 1000-1050 | 4.13 | 1.46 | 4.32 | 2.4 | 1.73 | 3.7 | 4.49 | 2.68 |
| 1050-1100 | 4.14 | 1.56 | 5.68 | 3.44 | 2.5 | 5.83 | 8.81 | 3.45 |
| 1100-1200 | 4.11 | 1.72 | 7.78 | 5.2 | 3.82 | 8.99 | 15.58 | 4.21 |
| 1200-1300 | 4.1 | 1.97 | 10.3 | 7.53 | 5.56 | 12.52 | 21.95 | 4.62 |
| 1300-1400 | 4.08 | 2.14 | 12.4 | 9.56 | 7.09 | 15.04 | 24.5 | 4.63 |
| 1400-1500 | 4.06 | 2.3 | 14 | 11.17 | 8.3 | 16.75 | 24.25 | 4.58 |
| 1500-1600 | 4.05 | 2.41 | 15.2 | 12.34 | 9.2 | 17.9 | 22.34 | 4.64 |
| 1600-1700 | 4.03 | 2.48 | 15.9 | 13.14 | 9.84 | 18.69 | 19.61 | 4.88 |
| 1700-1800 | 4.04 | 2.5 | 16.3 | 13.7 | 10.29 | 19.35 | 16.71 | 5.26 |
| 450-900 avg. | 4.24 | 0.86 | 0.94 | 0.82 | 1.13 | 0.77 | 0.84 | 0.76 |

TABLE 19
Avg. 1-surface % R

| wavelength | Comp. Ex. 1 | Comp. Ex. 2 | Comp. Ex. 3 | Ex. 6 | Ex. 7 | Ex. 8 | Ex. 9 | Ex. 10 |
|---|---|---|---|---|---|---|---|---|
| range (nm) | (msmt.) | (msmt.) | (model) | (model) | (model) | (model) | (model) | (model) |
| 200-250 | | | 23.5 | 3.79 | 11.6 | 12.47 | 7.36 | 5.77 |
| 250-300 | | | 28.8 | 15 | 25.78 | 21.68 | 23.54 | 24.27 |
| 300-350 | 4.8 | 3.2 | 12.1 | 7.32 | 33.88 | 56.93 | 36.25 | 26.07 |
| 350-400 | 4.5 | 2.7 | 18.7 | 7.63 | 3.86 | 37.47 | 42.51 | 31.37 |
| 400-450 | 4.43 | 2.14 | 2.78 | 3.26 | 1.77 | 1.76 | 1.54 | 1.67 |
| 450-500 | 4.37 | 1.5 | 0.5 | 1.04 | 0.46 | 1.09 | 0.86 | 0.83 |
| 500-550 | 4.32 | 1.02 | 0.75 | 1.67 | 0.69 | 0.74 | 0.57 | 0.54 |
| 550-600 | 4.29 | 0.727 | 0.43 | 2.11 | 1.23 | 0.53 | 0.43 | 0.42 |
| 600-650 | 4.26 | 0.584 | 0.68 | 1.82 | 1.25 | 0.47 | 0.4 | 0.37 |
| 650-700 | 4.24 | 0.562 | 1.09 | 1.27 | 0.92 | 0.44 | 0.33 | 0.33 |
| 700-750 | 4.21 | 0.635 | 1.24 | 0.9 | 0.62 | 0.49 | 0.41 | 0.38 |
| 750-800 | 4.2 | 0.753 | 1.17 | 0.89 | 0.54 | 0.6 | 0.47 | 0.45 |
| 800-850 | 4.16 | 0.9 | 1.16 | 1.22 | 0.72 | 0.72 | 0.53 | 0.48 |
| 850-900 | 4.14 | 1.06 | 1.43 | 1.82 | 1.12 | 0.89 | 0.67 | 0.59 |
| 900-950 | 4.13 | 1.19 | 2.08 | 2.51 | 1.66 | 1.19 | 0.82 | 0.67 |
| 950-1000 | 4.13 | 1.32 | 3.08 | 3.25 | 2.27 | 1.7 | 1.08 | 1.09 |
| 1000-1050 | 4.13 | 1.46 | 4.32 | 3.98 | 2.88 | 2.46 | 1.87 | 1.74 |
| 1050-1100 | 4.14 | 1.56 | 5.68 | 4.66 | 3.47 | 3.44 | 3.67 | 2.28 |
| 1100-1200 | 4.11 | 1.72 | 7.78 | 5.53 | 4.26 | 5.21 | 8.53 | 7.79 |
| 1200-1300 | 4.1 | 1.97 | 10.3 | 6.43 | 5.12 | 7.74 | 16.61 | 29.77 |
| 1300-1400 | 4.08 | 2.14 | 12.4 | 7.05 | 5.74 | 10.13 | 23.55 | 51.88 |
| 1400-1500 | 4.06 | 2.3 | 14 | 7.44 | 6.16 | 12.15 | 27.8 | 62.64 |
| 1500-1600 | 4.05 | 2.41 | 15.2 | 7.66 | 6.42 | 13.73 | 29.48 | 65.31 |
| 1600-1700 | 4.03 | 2.48 | 15.9 | 7.77 | 6.56 | 14.9 | 29.19 | 62.71 |
| 1700-1800 | 4.04 | 2.5 | 16.3 | 7.79 | 6.65 | 15.72 | 27.57 | 55.81 |
| 450-900 avg. | 4.24 | 0.86 | 0.94 | 1.42 | 0.84 | 0.66 | 0.52 | 0.49 |

TABLE 19
Avg. 1-surface % R

| wavelength | Comp. Ex. 1 | Comp. Ex. 2 | Comp. Ex. 3 | Comp. Ex. 4 | Ex. 11 | Ex. 12 |
|---|---|---|---|---|---|---|
| range (nm) | (msmt.) | (msmt.) | (model) | (model) | (model) | (model) |
| 200-250 | | | 23.5 | 5.81 | 11.3 | 13.7 |
| 250-300 | | | 28.8 | 5.15 | 31.2 | 40.4 |
| 300-350 | 4.8 | 3.2 | 12.1 | 4.77 | 48.3 | 72.6 |
| 350-400 | 4.5 | 2.7 | 18.7 | 4.55 | 15.0 | 24.3 |
| 400-450 | 4.43 | 2.14 | 2.78 | 4.42 | 1.97 | 2.59 |
| 450-500 | 4.37 | 1.5 | 0.5 | 4.32 | 1.13 | 1.17 |
| 500-550 | 4.32 | 1.02 | 0.75 | 4.26 | 0.61 | 0.79 |
| 550-600 | 4.29 | 0.727 | 0.43 | 4.21 | 0.54 | 0.49 |
| 600-650 | 4.26 | 0.584 | 0.68 | 4.18 | 0.40 | 0.44 |
| 650-700 | 4.24 | 0.562 | 1.09 | 4.15 | 0.36 | 0.38 |
| 700-750 | 4.21 | 0.635 | 1.24 | 4.13 | 0.47 | 0.47 |
| 750-800 | 4.2 | 0.753 | 1.17 | 4.11 | 0.55 | 0.57 |
| 800-850 | 4.16 | 0.9 | 1.16 | 4.09 | 0.57 | 0.68 |
| 850-900 | 4.14 | 1.06 | 1.43 | 4.08 | 0.62 | 0.88 |
| 900-950 | 4.13 | 1.19 | 2.08 | 4.07 | 0.91 | 1.06 |
| 950-1000 | 4.13 | 1.32 | 3.08 | 4.06 | 1.56 | 1.45 |
| 1000-1050 | 4.13 | 1.46 | 4.32 | 4.05 | 2.57 | 2.57 |
| 1050-1100 | 4.14 | 1.56 | 5.68 | 4.04 | 3.90 | 4.84 |
| 1100-1200 | 4.11 | 1.72 | 7.78 | 4.03 | 6.28 | 10.4 |
| 1200-1300 | 4.1 | 1.97 | 10.3 | 4.02 | 9.62 | 18.7 |
| 1300-1400 | 4.08 | 2.14 | 12.4 | 4.02 | 12.7 | 25.4 |
| 1400-1500 | 4.06 | 2.3 | 14 | 4.02 | 15.3 | 29.0 |
| 1500-1600 | 4.05 | 2.41 | 15.2 | 4.02 | 17.2 | 29.9 |
| 1600-1700 | 4.03 | 2.48 | 15.9 | 4.02 | 18.7 | 28.8 |
| 1700-1800 | 4.04 | 2.5 | 16.3 | 4.02 | 19.7 | 26.3 |
| 450-900 avg. | 4.24 | 0.86 | 0.94 | 4.17 | 0.58 | 0.65 |

The transmittance and reflectance values presented in Tables 18 and 19 are revealing. First, all of the Examples 1-10 exhibit an average first-surface reflectance that is less than or equal to 1.10% across one or more of the 700 nm to 750 nm, 750 nm to 800 nm, 800 nm to 850 nm, and 850 nm to 900 nm wavelength ranges. The lower the reflectance within any of those wavelength ranges, the more photons that transmit through the article to photovoltaic cells that can generate electricity. In contrast, the bare substrate of Comparative Example 1 exhibits an average first-surface reflectance of greater than 4.2% across all of those wavelength ranges. Such reflectance values are indicative of a substrate without an antireflective coating, meaning that transmittance therethrough is limited to about 96% (about 4% having been reflected). The efficiency of the solar panel would then suffer. The article of Comparative Example 3 is engineered to reduce reflectance across those wavelength ranges but the average first-surface reflectance is still greater than 1.10%—not as good as Examples 1-10 of the present disclosure. Although the article of Comparative Example 2 exhibits average first-surface reflectance roughly on par with the Examples 1-10, the article of Comparative Example 2 suffers from suboptimal reflectance and transmittance within detrimental ultraviolet ranges and suboptimal hardness, as will be further explained.

Second, all of the Examples 1-10 exhibit an average transmittance through the article across the ultraviolet wavelength range of from 250 nm to 300 nm that is less negligible—the highest being Example 5 exhibiting an average transmittance of 0.3%. The less electromagnetic radiation associated with that ultraviolet wavelength range that transmits through the article, the less such ultraviolet electromagnetic radiation impinges upon components of a solar panel to cause their degradation. In contrast, the article of Comparative Example 3, despite having a multilayer coating, exhibits an average transmittance of 12.8%, which is well above the Examples 1-10 of the present disclosure.

Third, moving to slightly longer ultraviolet wavelengths, all of the Examples 1-10 exhibit an average transmittance across the ultraviolet wavelength range of from 300 nm to 350 nm that is less than 50%. Removing the article of Example 6 (45.91%), and the average transmittance within that ultraviolet wavelength range that the remaining Examples exhibit is less than 15%. In contrast, the articles of Comparative Examples 1-3 all exhibit an average transmittance of greater than or equal to 65%. The articles of Examples 1-10 are thus all more protective of solar panel components from the degradation associated with ultraviolet wavelengths.

Fourth, it is understood through prior modeling and physical testing that the multilayer coatings of each of Examples 1-10 will impart a relatively high hardness (e.g., greater than 4 GPa). That is because of the inclusion of the materials such as TiO₂, SiNₓ, and SiOₓN_{y} to form HRI layers or MHRI layers as the case may be. In general, when at least 10% of the topmost 300 nm of the multilayer coating includes such material(s), the multilayer coating will exhibit a relatively high hardness. In contrast, the porous sol-gel coating of Comparative Example 2 is generally understood to be not durable to abrasion and weathering events. A recent study has shown reported such a porous antireflective sol-gel coating to exhibit a hardness of only 2.6 GPa. See Song, N., et al., “Multifunctional coatings for solar module glass,” Progress in Photovoltaics: Research and Applications, 33(1), 200-208 (2025).

Fifth, the articles of Examples 9-12 provide the added benefit of exhibiting an average transmittance of less than 80% across one or more infrared wavelength ranges of from 1200 nm to 1300 nm, from 1300 nm to 1400 nm, from 1400 nm to 1500 nm, from 1500 nm to 1600 nm, from 1600 nm to 1700 nm, and from 1700 nm to 1800 nm. As mentioned, photons associated with such infrared wavelength ranges do not cause a photovoltaic cell to generate electrical current. Rather, such photons are absorbed and generate heat, which can be detrimental to current generation and cause degradation over time. The articles of Examples 9 and 10 would limit the transmission of such electromagnetic radiation (e.g., via reflectance) and thus prevent those detrimental effects from occurring. In contrast, the articles of all of Comparative Examples 1-3 transmit greater than 80% across each of those wavelength ranges.

In summary, none of Comparative Examples 1~4 exhibit the combination of beneficial reflectance, transmittance, and hardness values that Examples 1-12 of the disclosure. The bare substrate of Comparative Example 1 is challenged in terms of too high transmittance of ultraviolet wavelengths, and too low transmittance of visible wavelengths. The article of Comparative Example 2, with the porous sol-gel antireflective coating, is challenged in terms of suboptimal hardness and too high transmittance of ultraviolet wavelengths. The article of Comparative Example 3 is challenged in terms of too high transmittance of ultraviolet wavelengths, and too high reflectance or too low transmittance of visible or near-infrared wavelengths (e.g. from 700 nm to 900 nm). The articles of Examples 1-12 address all of those issues, with the articles of Examples 9 and 10 further limiting transmission of infrared wavelengths longer than 1200 nm.

Comparative Example 4 is an uncoated glass (Glass E) designed for UV absorption. Although this glass exhibits UV blocking (% T less than 50% averaged from 300-350 nm, and less than 2% from 250-300 nm), Comp. Ex. 4 has transmittance that is too low (less than 92.5%) in visible-NIR wavelength ranges from 400-1000 nm, and transmittance that is undesirably high in the mid-IR ranges from 1300-1800 nm.

We have found through experimentation and modeling that the most preferred Example designs for some solar applications are those designs that exceed the performance of Comparative Example 2 (the porous SiO₂ AR coated glass) across multiple wavelength ranges of interest, with a particular emphasis on the 450-900 nm wavelength range, where the AM1.5 solar photon flux is highest (greater than 80% of the maximum photon flux). While other workers may have explored the use of coatings having visible AR functions combined with one or more UV or mid-IR blocking functions (see e.g. Song, N., Chang, N., Gentle, A., Zeng, Y., Jiang, Y., Wu, Y., . . . & Green, M. A., 2025, “Multifunctional coatings for solar module glass,” Progress in Photovoltaics: Research and Applications, 33(1), 200-208; and Li, W., Shi, Y., Chen, K., Zhu, L., & Fan, S., 2017, “A comprehensive photonic approach for solar cell cooling,” ACS Photonics, 4(4), 774-782), we have found that alternate coating designs proposed by others do not enable enhanced transmittance in the 450-900 nm wavelength range that exceeds that of porous SiO₂ AR coatings like Comp. Ex. 2. Based on our own modeling of solar panel performance, we believe that solar panels with coatings having inferior transmission from 450-900 nm are likely to have lower solar energy generation than panels using porous SiO2 coated glass, even when accounting for the UV and mid-IR (thermal) benefits that such coatings can provide. Thus, particularly preferred ranges of two-surface transmittance (measured with one coated and one uncoated surface of the article) are greater than 94.9%, greater than 95%, greater than 95.1%, greater than 95.2%, greater than 95.3%, or greater than 95.4% for one or more wavelength ranges between 450-900 nm (e.g. from 500-550 nm or from 700-750 nm), or having average transmittance over the entire range from 450-900 nm greater than 94.7%, greater than 94.8%, greater than 94.9%, greater than 95.0%, greater than 95.2%, greater than 95.4%, greater than 95.6%, or even greater than 95.7% (e.g. 95.8%). These preferred transmission ranges from 450-900 nm (visible to NIR) can be combined with preferred low UV transmittance values: less than 5%, less than 2%, or less than 1% averaged from 250-300 nm; and/or less than 50%, less than 25%, less than 20%, less than 15%, less than 10%, less than 5%, or less than 3% averaged from 300-350 nm. Examples illustrating these preferred ranges of visible-NIR transmittance combined with low UV transmittance include Ex. 1, Ex. 5, Ex. 8, Ex. 9, Ex. 10, Ex. 11, and Ex. 12. These preferred visible-NIR and UV transmittance levels can further be preferably combined with average transmittance below 85% or below 80% in one or more mid-IR wavelength ranges from 1200-1800 nm. Examples illustrating these preferred transmittance values in all three wavelength ranges (450-900 nm, 250-350 nm, and 1200-1800 nm) include Ex. 1, Ex. 8, Ex. 9, Ex. 10, Ex. 11, and Ex. 12.

In a related manner, we have found that the most preferred Example designs for some solar applications are those designs that have lower first-surface reflectance than Comparative Example 2 (the porous SiO₂ AR coated glass) across the 450-900 nm wavelength range, where the AM1.5 solar photon flux is highest (greater than 80% of the maximum photon flux). Thus, particularly preferred ranges of first-surface reflectance (measured with one coated surface, and back-surface reflections of the article removed) are having average first-surface reflectance over the entire range from 450-900 nm less than 0.85, less than 0.8, less than 0.75, less than 0.7, less than 0.65, less than 0.6, less than 0.55, or even less than 0.5. These preferred reflectance ranges from 450-900 nm (visible to NIR) can be combined with preferred high UV first-surface reflectance values: greater than 30% or greater than 35% averaged from 250-300 nm; and/or greater 20%, greater than 30%, greater than 40%, greater than 50%, greater than 60%, greater than 70%, or even greater than 80% averaged from 300-350 nm. Examples illustrating these preferred ranges of visible-NIR reflectance combined with high UV reflectance in one or more UV wavelength ranges include Ex. 1, Ex. 3, Ex. 4, Ex. 5, Ex. 7, Ex. 8, Ex. 9, Ex. 10, Ex. 11, and Ex. 12. These preferred visible-NIR and UV reflectance levels can further be preferably combined with average first-surface reflectance greater than 17%, greater than 18%, greater than 19%, greater than 20%, greater than 25%, greater than 30%, greater than 40%, greater than 50%, or greater than 60%, in one or more mid-IR wavelength ranges from 1200-1800 nm. Examples illustrating these preferred transmittance values in all three wavelength ranges (450-900 nm, 250-350 nm, and 1200-1800 nm) include Ex. 3, Ex. 4, Ex. 9, Ex. 10, Ex. 11, and Ex. 12. The fact that some Examples do not simultaneously meet these combinations of the most preferred criteria is a further illustration that only specifically engineered coating designs can enable the highest performance across UV, visible, NIR, and mid-IR ranges to provide the greatest enhancement to lifetime power generation in solar panel cover glass applications. The Figure above compares the UV cutoff sharpness of Comp. Ex. 4 with Examples 11 and 12. Comp. Ex. 1, 2, and 3 are excluded from the UV cutoff sharpness analysis here, because these comparative examples do not have the targeted UV blocking properties, that is, the average transmission of Comp. Ex. 1, 2 and 3 over the 300-350 nm wavelength range are all greater than 50%. In contrast, Comp. Ex. 4 is a glass designed for bulk UV absorption, having an average transmission over the 300-350 nm wavelength range of less than 25% at 100 microns thickness, making Comp. Ex. 4 the most relevant comparative example to compare UV cutoff sharpness with the coated Examples. As can be seen from the Figure above and the Table below, selected Examples have substantially sharper UV cutoffs than Comp. Ex. 4, using either the “UV cut sharpness (90-2)” or the “UV cut sharpness (85-5)” metrics. Preferred ranges of UV cut sharpness (90-2) are less than 120 nm, less than 110 nm, less than 100 nm, less than 90 nm, less than 80 nm, less than 70 nm, less than 60 nm, less than 50 nm, less than 40 nm, or even less than 30 nm. Preferred ranges of UV cut sharpness (85-5) are less than 75 nm, less than 70 nm, less than 60 nm, less than 50 nm, less than 40 nm, or even less than 30 nm, or even less than 20 nm. In addition, preferred ranges of 2% T UV edge wavelength include 300-375 nm, 300-360 nm, 310-360 nm, 320-350 nm, or 320-345 nm. Preferred ranges of 5% T UV edge wavelength include 305-375 nm, 310-360 nm, 320-360 nm, 320-355 nm, or 320-350 nm. Preferred ranges of 85% T UV edge wavelength include 340-390 nm, 350-380 nm, or 360-380 nm. Preferred ranges of 90% T UV edge wavelength include 350-420 nm, 370-410 nm, 380-410 nm, 380-405 nm, 380-400 nm, or 380-395 nm. These preferred values of UV edge wavelengths and UV cut sharpness can be combined with the preferred values of low UV transmission, high UV reflection, high visible-NIR transmission, low visible-NIR reflection, and preferred levels of mid-IR (e.g. 1300-1800 nm) transmission and reflection defined above and in Tables and Figures for Examples.

UV cutoff sharpness values for Examples are summarized in the Table 20 below.

TABLE 20
UV Cutoff parameters

| | 2% T | 90% T | UV Cut | 5% T | 85% T | UV Cut |
|---|---|---|---|---|---|---|
| | wavelength | wavelength | sharpness | wavelength | Wavelength | sharpness |
| Example | (nm) | (nm) | 90-2 | (nm) | (nm) | 85-5 |
| Comp. Ex. 4 | 291 | 425 | 134 | 301 | 383 | 82 |
| Ex. 1 | 341 | 389 | 48 | 350 | 386 | 36 |
| Ex. 2 | 326 | 420 | 94 | 333 | 404 | 71 |
| Ex. 3 | 316 | 386 | 70 | 323 | 370 | 47 |
| Ex. 4 | 329 | 412 | 83 | 335 | 380 | 45 |
| Ex. 5 | 311 | 402 | 91 | 325 | 363 | 38 |
| Ex. 6 | 303 | 404 | 101 | 307 | 350 | 43 |
| Ex. 7 | 327 | 431 | 104 | 331 | 385 | 54 |
| Ex. 8 | 335 | 387 | 52 | 347 | 384 | 37 |
| Ex. 9 | 355 | 382 | 27 | 361 | 380 | 19 |
| Ex. 10 | 338 | 384 | 46 | 342 | 380 | 38 |
| Ex. 11 | 326 | 381 | 55 | 336 | 375 | 39 |
| Ex. 12 | 337 | 393 | 56 | 347 | 375 | 28 |

It will be apparent to those skilled in the art that various modifications and variations can be made without departing from the spirit or scope of the claims.

What is claimed is:

1. An article comprising:
a substrate comprising a first major surface and a second major surface, the first major surface and the second major surface facing in generally opposite directions; and
a multilayer coating disposed on the first major surface of the substrate, the multilayer coating comprising a total coating thickness,
wherein, the multilayer coating of the article exhibits a maximum hardness that is greater than or equal to 5 GPa measured at any depth within an indentation depth range of (i) from 0 to 500 nm into the total coating thickness or (ii) from 0 to the total coating thickness, whichever of (i) and (ii) is smaller, according to a Berkovich Indenter Hardness Test,
wherein, the article exhibits an average first-surface reflectance, at an angle of incidence of 5 degrees from orthogonal to the first major surface, that is less than or equal to 1.10% across one or more of the following wavelength ranges: from 700 nm to 750 nm, from 750 nm to 800 nm, from 800 nm to 850 nm, and from 850 nm to 900 nm, and
wherein, the article exhibits an average transmittance through the article, at an angle of incidence of 0 degrees from orthogonal to the first major surface, that is (i) less than or equal to 12.0% across the wavelength range of from 250 nm to 300 nm, and (ii) less than or equal to 50% across the wavelength range of from 300 nm to 350 nm.

2. The article of claim 1, wherein
the substrate comprises a glass composition or a glass-ceramic composition, and
the multilayer coating further comprises
a plurality of multilayer sections, each of the multilayer sections disposed successively with respect to one another on the first major surface, each multilayer section comprising at least two layers, wherein
both of the at least two layers exhibit unique indices of refraction,
the layer of the at least two layers disposed closer to the first major surface of the substrate is one of (i) an LRI layer exhibiting a low index of refraction within a range of from 1.35 to 1.60, (ii) an MLRI layer exhibiting a medium-low index of refraction that is within a range of from 1.61 to 1.84, and (iii) an MHRI layer exhibiting a medium-high index of refraction that is within a range of from 1.85 to 2.10, and
the layer of the at least two layers disposed farther from the first major surface of the substrate exhibits a greater index of refraction than the closer layer and is one of (i) an MLRI layer, (ii) an MHRI layer, and (iii) an HRI layer exhibiting a high index of refraction that is within a range of from 2.11 to 2.70, and
a capping LRI layer disposed over the plurality of multilayer sections, the capping LRI layer exhibiting the low index of refraction and comprising a capping layer thickness.

3. The article of claim 1, wherein
the average first-reflectance, at an angle of incidence of 5 degrees from orthogonal to the first major surface, that the article exhibits is less than or equal to 0.9% across all of the following wavelength ranges: from 500 nm to 550 nm, from 550 nm to 600 nm, from 600 nm to 650 nm, from 650 nm to 700 nm, from 700 nm to 750 nm, from 750 nm to 800 nm, and from 800 nm to 850 nm.

4. The article of claim 1, wherein
the article exhibits an average first-surface reflectance, at an angle of incidence of 5 degrees from orthogonal to the first major surface, that is less than or equal to 1.50% across the wavelength range of from 450 nm to 900 nm, and
the article exhibits an average transmittance, at an angle of incidence of 0 degrees from orthogonal to the first major surface, that is greater than or equal to 30% across the wavelength range of from 300 nm to 350 nm.

5. The article of claim 1, wherein
the article exhibits an average transmittance through the article, at an angle of incidence of 0 degrees from orthogonal to the first major surface, that is less than or equal to 10.0% across the wavelength range of from 300 nm to 350 nm, and
the article exhibits an average first-surface reflectance, at an angle of incidence of 5 degrees from orthogonal to the first major surface, that is (i) less than or equal to 0.50% across one or more of the following wavelength ranges: from 550 nm to 600 nm, from 600 nm to 650 nm, from 650 nm to 700 nm, and from 750 nm to 800 nm, and (ii) less than or equal to 2.0% across one or more of the following wavelength ranges: from 800 nm to 850 nm, from 850 nm to 900 nm, from 900 nm to 950 nm, from 950 nm to 1000 nm, and from 1000 nm to 1050 nm.

6. The article of claim 1, wherein
the article exhibits an average transmittance through the article, at an angle of incidence of 0 degrees from orthogonal to the first major surface, that is (i) less than or equal to 10% across the wavelength range of from 250 nm to 300 nm, (i) less than or equal to 50% across the wavelength range of from 300 nm to 350 nm, and (iii) greater than or equal to 93.0% across the wavelength range of from 400 nm to 1100 nm.

7. The article of claim 1, wherein
the article exhibits an average transmittance through the article, at an angle of incidence of 0 degrees from orthogonal to the first major surface, that is less than or equal to 80% across one or more of the following wavelength ranges: from 1200 nm to 1300 nm, from 1300 nm to 1400 nm, from 1400 nm to 1500 nm, from 1500 nm to 1600 nm, from 1600 nm to 1700 nm, from 1700 nm to 1800 nm.

8. An article comprising:
a substrate comprising (i) a glass composition or a glass-ceramic composition, (ii) a first major surface, and (iii) a second major surface, the first major surface and the second major surface facing in generally opposite directions; and
a multilayer coating disposed on the first major surface of the substrate, the multilayer coating comprising
a plurality of multilayer sections, each of the multilayer sections disposed successively with respect to one another on the first major surface, each multilayer section comprising at least two layers, wherein
both of the at least two layers exhibit unique indices of refraction,
the layer of the at least two layers disposed closer to the first major surface of the substrate is one of (i) an LRI layer exhibiting a low index of refraction within a range of from 1.35 to 1.60, (ii) an MLRI layer exhibiting a medium-low index of refraction that is within a range of from 1.61 to 1.84, and (iii) an MHRI layer exhibiting a medium-high index of refraction that is within a range of from 1.85 to 2.10, and
the layer of the at least two layers disposed farther from the first major surface of the substrate exhibits a greater index of refraction than the closer layer and is one of (i) an MLRI layer, (ii) an MHRI layer, and (iii) an HRI layer exhibiting a high index of refraction that is within a range of from 2.11 to 2.70,
a total coating thickness that is within a range of from 100 nm to 10000 nm, and
a capping LRI layer disposed over the plurality of multilayer sections, the capping LRI layer exhibiting the low index of refraction and comprising a capping layer thickness,
wherein, each of the layers of the plurality of multilayer sections comprises a layer thickness,
wherein, a sum of the layer thicknesses of the LRI layers and the capping LRI layer is within a range of from 50% to 90% of the total coating thickness, and
wherein, at least 10% of a 300 nm thick topmost portion of the total coating thickness is made of material forming one or more of the HRI layers, MHRI layers, or both.

9. The article of claim 8, wherein
the plurality of multilayer sections numbers within a range of from 3 to 15.

10. The article of claim 8, wherein
the total coating thickness of the multilayer coating further is within a range of from 250 nm to 1500 nm.

11. The article of claim 8, wherein
the multilayer coating comprises at least three layers, each of the at least three exhibiting unique indices of refraction.

12. The article of claim 8, wherein
each of the LRI layers and the capping LRI layer comprise one or more of SiO₂, doped SiO₂, Al₂O₃, GeO₂, SiO, AlOₓN_{y}, SiOₓN_{y}, SiᵤAl_{y}OₓN_{y}, MgO, MgF₂, BaF₂, CaF₂, DyF₃, YbF₃, YF₃, and CeF₃,
each of the MLRI layers comprises one or more of AlSiₓO_{y}N_{z}, AlOₓN_{y}, and SiOₓN_{y},
each of the MHRI layers comprises one or more of AlSiₓO_{y}N_{z}, SiNₓ, AlOₓN_{y}, and SiOₓN_{y}, and
each of the HRI layers comprises one or more of Nb₂O₅, AlN, SiNₓ, AlOₓN_{y}, SiOₓN_{y}, TiO₂, and CeO₂.

13. The article of claim 12, wherein
the HRI layer of at least one of the plurality of multilayer sections comprises CeO₂.

14. The article of claim 8, wherein
the glass composition or the glass-ceramic composition of the substrate comprises one or more of elemental titanium, ionic titanium, and a titanium oxide.

15. An article comprising:
a substrate comprising a first major surface, a second major surface, the first major surface and the second major surface facing in generally opposite directions, and a substrate thickness between the first major surface and the second major surface; and
a multilayer coating disposed on the first major surface of the substrate, the multilayer coating comprising a total coating thickness, each of the layers comprising a layer thickness,
wherein, the article exhibits an average transmittance through the article, at an angle of incidence of 0 degrees from orthogonal to the first major surface, that is less than or equal 20.0% across the wavelength range of from 300 nm to 350 nm,
wherein, the article exhibits an average transmittance through the article, at an angle of incidence of 0 degrees from orthogonal to the first major surface, that is greater than or equal to 94.8% across the wavelength range of from 450 nm to 900 nm,
wherein, the article exhibits an average transmittance through the article, at an angle of incidence of 0 degrees from orthogonal to the first major surface, that is less than or equal to 80% across any one or more of the following wavelength ranges: from 1300 nm to 1400 nm, from 1400 nm to 1500 nm, from 1500 nm to 1600 nm, from 1600 nm to 1700 nm, and from 1700 nm to 1800 nm,
wherein, the article exhibits an average first-surface reflectance, at an angle of incidence of 5 degrees from orthogonal to the first major surface, that is greater than or equal to 40.0% across the wavelength range of from 300 nm to 350 nm, and
wherein, the multilayer coating of the article exhibits a maximum hardness that is greater than or equal to 5 GPa measured at any depth within an indentation depth range of (i) from 0 to 500 nm into the total coating thickness or (ii) from 0 to the total coating thickness, whichever of (i) and (ii) is smaller, according to a Berkovich Indenter Hardness Test.

16. The article of claim 15, wherein
the article exhibits an ultraviolet cutoff wavelength within a range of from 320 nm to 390 nm.

17. The article of claim 15, wherein
the multilayer coating further comprises
a plurality of multilayer sections, each of the multilayer sections disposed successively with respect to one another on the first major surface, each multilayer section comprising at least two layers, wherein
both of the at least two layers exhibit unique indices of refraction,
the layer of the at least two layers disposed closer to the first major surface of the substrate is one of (i) an LRI layer exhibiting a low index of refraction within a range of from 1.35 to 1.60, (ii) an MLRI layer exhibiting a medium-low index of refraction that is within a range of from 1.61 to 1.84, and (iii) an MHRI layer exhibiting a medium-high index of refraction that is within a range of from 1.85 to 2.10, and
the layer of the at least two layers disposed farther from the first major surface of the substrate exhibits a greater index of refraction than the closer layer and is one of (i) an MLRI layer, (ii) an MHRI layer, and (iii) an HRI layer exhibiting a high index of refraction that is within a range of from 2.11 to 2.70, and
a capping LRI layer disposed over the plurality of multilayer sections, the capping LRI layer exhibiting the low index of refraction and comprising a capping layer thickness.

18. The article of claim 17, wherein
at least one of the plurality of multilayer sections comprise a layer of SiO₂ and a layer of SiNₓ,
at least one of the plurality of multilayer sections comprise a layer of SiO₂ and a layer of TiO₂, and
all of the multilayer sections that comprise a layer of SiO₂ and a layer of TiO₂ are disposed closer to the first major surface of the substrate than the at least one of the plurality of multilayer sections that comprise a layer of SiO₂ and a layer of SiNₓ.

19. The article of claim 18, wherein
a layer of SiO₂ having a layer thickness of less than 2.0 nm is disposed between, and in direct contact with, a layer of SiNₓ and a layer of TiO₂.

20. The article of claim 17, wherein
at least 30% of a 300 nm thick topmost portion of the total coating thickness is made of material forming one or more of the HRI layers, MHRI layers, or both.
